(19) United States
(12) Patent Application Publication
(10) Pub. No.: US 2026/0173655 A1
(43) Pub. Date: Jun. 18, 2026

(54) DISPLAY DEVICE, ELECTRONIC APPARATUS, AND METHOD OF MANUFACTURING DISPLAY DEVICE

(71) Applicant: Sony Semiconductor Solutions Corporation, Kanagawa (JP)

(72) Inventor: Tomoyoshi Ichikawa, Kanagawa (JP)

(21) Appl. No.: 19/108,908

(22) PCT Filed: Oct. 3, 2023
(86) PCT No.: PCT/JP2023/036032

§ 371 Date: Mar. 5, 2025

(30) Foreign Application Priority Data
Oct. 28, 2022 (JP) 2022-172851

(51) Int. Cl. H10K 59/122; H10K 59/12; H10K 59/131; H10K 59/80; H10K 102/00

(52) U.S. Cl. CPC H10K 59/122; H10K 59/1201; H10K 59/131; H10K 59/80522; H10K 59/873; H10K 2102/351

(57) ABSTRACT

Display devices with improved sub-pixel light emission efficiency are disclosed. In one example, a display device includes first, second and third sub-pixels. The first sub-pixel includes a first light emitting element that includes a first organic layer. A protective layer covers at least the first light emitting element. In the protective layer, a first opening and a second opening are formed in portions corresponding to the second sub-pixel and the third sub-pixel, respectively, and opening shapes of the first opening and the second opening are different.

### TECHNICAL FIELD

The present disclosure relates to a display device, an electronic apparatus, and a method of manufacturing a display device.

### BACKGROUND ART

In a display device using an organic electro-luminescence (EL) element having a light emitting layer, a display device having a plurality of sub-pixels corresponding to a plurality of color types is also required to miniaturize the pitch of sub-pixels. In order to realize a fine pitch of sub-pixels in a display device, Patent Document 1 discloses a technique in which a structure in which a plurality of light emitting layers corresponding to a plurality of color types of sub-pixels are laminated is formed over the plurality of sub-pixels. Furthermore, Patent Document 2 discloses a technique in which an organic EL element for each color type is formed by performing a vapor deposition process and processing of a light emitting layer or the like for each color type of sub-pixels.

### CITATION LIST

### Patent Document

Patent Document 1: Japanese Patent Application Laid-Open No. 2013-258022
Patent Document 2: WO 2020/004086 A

### SUMMARY OF THE INVENTION

### Problems to be Solved by the Invention

The technique disclosed in Patent Document 1 has room for improvement in terms of improving the light emission efficiency of the sub-pixel. The technique disclosed in Patent Document 2 has room for improvement in terms of suppressing an increase in the number of manufacturing processes.

The present disclosure has been made in view of the above-described points, and an object of the present disclosure is to provide a display device, an electronic apparatus, and a method of manufacturing a display device capable of suppressing an increase in the number of manufacturing processes and improving light emission efficiency of a sub-pixel.

### Solutions to Problems

The present disclosure is, for example, (1) a display device including:
a first sub-pixel, a second sub-pixel, and a third sub-pixel as sub-pixels, in which
a light emitting element including an organic layer is formed in each of the sub-pixels,
the first sub-pixel includes a first light emitting element as the light emitting element, and the first light emitting element includes a first organic layer as the organic layer,
the display device further includes: a protective layer that covers at least the first light emitting element,
in the protective layer, a first opening and a second opening are formed as openings in portions corresponding to the second sub-pixel and the third sub-pixel, respectively, and
opening shapes of the first opening and the second opening are different.

The present disclosure may be (2) an electronic apparatus including the display device according to (1) described above.

Furthermore, the present disclosure is (3) a method of manufacturing a display device, the method including:
forming a first light emitting element that has a first organic layer at a position corresponding to a first sub-pixel;
forming a protective layer that covers the first light emitting element;
forming a first opening and a second opening at positions corresponding to a second sub-pixel and a third sub-pixel in the protective layer so as to have opening shapes different from each other; and
forming, in portions corresponding to the first opening and the second opening, a second organic layer forming a second light emitting element and a third light emitting element corresponding to the second sub-pixel and the third sub-pixel, respectively, and having a common material.

### BRIEF DESCRIPTION OF DRAWINGS

FIG. 1A is a plan diagram for explaining an example of a display device according to a first embodiment. FIG. 1B is a plan diagram schematically illustrating a state where a region XS1 portion surrounded by a broken line in FIG. 1A is enlarged.

FIG. 2 is a cross-sectional view for explaining an example of the display device according to the first embodiment.

FIG. 3A is a cross-sectional view schematically illustrating a state of a longitudinal cross section taken along line A-A in FIG. 1B. FIG. 3B is a cross-sectional view schematically illustrating a state of a vertical cross section taken along line B-B in FIG. 1B.

FIGS. 4A and 4B are plan diagrams for explaining an example of the display device according to the first embodiment. FIG. 4C is a cross-sectional view for explaining an example of an auxiliary electrode provided in an outer region of a display region.

FIGS. 5A to 5C are cross-sectional views for explaining an organic layer in one example of the display device according to the first embodiment.

FIGS. 6A to 6D are diagrams for explaining an example of a method of manufacturing the display device according to the first embodiment.

FIGS. 7A to 7C are diagrams for explaining the example of the method of manufacturing the display device according to the first embodiment.

FIG. 8A is a diagram for explaining an example of a manufacturing line used in the method of manufacturing the display device according to the first embodiment. FIG. 8B is a diagram schematically illustrating a state where a region XS2 portion in FIG. 8A is enlarged.

FIGS. 9A to 9F are diagrams for explaining examples of a sub-pixel of a display device according to a first modification of the first embodiment.

FIGS. 10A to 10C are cross-sectional views for explaining examples of a display device according to a second modification of the first embodiment.

FIGS. 11A to 11D are cross-sectional views for explaining examples of a display device according to a third modification of the first embodiment.

FIGS. 12A and 12B are cross-sectional views for explaining examples of a display device according to a fourth modification of the first embodiment. FIG. 12C is a cross-sectional view for explaining an example of a display device according to a fifth modification of the first embodiment.

FIGS. 13A to 13C are cross-sectional views for explaining examples of a display device according to a sixth modification of the first embodiment.

FIGS. 14A and 14B are cross-sectional views for explaining examples of a display device according to a seventh modification of the first embodiment.

FIGS. 15A and 15B are cross-sectional views for explaining examples of a display device according to an eighth modification of the first embodiment.

FIG. 16A is a cross-sectional view for explaining an example of a display device according to a seventh modification of the first embodiment. FIG. 16B is a cross-sectional view for explaining an example of a display device according to a ninth modification of the first embodiment.

FIGS. 17A and 17B are cross-sectional views for explaining an organic layer in an example of a display device according to a tenth modification of the first embodiment.

FIGS. 18A and 18B are cross-sectional views for explaining an organic layer in an example of a display device according to an eleventh modification of the first embodiment.

FIG. 19 is a cross-sectional view for explaining an example of a display device according to a twelfth modification of the first embodiment.

FIG. 20A is a cross-sectional view for explaining an example of a display device according to a thirteenth modification of the first embodiment.

FIG. 20B is a cross-sectional view for explaining an example of the display device according to the thirteenth modification of the first embodiment.

FIG. 20C is a cross-sectional view for explaining an example of the display device according to the thirteenth modification of the first embodiment.

FIG. 20D is a cross-sectional view for explaining an example of the display device according to the thirteenth modification of the first embodiment.

FIG. 21A is a cross-sectional view for explaining an example of a display device according to a fourteenth modification of the first embodiment.

FIG. 21B is a cross-sectional view for explaining an example of a display device according to the fourteenth modification of the first embodiment.

FIG. 21C is a cross-sectional view for explaining an example of the display device according to the fourteenth modification of the first embodiment.

FIG. 21D is a cross-sectional view for explaining an example of the display device according to the fourteenth modification of the first embodiment.

FIG. 21E is a cross-sectional view for explaining an example of the display device according to the fourteenth modification of the first embodiment.

FIG. 22A is a cross-sectional view for explaining an example of a display device according to a fifteenth modification of the first embodiment.

FIG. 22B is a cross-sectional view for explaining an example of a display device according to the fifteenth modification of the first embodiment.

FIG. 22C is a cross-sectional view for explaining an example of the display device according to fifteenth modification of the first embodiment.

FIGS. 23A to 23F are diagrams for explaining layouts of sub-pixels in the example of the display device of the first embodiment.

FIGS. 24A to 24F are cross-sectional views for explaining the examples of the display device according to the first modification of the first embodiment.

FIGS. 25A to 25C are plan diagrams for explaining the examples of the display device according to the twelfth modification of the first embodiment.

FIG. 26 is a cross-sectional view for explaining the example of the display device according to the twelfth modification of the first embodiment.

FIG. 27 is a cross-sectional view for explaining an example of the display device according to the second embodiment.

FIGS. 28A and 28B are plan diagrams for explaining the example of the display device according to the second embodiment.

FIGS. 29A and 29B are cross-sectional views for explaining an example of a method of manufacturing the display device according to the second embodiment.

FIGS. 30A and 30B are cross-sectional views for explaining the example of the method of manufacturing the display device according to the second embodiment.

FIG. 31 is a cross-sectional view for explaining an example of the display device according to the second embodiment.

FIG. 32A is a cross-sectional view for explaining an example of a display device according to a third embodiment. FIG. 32B is a plan diagram schematically illustrating a state where a region XS3 portion surrounded by a broken line in FIG. 32A is enlarged.

FIG. 33 is a diagram for explaining a sub-pixel in an example of a display device according to a first modification of the third embodiment.

FIG. 34A is a cross-sectional view for explaining an example of a display device according to a modification of the third embodiment. FIG. 34B is a plan diagram for explaining an example of an annular lens.

FIGS. 35A and 35B are cross-sectional views for explaining a second organic layer used in an example of a display device according to a fourth embodiment.

FIGS. 36A and 36B are cross-sectional views for explaining a second organic layer used in an example of the display device according to the fourth embodiment.

FIGS. 37A and 37B are diagrams for explaining an example of a display device having a resonator structure.

FIGS. 38A and 38B are diagrams for explaining an example of the display device having the resonator structure.

FIGS. 39A and 39B are diagrams for explaining an example of the display device having the resonator structures.

FIG. 40 is a diagram for explaining an example of the display device having the resonator structure.

FIGS. 41A, 41B, and 41C are diagrams for explaining an example of a case where the display device includes a wavelength selection unit.

FIG. 42 is a diagram for explaining an example of a case where the display device includes the wavelength selection unit.

FIGS. 43A and 43B are diagrams for explaining an example of a case where the display device includes the wavelength selection unit.

FIG. 44 is a diagram for explaining an example of a case where the display device includes the wavelength selection unit.

FIGS. 45A and 45B are views for explaining an application example of the display device.

FIG. 46 is a view for explaining an application example of the display device.

FIG. 47 is a view for explaining an application example of the display device.

FIG. 48 is a view for explaining an application example of the display device.

FIG. 49 is a view for explaining an application example of the display device.

FIGS. 50A and 50B are views for explaining an application example of the display device.

### MODE FOR CARRYING OUT THE INVENTION

Hereinafter, an example and the like according to the present disclosure will be described with reference to the drawings. Note that the description will be given in the following order. In the present specification and the drawings, configurations having substantially the same functional configurations are denoted by the same reference numeral, and redundant descriptions are omitted.

Note that the description will be given in the following order.
1. First Embodiment
2. Second Embodiment
3. Third Embodiment
4. Fourth Embodiment
5. Example of Case Where Display Device Has Resonator Structure
6. Example of Positional Relationship in Case Where Display Device Includes Wavelength Selection Unit
7. Application Example

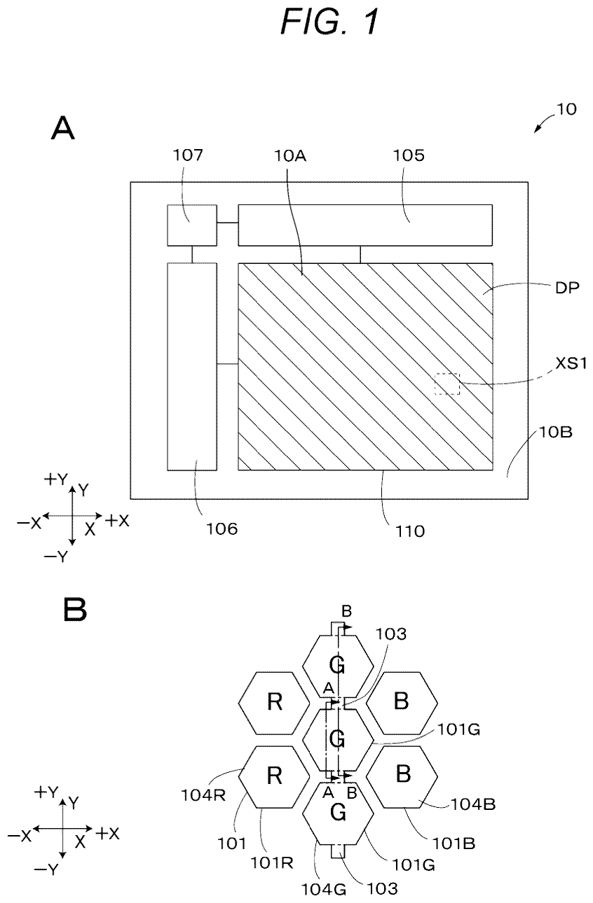

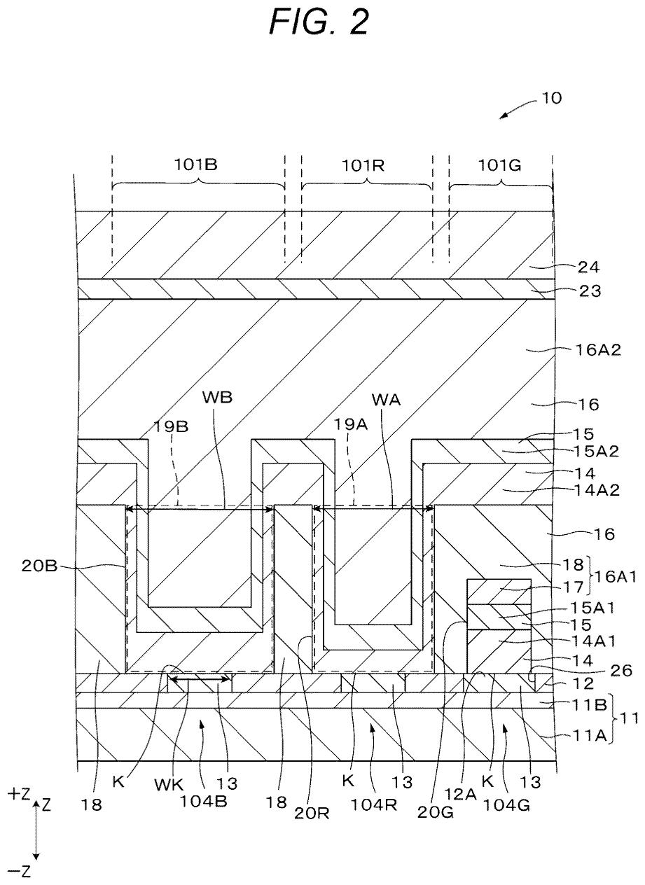

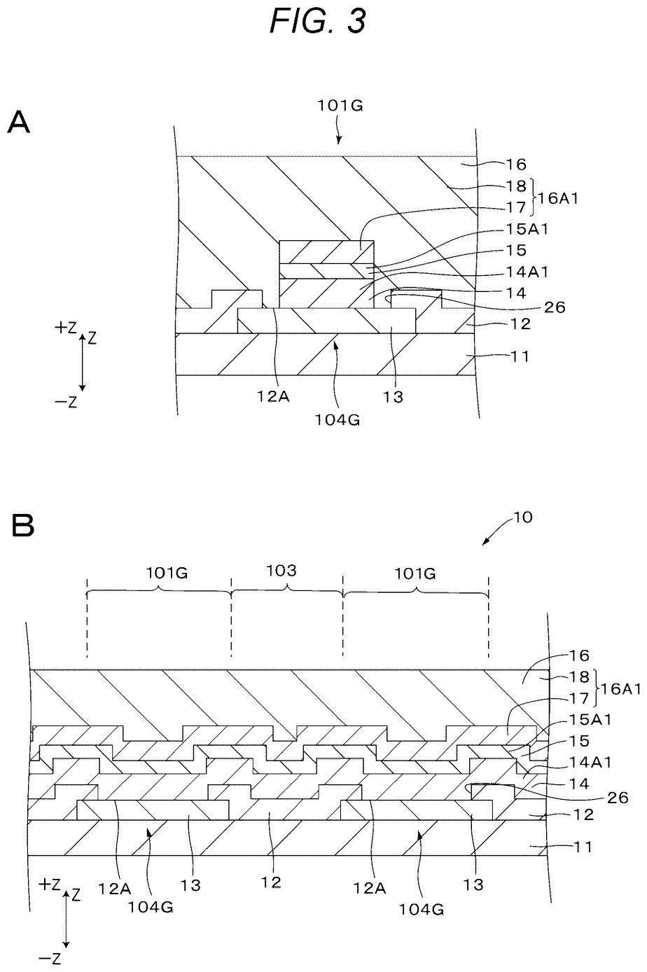

The following description is preferred specific examples of the present disclosure, and the contents of the present disclosure is not limited to these embodiments and the like. Furthermore, in the following description, directions of front and rear, left and right, up and down, and the like are indicated in consideration of convenience of description, but the content of the present disclosure is not limited to these directions. In examples of FIGS. 1 and 2, it is assumed that a Z-axis direction is an up-down direction (an upper side is in a +Z direction, and a lower side is in a −Z direction), an X-axis direction is a left-right direction (a right side is in a +X direction, and a left side is in a −X direction), and a Y-axis direction is a front-rear direction (a rear side is in a +Y direction, and a front side is in a −Y direction), and the description will be made on the basis of this. The similarity applies to the description of any one or more of the X axis, the Y axis, and the Z axis in FIGS. 3 to 36. A relative dimensional ratio of the size and thickness of each layer illustrated in each drawing of FIG. 1 and the like is illustrated for convenience, and does not limit any actual dimensional ratios. The similarity applies to each drawing of FIGS. 2 to 36 regarding the definitions of these directions and the dimensional ratios.

### 1 First Embodiment

### 1-1 Configuration of Device

A display device 10 according to a first embodiment of the present disclosure includes a plurality of pixels arranged two-dimensionally. In the display device 10, one pixel may be formed by a combination of a plurality of sub-pixels 101. Hereinafter, a case where one pixel is formed by a combination of a plurality of sub-pixels corresponding to a plurality of color types in the display device 10 will be described as an example. Note that, in this case, the plurality of sub-pixels 101 is two-dimensionally arranged in the display device 10.

Examples of the display device according to the first embodiment of the present disclosure include an organic electroluminescence (EL) display device. In the display device according to the first embodiment, as illustrated in FIGS. 1A, 1B, 2, and the like, a case where the display device is an organic EL display device (hereinafter, simply referred to as a “display device 10”.) will be described as an example. FIG. 1A is a plan diagram illustrating an example of the display device 10. FIG. 1B is a diagram schematically illustrating a state where a region XS1 portion in FIG. 1A is enlarged. FIG. 2 is a cross-sectional view illustrating an example of the display device 10.

In the description below, a case where the display device 10 performs display by a top emission method is explained as an example. It is assumed that the top emission method indicates a method in which a light emitting element 104 is disposed on a side of a display surface DP than a die of a substrate 11A. Accordingly, in the display device 10, the substrate 11A is located on a back surface side of the display device 10, and a direction (+Z direction) from the substrate 11A toward the light emitting elements 104 described later is a direction toward a front surface side (upper surface side) of the display device 10. In the display device 10, light generated from the light emitting element 104 is directed in the +Z direction, and is emitted to the outside. In the following description, in each of the layers constituting the display device 10, a surface on the display surface DP side in a display region (display region 10A) formed by a display region forming unit 110 of the display device 10 is referred to as a first surface (upper surface), and a surface on the back surface side of the display device 10 is referred to as a second surface (lower surface). Note that this does not prohibit the case where the display device 10 according to the present disclosure is of a bottom emission type. The display device 10 is also applicable to a bottom emission type. In the bottom emission type, light generated from the light emitting element 104 is directed in the −Z direction and emitted to the outside. Furthermore, a region outside the display region 10A on the surface on the display surface DP side may be referred to as an outer region 10B.

Details of the type of the sub-pixel, the configuration of the sub-pixel, and the configuration of each layer or the like formed in each sub-pixel will be further described.

### (Type of Sub-Pixel)

The display device 10 includes at least a first sub-pixel, a second sub-pixel, and a third sub-pixel as sub-pixels. In the examples of FIGS. 1, 2, and the like, the first sub-pixel, the second sub-pixel, and the third sub-pixel are defined as sub-pixels having different color types as emission colors. In the examples of FIGS. 1A, 1B, 2, and the like, three colors of green, red, and blue are defined as a plurality of color types corresponding to the emission colors of the display device 10. In the examples of FIGS. 1 and 2, three types of a sub-pixel 101G, a sub-pixel 101R, and a sub-pixel 101B are provided as the first sub-pixel, the second sub-pixel, and the third sub-pixel, respectively. The sub-pixel 101R, the sub-pixel 101G, and the sub-pixel 101B are a red sub-pixel, a green sub-pixel, and a blue sub-pixel, respectively, and display red color, green color, and blue color, respectively. However, the examples of FIGS. 1 and 2 are merely examples, and the display device 10 is not limited to a case of including a plurality of sub-pixels corresponding to three color types. Furthermore, wavelengths of light corresponding to the respective color types of red, green, and blue can be defined as, for example, wavelengths in a range of 610 nm to 650 nm (red wavelength band), a range of 510 nm to 590 nm (green wavelength band), and a range of 440 nm to 480 nm (blue wavelength band), respectively. Note that the number of color types of the sub-pixels is not limited to the three colors illustrated here, and may be four colors or the like. Furthermore, the color type of the sub-pixel is not limited to red, green, and blue, and may be yellow, white, or the like. Even in a case where the color type of the sub-pixel is three types of red, green, and blue, the first sub-pixel, the second sub-pixel, and the third sub-pixel are not limited to the case of the sub-pixel 101G, the sub-pixel 101R, and the sub-pixel 101B, respectively. For example, the first sub-pixel, the second sub-pixel, and the third sub-pixel may be the sub-pixel 101G, the sub-pixel 101B, and the sub-pixel 101R, respectively, or may be the sub-pixel 101B, the sub-pixel 101G, and the sub-pixel 101R, respectively.

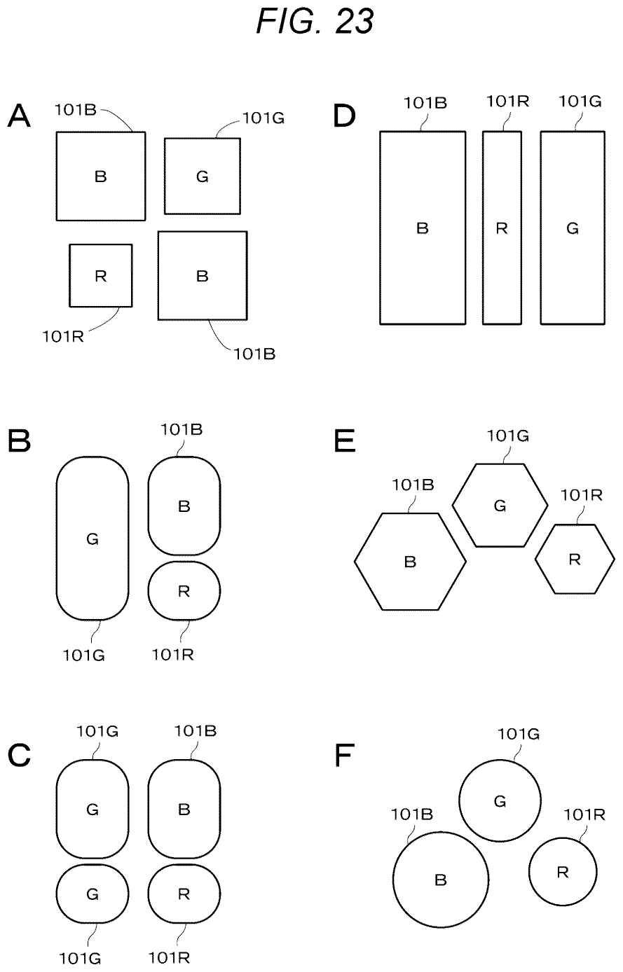

Furthermore, the layout of the sub-pixels 101B, 101R, and 101G in the display device 10 is not particularly limited, but in the example of FIGS. 1A, 1B, 2, and the like, the sub-pixels 101B, 101R, and 101G constituting one pixel are arranged in a predetermined region constituting the display surface DP, and each pixel is two-dimensionally provided. Therefore, in the display device 10 illustrated in the example of FIG. 1B, the plurality of sub-pixels 101B, 101R, and 101G corresponding to the plurality of color types is provided in a two-dimensional and delta-shaped layout. As illustrated in FIGS. 23E, 23 F, and the like in addition to FIG. 1B, the delta-shaped layout indicates a layout in which a triangle is formed by line segments connecting the centers of the plurality of sub-pixels 101 constituting the pixel. Note that FIGS. 1B, 23E, and 23 F are examples, and as will be described later, the layout of the sub-pixels 101B, 101R, and 101G is not limited in the present disclosure. FIGS. 1A and 1B are diagrams for explaining an example of the display region 10A of the display device 10 and the sub-pixel 101. In FIG. 1A, the display region 10A is illustrated as a hatched region. FIGS. 23E and 23F are diagrams illustrating examples of the layout of the sub-pixel 101. In FIG. 23E, the sub-pixel 101 is formed in a hexagonal shape, and in FIG. 23F, the sub-pixel 101 is formed in a circular shape, but these shapes are an example of the shape of the sub-pixel 101.

In the description of the present specification, in a case where the types of the sub-pixels 101R, 101G, and 101B are not particularly distinguished, the sub-pixels 101R, 101G, and 101B are collectively referred to as the sub-pixel 101.

### (Drive of Sub-Pixel)

As illustrated in FIG. 1A, the display device 10 generally includes a control circuit 107, an H driver 105, and a V driver 106, and the control circuit 107 controls driving of the H driver 105 and the V driver 106. The H driver 105 and the V driver 106 control driving of the sub-pixels 101 in units of columns and rows, respectively, in a case where a two-dimensional matrix is allocated to each sub-pixel 101.

### (Configuration of Sub-Pixels)

In the example of FIG. 2, in the display device 10, the sub-pixel 101 includes a light emitting element 104 having an organic layer 14. In the example of FIG. 2, the display device 10 includes a light emitting element 104 on the upper side of a drive substrate 11. Here, as will be described later, the light emitting element 104 has a structure in which a first electrode 13, the organic layer 14, and a second electrode 15 are layered in this order from the side closer to the drive substrate 11 on the upper side of the drive substrate 11.

Next, each configuration of the drive substrate and the like will be described.

### (Drive Substrate)

As illustrated in FIG. 2, in the drive substrate 11, an insulating layer 11B is provided on the substrate 11A, and various circuits for driving the plurality of light emitting elements 104 are provided in the insulating layer 11B. Examples of the various circuits include a drive circuit that controls driving of the light emitting elements 104, and a power supply circuit that supplies power to the plurality of light emitting elements 104 (none of which is illustrated in the drawings). The various circuits are restricted from being exposed to the outside by the insulating layer 11B. Furthermore, the drive substrate 11 is provided with a wiring for connecting the light emitting elements 104, a circuit provided on the substrate 11A, and the like to the first electrode 13 and the like. Examples of the wiring include a plurality of contact plugs.

The substrate 11A may include, for example, glass or resin having low moisture and oxygen permeability, or may include a semiconductor in which a transistor or the like is easily formed. Specifically, the substrate 11A may be a glass substrate, a semiconductor substrate, a resin substrate, or the like.

### (Insulating Layer)

The insulating layer 11B is formed with an organic material or an inorganic material, for example. The organic material contains at least one material of polyimide or acrylic resin, for example. The inorganic material contains at least one material of silicon oxide, silicon nitride, silicon oxynitride, or aluminum oxide, for example.

### (Light Emitting Element)

A plurality of light emitting elements 104 is provided on the first surface side of the drive substrate 11. In the examples of FIGS. 1A, 1B, 2, and the like, the light emitting elements 104 are organic electroluminescent elements (organic EL elements). As the plurality of light emitting elements 104, light emitting elements that set a color corresponding to the color type of the sub-pixel 101 as light emitted (as an emission color) from a light emitting surface are provided. The first sub-pixel includes a first light emitting element as the light emitting element. In the examples of FIGS. 1A, 1B, 2, and the like, the second sub-pixel and the third sub-pixel include a second light emitting element and a third light emitting element as light emitting elements, respectively. For example, the light emitting elements 104R, 104G, and 104B are formed in the sub-pixels 101R, 101G, and 101B, respectively. In the example of FIG. 2, the first light emitting element corresponds to the light emitting element 104G, and the second light emitting element and the third light emitting element correspond to the light emitting element 104R and the light emitting element 104B, respectively. The plurality of light emitting elements 104 is arranged in a layout corresponding to the arrangement of the sub-pixels 101 of the respective color types. The plurality of light emitting elements 104 is arranged in a two-dimensional layout. Note that, in the present specification, in a case where the types such as the light emitting elements 104R, 104G, and 104B are not particularly distinguished, the term light emitting element 104 is used.

The light emitting element 104 has a laminated structure in which the first electrode 13, the organic layer 14, and the second electrode 15 are layered in this order. The first electrode 13, the organic layer 14, and the second electrode 15 are layered in this order from the side of the drive substrate 11 in the direction from the second surface toward the first surface.

### (First Electrode)

A plurality of the first electrodes 13 is provided on the first surface side of the drive substrate 11. In the example of FIG. 2, the first electrode 13 is an anode electrode.

The first electrodes 13 each include at least one of a metal layer or a metal oxide layer. The first electrodes 13 may each include a single-layer film of a metal layer or a metal oxide layer, or a laminated film (multilayer film) of a metal layer and a metal oxide layer. The thickness of the first electrode 13 is preferably in a range of 100 nm to 300 nm. The first electrode 13 is preferably formed with a light reflective material.

The metal layer includes at least one metal element selected from a group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may include the at least one metal element described above as a constituent element of an alloy. Specific examples of the alloy include an aluminum alloy and a silver alloy. Specific examples of the aluminum alloy include, for example, AlNd and AlCu.

The metal oxide layer includes at least one of a mixture of indium oxide and tin oxide (ITO), a mixture of indium oxide and zinc oxide (IZO), or titanium oxide (TiO), for example.

Furthermore, the first electrode 13 may have a configuration in which a layer of a hole injection material of an inorganic material and a reflection layer including a light reflection material are laminated. For example, in a case where the first electrode 13 has a structure in which a first material layer and a second material layer are laminated, the first material layer may include an aluminum alloy, and the second material layer may be include an inorganic material such as Ti, TiO, Mo, or MoO3.

In FIG. 2, the first electrodes 13 are electrically separated for respective sub-pixels 101. That is, a plurality of the first electrodes 13 is provided on the first surface side of the drive substrate 11, and is provided for respective sub-pixels 101.

### (Inter-Pixel Insulating Layer)

Furthermore, a layer having insulating properties (inter-pixel insulating layer 12) is preferably formed between the first electrodes 13 adjacent to each other. The inter-pixel insulating layer 12 is formed between the first electrodes 13 adjacent to each other. However, the inter-pixel insulating layer 12 may be a layer formed with the same material as the insulating layer 11B, or may be a layer formed with a material different from the insulating layer 11B. In the example of FIG. 2 and the like, the inter-pixel insulating layer 12 electrically insulates each first electrode 13 for each light emitting element 104 (that is, for each sub-pixel 101). Furthermore, in the inter-pixel insulating layer 12 illustrated in the example of FIG. 2, an opening 12A is formed on the first surface side, the first surface of the first electrode 13 (the surface facing the second electrode 15) is exposed from the opening 12A, and the portion of the first electrode 13 exposed through the opening 12A directly faces the organic layer 14 described later without interposing the insulating layer 11B. Note that in the example of FIG. 2, an end edge 26 of the opening 12A is illustrated as being in contact with the end edge of the first electrode 13, but this is an example.

In a case where a direction along the thickness direction (Z-axis direction) of the light emitting element 104 is a line-of-sight direction, a portion (a portion where the organic layer 14 and the first electrode 13 directly face each other) of each light emitting element 104 specified as a portion (a portion where the first electrode 13 and the organic layer 14 directly face each other) where the first electrode 13 and the organic layer 14 face each other while avoiding interposition of the insulating layer 11B is defined as a light emitting unit K.

Note that the inter-pixel insulating layer 12 may be formed not only between the first electrodes 13 adjacent to each other but also so as to ride on the edge portion of the first electrode 13 as illustrated in FIGS. 3A and 3B. In FIGS. 3A and 3B, the edge portion of the first electrode 13 is defined by a portion from the outer peripheral edge of the first electrode 13 to a predetermined position closer to the center side of the first electrode 13. Also in this case, the inter-pixel insulating layer 12 has the opening 12A, and the first surface of the first electrode 13 is exposed from the opening 12A. FIG. 3A is a cross-sectional view schematically illustrating an example of a state of a longitudinal cross section taken along line A-A in FIG. 1B. FIG. 3B is a cross-sectional view schematically illustrating an example of a state of a longitudinal cross section taken along line B-B in FIG. 1B. Note that in FIGS. 3A and 3B, a second organic layer 14A2, a second electrode 15A2, a second protective layer 16A2, a sealing resin layer 23, and a counter substrate 24 are not illustrated for convenience of description.

It is sufficient that a region where the inter-pixel insulating layer 12 is formed is formed at least in a region corresponding to a continuous portion 103 to be described later in a case where the thickness direction of the display device 10 is the line-of-sight direction (the Z-axis direction in the example of FIG. 2), and may be locally formed only in the region corresponding to the continuous portion 103, for example.

### (Organic Layer)

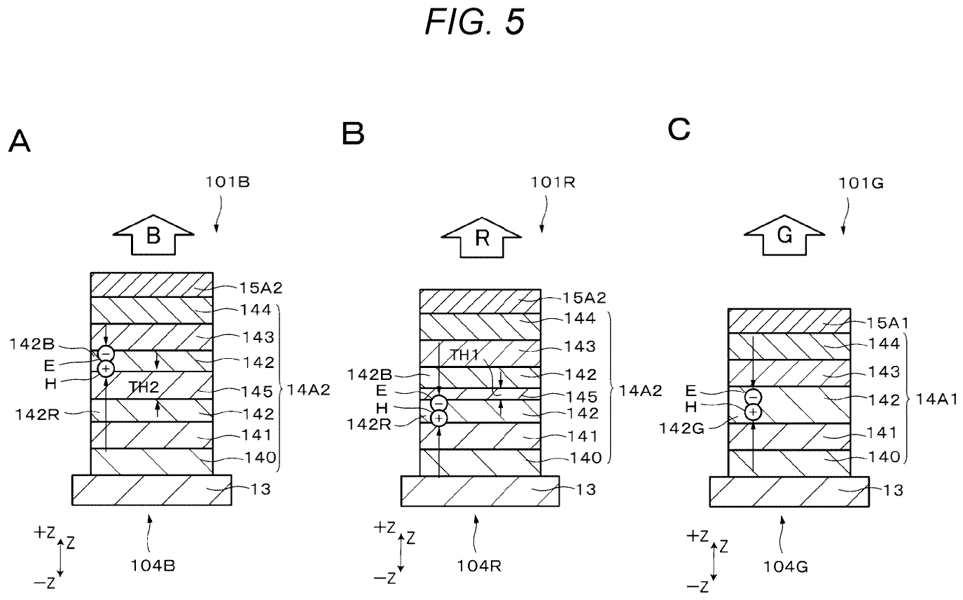

The organic layer 14 is provided on the first electrode 13. The organic layer 14 is provided at least between the first electrode 13 and the second electrode 15. In the display device 10 illustrated in the example of FIG. 2, as illustrated in FIGS. 5A to 5C, the light emitting element 104G (the light emitting element 104 corresponding to the sub-pixel 101G) serving as the first light emitting element includes a first organic layer 14A1 as the organic layer 14, and the light emitting elements 104R and 104B serving as the second light emitting element and the third light emitting element respectively include a second organic layer 14A2 as the organic layer 14. The second organic layer 14A2 is isolated from the first organic layer 14A1. In the first embodiment, the second organic layer 14A2 forms a continuous layer such that a portion corresponding to the second light emitting element and a portion corresponding to the third light emitting element are connected. FIGS. 5A to 5C are cross-sectional views schematically illustrating an example of a layer structure of the light emitting element 104 corresponding to the sub-pixel 101. In FIGS. 5A to 5C, an arrow G, an arrow R, and an arrow B indicate emission colors (green, red, and blue, respectively) and light directions of the light emitting elements 104G, 104R, and 104B, respectively.

In the example of FIG. 2, the first organic layer 14A1 is a layer included in the configuration of the light emitting element 104G, and is configured to be able to emit green light. The second organic layer 14A2 is a layer (in the example of FIG. 2, a layer having a material common to the sub-pixel 101R and the sub-pixel 101B) having a material common to the light emitting elements 104R and 104B. Note that the emission color of the organic layer 14 described above is an example, and may be determined according to the combination of the sub-pixels 101, and is not prohibited from being other than the color type described above.

In the example of FIG. 2, the organic layer 14 includes a light emitting layer 142 as illustrated in FIGS. 5A to 5C. The organic layer 14 is a so-called organic EL layer.

In the example of the first embodiment illustrated in FIG. 2, the first organic layer 14A1 is formed in a layout corresponding to a shape formed by the sub-pixel 101G and the continuous portion 103 as illustrated in FIG. 1B. That is, the first organic layer 14A1 is connected between the sub-pixels 101G adjacent to each other and extends along the arrangement direction of the sub-pixels 101G. Furthermore, in the example of FIG. 2, the second organic layer 14A2 spreads in the plane direction of the display region 10A and is formed so as to substantially cover the entire sub-pixel 101.

### (First Organic Layer)

As illustrated in FIG. 5C, for example, the first organic layer 14A1 has a configuration in which a hole injection layer 140, a hole transport layer 141, a light emitting layer 142, and an electron transport layer 143 are laminated in this order from the first electrode 13 toward the second electrode 15A1. An electron injection layer 144 may be provided between the electron transport layer 143 and the second electrode 15. The electron injection layer 144 is for enhancing electron injection efficiency. The electron injection layer 144 includes a simple substance of an alkali metal or an alkaline earth metal or a compound containing the same, for example, lithium (Li), lithium fluoride (LiF), or the like. Note that the configuration of the first organic layer 14A1 is not limited thereto, and layers other than the light emitting layer 142 are provided as necessary.

The hole injection layer 140 is a buffer layer for enhancing efficiency of hole injection into the light emitting layer 142 and suppressing leakage. The hole injection layer 140 may include, for example, hexaazatriphenylene (HAT) or the like.

The hole transport layer 141 is for enhancing efficiency of hole transport to the light emitting layer 142. The hole transport layer 141 includes, for example, α-NPD [N,N′-di(1-naphthyl)-N, N′-diphenyl-[1,1′-biphenyl]-4,4′-diamine].

The electron transport layer 143 is for enhancing efficiency of electron transport to the light emitting layer 142. As the electron transport layer 143, for example, BCP (2,9-dimethyl-4,7-diphenyl-1,10-phenanthroline), Alq3 (aluminum quinolinol), Bphen (bathophenanthroline), or the like is used. The electron transport layer includes at least one layer, and may include a layer doped with an alkali metal or an alkaline earth metal.

In a case where the electron transport layer 143 includes a layer doped with an alkali metal or an alkaline earth metal, for example, a host material of BCP (2,9-dimethyl-4,7-diphenyl-1,10-phenanthroline), Alq3 (aluminum quinolinol), Bphen (bathophenanthroline), or the like is doped by co-evaporation with, for example, 0.5 to 15 wt % of a dopant material of an alkali metal such as lithium (Li), sodium (Na), potassium (K), rubidium (Rb), or cesium (Cs) or an alkaline earth metal such as magnesium (Mg), calcium (Ca), strontium (Sr), or barium (Ba).

As illustrated in FIG. 5C, the light emitting layer 142 generates light by recombination of electrons (E) and holes (H) by applying an electric field. The light emitting layers 142 are organic compound layers including an organic light emitting material. In FIG. 5C, for convenience of description, holes (H) and electrons (E) are schematically illustrated, and the movements thereof are indicated by arrows. The similarity applies to FIGS. 5A and 5B.

In the example of FIG. 2, the light emitting layer 142 in the first organic layer 14A1 is a green light emitting layer 142G. In the green light emitting layer 142G, when an electric field is applied, some of holes (H) injected from the first electrode 13 through the hole injection layer 140 and the hole transport layer 141 and some of electrons (E) injected from the second electrode 15 through the electron transport layer 143 are recombined to generate green light.

The green light emitting layer 142G includes, for example, at least one of a green light emitting material, a hole transport material, an electron transport material, or both-charges transport material. The green light emitting material may be fluorescent or phosphorescent. Specifically, the green light emitting layer 142G includes, for example, a mixture of DPVBi and 5 wt % of coumarin 6. Examples of the hole transport material include a material that can be used as a material constituting the hole transport layer 141. Examples of the electron transport material include a material that can be used as a material constituting the electron transport layer 143. Examples of the both-charges transport material include a material having hole transporting properties and electron transporting properties.

The optical thickness of the organic layer 14 and the optical thickness of each layer constituting the organic layer 14 are set to values that enable the movement of recombination of electrons and holes corresponding to the wavelength associated with the color type of the sub-pixel 101. The thickness of each layer constituting the organic layer 14 is preferably a thickness in consideration of the optical thickness of each layer constituting the organic layer 14. Specifically, the thickness of each layer constituting the organic layer 14 is preferably set in a range of 1 to 20 nm for the hole injection layer 140, 10 to 200 nm for the hole transport layer 141, 5 to 50 nm for the light emitting layer 142, and 10 to 200 nm for the electron transport layer 143.

### (Second Organic Layer)

A second organic layer 14A2 has a configuration in which, for example, the hole injection layer 140, the hole transport layer 141, the light emitting layer 142 (first light emitting layer), a light emission separation layer 145, the light emitting layer 142 (second light emitting layer), and the electron transport layer 143 are laminated in this order from the first electrode 13 toward the second electrode 15 (in FIG. 1, the second electrode 15A2). The electron injection layer 144 may be provided between the electron transport layer 143 and the second electrode 15A2. The electron injection layer 144 is for enhancing the electron injection efficiency as described in the first organic layer 14A1. Note that the configuration of the second organic layer 14A2 is not limited thereto, and layers other than the plurality of light emitting layers 142 (the first light emitting layer and the second light emitting layer) and the light emission separation layer 145 are provided as necessary.

As the respective layers of the hole injection layer 140, the hole transport layer 141, and the electron transport layer 143 shown in the example of the layer configuration of the second organic layer 14A2, layers similar to the respective layers of the hole injection layer 140, the hole transport layer 141, and the electron transport layer 143 described in the first organic layer 14A1 may be used.

In the example of FIG. 2, the first light emitting layer and the second light emitting layer in the second organic layer 14A2 are layers having different light emission peak wavelengths, and are the red light emitting layer 142R and the blue light emitting layer 142B, respectively, as illustrated in FIGS. 5A and 5B. Note that the color types of the first light emitting layer and the second light emitting layer are not limited to the examples of FIGS. 5A and 5B, and may be changed according to the color type of the light emitting element 104.

In the red light emitting layer 142R, when an electric field is applied, some of holes (holes) (H) injected from the first electrode 13 through the hole injection layer 140 and the hole transport layer 141 and some of electrons (E) injected from the second electrode 15A2 through the electron transport layer 143 are recombined to generate red light.

The red light emitting layer 142R includes, for example, at least one of a red light emitting material, a hole transport material, an electron transport material, or both-charges transport material. The red light emitting material may be fluorescent or phosphorescent. Specifically, the red light emitting layer 142R includes, for example, a mixture of 4,4-bis(2,2-diphenylvinyl) biphenyl (DPVBi) and 30 wt % of 2,6-bis[(4′-methoxy-diphenylamino)-styryl]-1,5-dicyanonaphthalene (BSN).

In the blue light emitting layer 142B, when an electric field is applied, some of holes (H) injected from the first electrode 13 through the hole injection layer 140, the hole transport layer 141, and the light emission separation layer 145 and some of electrons (E) injected from the second electrode 15A2 through the electron transport layer 143 are recombined to generate blue light.

The blue light emitting layer 142B includes, for example, at least one of a blue light emitting material, a hole transport material, an electron transport material, or both-charges transport material. The blue light emitting material may be fluorescent or phosphorescent. Specifically, the blue light emitting layer 142B includes, for example, a mixture of DPVBi and 2.5 wt % of 4,4′-bis[2-{4-(N, N-diphenylamino)phenyl} vinyl] biphenyl (DPAVBi).

The light emission separation layer 145 is arranged between the first light emitting layer and the second light emitting layer and is a layer for adjusting injection of carriers into the light emitting layer 142, and light emission balance of each color is adjusted by injecting electrons or holes into the light emitting layer 142 via the light emission separation layer 145. The light emission separation layer 145 includes, for example, 4,4′-bis[N-(1-naphthyl)-N-phenylamino]biphenyl derivatives, or the like.

In the light emission separation layer 145, the thickness of the light emission separation layer 145 is different between the portion corresponding to the second sub-pixel and the portion corresponding to the third sub-pixel, and the thickness of the light emission separation layer 145 formed in the second sub-pixel is formed to be smaller than the thickness of the light emission separation layer 145 formed in the third sub-pixel. In the example of FIG. 2, as illustrated in FIGS. 5A and 5B, a thickness TH1 of the light emission separation layer 145 of the sub-pixel 101R is formed to be smaller than a thickness TH2 of the light emission separation layer 145 formed in the sub-pixel 101B.

The thickness of the light emission separation layer 145 of the second sub-pixel and the thickness of the light emission separation layer 145 of the third sub-pixel are preferably set within a range of 0 nm to 20 nm.

Since the thickness of the light emission separation layer 145 of the second sub-pixel (sub-pixel 101R) is different from the thickness of the light emission separation layer 145 of the third sub-pixel (sub-pixel 101B), regarding the light emission balance between the light emission (red light emission) of the red light emitting layer 142R and the light emission (blue light emission) of the blue light emitting layer 142B, the light emission balance of the second sub-pixel and the light emission balance of the third sub-pixel can be made different. In the example of FIG. 2, the red light emission intensity increases in the sub-pixel 101R, and the blue light emission intensity increases in the sub-pixel 101B. Therefore, the light emission efficiency can be improved according to the sub-pixel 101.

### (Second Electrode)

The second electrode 15 is provided on the upper side of the organic layer 14. A portion (a portion corresponding to the light emitting element 104) of the second electrode 15 corresponding to the sub-pixel 101 faces the first electrode 13. As the second electrode 15, an electrode (second electrode 15A1) provided on the upper side of the first organic layer 14A1 and an electrode (second electrode 15A2) provided on the upper side of the second organic layer 14A2 are provided. The second electrode 15A2 is provided as an electrode for the sub-pixel 101G. The second electrode 15A2 is provided as an electrode common to the sub-pixels 101R and 101B. Note that in the description of the present specification, in a case where the types of the second electrode 15A1 and the second electrode 15A2 are not particularly distinguished, the second electrode 15A1 and the second electrode 15A2 are collectively referred to as the second electrode 15.

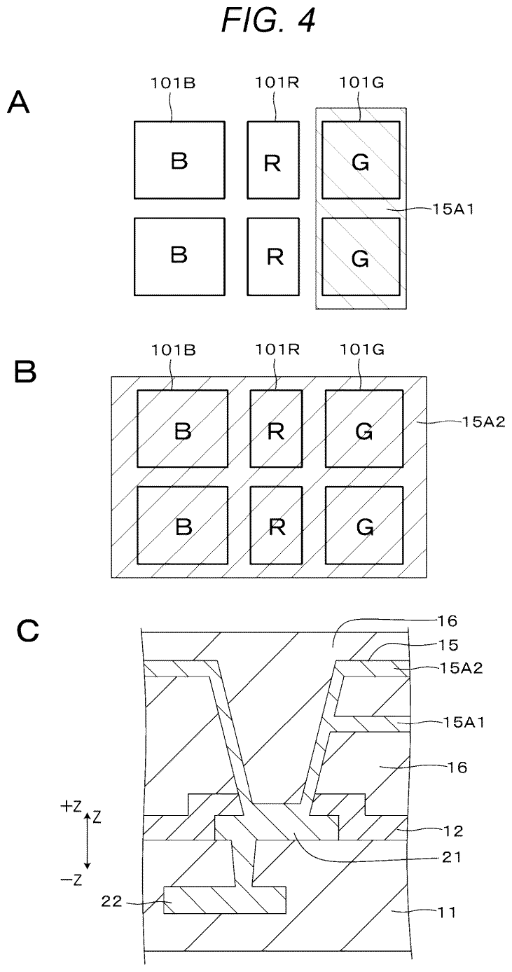

As illustrated in FIG. 4A, the second electrode 15A1 is connected between the sub-pixels 101G adjacent to each other and extends along the arrangement direction of the sub-pixels 101G. Furthermore, as illustrated in FIG. 4B, the second electrode 15A2 spreads in the plane direction of the display region 10A, and is formed so as to substantially cover the entire sub-pixel 101. FIGS. 4A and 4B are diagrams for explaining formation regions of the second electrodes 15A1 and 15A2. In FIGS. 4A and 4B, hatched regions indicate the formation regions of the second electrodes 15A1 and 15A2. Note that, in FIGS. 4A and 4B, for convenience of description, each of the sub-pixels 101B, 101R, and 101G is formed in a rectangular shape, and the layout of the sub-pixels 101 is in a lattice shape.

The second electrode 15 is a cathode electrode. The second electrode 15 is preferably a transparent electrode having transparency to light generated in the organic layer 14. The transparent electrode referred to herein includes a transparent electrode including a transparent conductive layer and a transparent electrode having a structure including a transparent conductive layer and a semitransmissive reflection layer.

The thickness of the second electrode 15 is not particularly limited, but is preferably set in a range of 3 nm to 500 nm. Note that in a case where the second electrode 15 is a transparent conductive layer, for example, in a case where the second electrode 15 includes indium zinc oxide (IZO), the thickness of the second electrode 15 may be set in a range of 10 nm to 500 nm, for example.

As the second electrode 15, a material having excellent optical transparency and a small work function is preferably used. Furthermore, the second electrode 15 can include, for example, a metal layer. For example, the second electrode 15 includes a metal layer of IZO, magnesium (Mg), silver (Ag), an alloy thereof, or the like. Furthermore, the second electrode 15 may be a multilayer film. In a case where the second electrode 15 is a film in which the second layer is laminated on the first layer, for example, a metal layer such as calcium (Ca), barium (Ba), lithium (Li), lithium fluoride (LiF), cesium (Cs), indium (In), magnesium (Mg), silver (Ag), an alloy thereof, or the like may be adopted as the first layer, and a metal layer such as magnesium (Mg), silver (Ag), an alloy thereof, or the like may be adopted as the second layer. Furthermore, the multilayer film of the second electrode 15 may include the same kind of material, for example, the first layer and the second layer may be alloy metal layers of magnesium (Mg) and silver (Ag), laminated at different concentrations, and for example, the Ag concentration of the first layer (lower layer) may be set lower while the Ag concentration of the second layer (upper layer) may be set higher. Since the second electrode 15 is the multilayer film exemplified above, it is possible to enhance the light extraction efficiency while enhancing the electron injection property.

### (Protective Layer)

The protective layer 16 is formed so as to cover the first surface of the light emitting element 104. The protective layer 16 makes it difficult for the first surface of the light emitting element 104 to come into contact with the outside air, and suppresses the infiltration of moisture into the light emitting element 104 from the external environment.

In the example of FIG. 2, a first protective layer 16A1 and a second protective layer 16A2 are provided as the protective layer 16.

### (First Protective Layer)

A first protective layer 16A1 covers the first light emitting element (the sub-pixel 101G in the example of FIG. 2). The first protective layer 16A1 includes an upper surface protective layer 17 covering the second electrode 15A1 and an end surface protective layer 18. The end surface protective layer 18 covers the first surface of the upper surface protective layer 17 and an end surface 20G (side wall) of the first light emitting element (the light emitting element 104G in the example of FIG. 1). The end surface protective layer 18 covers respective end surfaces 20R and 20B of the second light emitting element (the light emitting element 104R in the example of FIG. 2) and the third light emitting element (the light emitting element 104B in the example of FIG. 2).

As the material of the first protective layer 16A1, a material having low permeability and low water permeability is preferably used for both the upper surface protective layer 17 and the end surface protective layer 18. The thickness of the first protective layer 16A1 is preferably 1 μm to 5 μm.

Furthermore, regarding the material of the first protective layer 16A1, both the upper surface protective layer 17 and the end surface protective layer 18 include an insulating material. Examples of the insulating material include silicon nitride (SiNx), silicon oxide (SiOx), aluminum oxide (Alox), titanium oxide (TiOx), or a combination thereof. Furthermore, as the insulating material, a thermosetting resin or the like can be used. Examples of the upper surface protective layer 17 and the end surface protective layer 18 include a CVD film including Sio, SiON, or the like, an ALD film including AlO, TiO, SiO, or the like, and the like. Note that the CVD film indicates a film formed using chemical vapor deposition. The ALD film indicates a film formed using atomic layer deposition. The upper surface protective layer 17 and the end surface protective layer 18 may be formed to be one layer or may have a structure in which a plurality of layers are laminated. For example, the upper surface protective layer 17 and the end surface protective layer 18 may have a structure in which a CVD film and an ALD film are laminated.

### (Opening)

The first protective layer 16A1 has an opening, and in the example of FIG. 2, a first opening 19A and a second opening 19B are formed as the opening. The first opening 19A and the second opening 19B are formed in portions corresponding to the sub-pixel 101R and the sub-pixel 101B, respectively. In the present specification, in a case where the first opening 19A and the second opening 19B are not particularly distinguished, they are simply collectively referred to as the opening.

In the display device 10, the first protective layer 16A1 has different opening shapes of the first opening 19A and the second opening 19B. In the example of FIG. 2, in the end surface protective layer 18 of the light emitting element 104G formed in the sub-pixel 101G, the first opening 19A and the second opening 19B are formed at positions corresponding to the sub-pixel 101R and the sub-pixel 101B, respectively. The description that the opening shapes of the first opening 19A and the second opening 19B are different from each other indicates that the contour shapes of the first opening 19A and the second opening 19B do not match each other, and includes a case where the contour shapes of the first opening 19A and the second opening 19B are similar to each other.

In the example of FIG. 2, an opening width WA of the first opening 19A and the opening width WB of the second opening 19B formed in the end surface protective layer 18 of the first light emitting element are different from each other, and the opening width WA of the first opening 19A is smaller (narrower) than the opening width WB of the second opening 19B.

The sizes of the opening width WA of the first opening 19A and the opening width WB of the second opening 19B are only required to be determined according to the color type of the sub-pixel 101 or the layer configuration of the light emitting element 104, and are not particularly limited, but are preferably set within a range of approximately 1 μm to 10 μm. In a case where the first opening 19A and the second opening 19B are not particularly distinguished, they are collectively referred to as the opening. Furthermore, in a case where the opening width WA of the first opening 19A and the opening width WB of the second opening 19B are not particularly distinguished, they are collectively referred to as the opening width of the opening.

Note that the opening width of the opening indicates a separation distance between the end edges on the first surface side of the opening in the cross section of the protective layer 16. In the example of FIG. 1, in the sub-pixel 101R, the opening width WA of the first opening 19A is set to a value larger than the width of the light emitting unit K which is a region where the first electrode 13 and the organic layer 14 face each other (a region where the opening 12A of the inter-pixel insulating layer 12 is formed). In the sub-pixel 101B, the opening width WB of the second opening 19B is set to a value larger than the width of the light emitting unit K, similarly to the sub-pixel 101R.

### (Second Protective Layer)

The second protective layer 16A2 preferably covers the entire region of the display region 10A. The thickness of the second protective layer 16A2 is formed to be approximately 0.5 μm to 8 μm.

Examples of the material of the second protective layer 16A2 include a material having low permeability and low water permeability, and examples thereof include a material similar to that of the first protective layer 16A1.

### (Continuous Portion)

The first sub-pixels (the sub-pixels 101G in FIG. 2) adjacent to each other are preferably connected by the continuous portion 103 as illustrated in FIGS. 1B, 3B, and the like. The continuous portion 103 has a structure in which the first organic layer 14A1 and the second electrode 15A1 are laminated. In the display device 10, the second electrode 15A1 provided in the sub-pixel 101G is connected to the second electrode 15A1 of the continuous portion 103, so that the second electrodes 15A1 of the sub-pixels 101G adjacent to each other are electrically connected. Furthermore, the first organic layer 14A1 provided in the sub-pixel 101G is also connected to the first organic layer 14A1 of the continuous portion 103, so that the first organic layers 14A1 of the sub-pixels 101G adjacent to each other are electrically connected. Since the continuous portion 103 is formed in this manner, it is possible to form a state where the laminated structures of the second electrodes and the first organic layers formed in the plurality of first light emitting elements are connected to each other. Then, in a case where an auxiliary electrode 21 as described later is provided outside the display region 10A, by connecting the second electrode 15A1 to the auxiliary electrode 21, it is possible to easily control energization of the sub-pixel 101 in the display region 10A.

### (Auxiliary Electrode)

On the outside of the display region 10A, as illustrated in FIG. 4C, the auxiliary electrode 21 is preferably provided on the drive substrate 11, and the second electrode 15A1 and the second electrode 15A2 are preferably connected to the auxiliary electrode 21. The second electrode 15 connected to the auxiliary electrode 21 may be electrically connected to a potential supply wiring 22 formed on the drive substrate 11 side via the auxiliary electrode 21 and the like. The auxiliary electrode 21 is preferably configured to be electrically connectable to the outside via the potential supply wiring 22 and the like or directly. The auxiliary electrode 21 may include a material similar to that of the first electrode 13 and the like. FIG. 4C is a diagram illustrating an example of a connection structure between the auxiliary electrode 21 and the second electrode 15 outside display region 10A. Note that for convenience of description, the second electrode 15, the auxiliary electrode 21, and the potential supply wiring 22 are indicated by the same hatching.

### (Sealing Resin Layer)

In the example of FIG. 2, a sealing resin layer 23 is formed on the first surface side of the second protective layer 16A2. The sealing resin layer 23 has a function as an adhesive layer for bonding the counter substrate 24 to be described later. Examples of the sealing resin layer 23 can include an ultraviolet curable resin, a thermosetting resin, and the like.

### (Counter Substrate)

The counter substrate 24 may be provided on the first surface side of the sealing resin layer 23. As the material of the counter substrate 24, the material of the substrate 11A of the drive substrate 11 and the like can be used. For example, a glass substrate can be used as the counter substrate 24. The material of the glass substrate is not particularly limited as long as the glass substrate is formed with a material that transmits light emitted from the organic layer 14. Examples of the material of the glass substrate include various glass substrates such as high strain point glass, soda glass, borosilicate glass, and lead glass, quartz substrates, and the like.

### 1-2 Manufacturing Method

A method of manufacturing the display device 10 according to the first embodiment includes a process of forming a first light emitting element having a first organic layer at a position corresponding to a first sub-pixel, and a process of forming a protective layer covering the first light emitting element. Furthermore, the method further includes a process of forming a first opening and a second opening at positions corresponding to a second sub-pixel and a third sub-pixel in the protective layer so as to have opening shapes different from each other. The method further includes a process of forming a second organic layer in portions corresponding to the first opening and the second opening, the second organic layer forming a second light emitting element and a third light emitting element corresponding to the second sub-pixel and the third sub-pixel, respectively, and having a common material.

Next, an example of the method of manufacturing the display device 10 according to the first embodiment will be described. The manufacturing method can be performed, for example, as follows. First, for example, a transistor, a wiring layer necessary for driving the sub-pixel 101, and an insulating layer 11B are formed on the substrate 11A including a semiconductor material such as silicon. The wiring layer is provided with wirings, vias, and the like, the wirings can be formed by a lithography technique using a material such as aluminum (Al), for example, and the vias can be formed using a material such as tungsten (W).

The first electrode 13 is formed on the drive substrate 11 on which the wiring layer, the insulating layer 11B, and the like are formed. The first electrode 13 is formed by patterning using a sputtering method or the like.

An insulating material layer is entirely formed over the entire region, which includes the first surface of the first electrode 13, on the first surface side of the drive substrate 11. The material of the insulating material layer is an insulating material constituting the inter-pixel insulating portion. The insulating material layer is, for example, a SiNx film or the like.

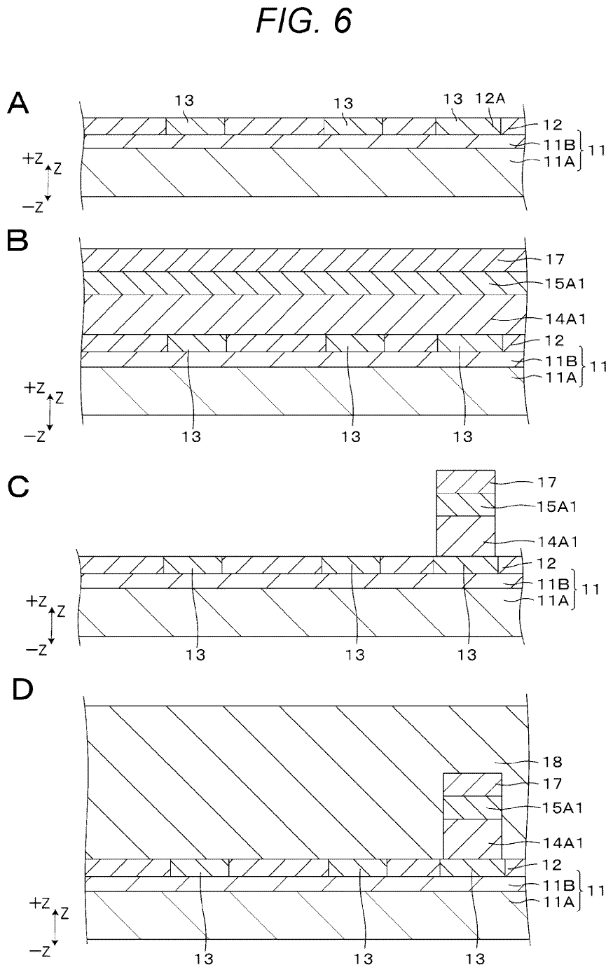

The insulating material layer is patterned using a patterning technique such as lithography or etching to form the opening 12A corresponding to the sub-pixel 101, and the upper surface of the first electrode is exposed from the opening 12A. Therefore, as illustrated in FIG. 6A, the inter-pixel insulating layer 12 and the first electrode 13 can be formed on the drive substrate 11.

The first organic layer 14A1 is formed over the entire region on the first surface side so as to cover the inter-pixel insulating layer 12 and the first electrode 13. The first organic layer 14A1 is formed by the hole injection layer 140, the hole transport layer 141, the light emitting layer 142, the electron transport layer 143, and the electron injection layer 144 in this order. As a method of forming each layer of the hole injection layer 140, the hole transport layer 141, the light emitting layer 142, the electron transport layer 143, and the electron injection layer 144, for example, a vapor deposition method can be used.

The second electrode 15A1 is formed over the entire exposure surface side (first surface side) of the first organic layer 14A1 by the sputtering method or the like so as to cover the first organic layer 14A1. Examples of the second electrode 15A1 include an IZO film formed by the sputtering method. As illustrated in FIG. 6B, the upper surface protective layer 17 is formed on the entire exposure surface (a surface on the +Z direction side) of the second electrode 15A1. Examples of the upper surface protective layer 17 include a SiN film formed by a CVD method.

The laminated structure of the first organic layer 14A1, the second electrode 15A1, and the upper surface protective layer 17 is processed by a dry etching method according to the layout of the first sub-pixel, and some of the first organic layer 14A1, the second electrode 15A1, and the upper surface protective layer 17 are removed such that a portion corresponding to the first sub-pixel (sub-pixel 101G) and a portion corresponding to the continuous portion 103 remain. At this time, as illustrated in FIG. 6C, the first light emitting element (light emitting element 104G) is formed.

Next, as illustrated in FIG. 6D, the end surface protective layer 18 is formed, so as to cover the end surface 20G (the end surface of the laminated structure of the first organic layer 14A1, the second electrode 15A1, and the upper surface protective layer 17) of the light emitting element 104G and the upper surface protective layer 17, on the entire surface thereof. Examples of the end surface protective layer 18 include a SiN film formed by a CVD method. The end surface protective layer 18 and the upper surface protective layer 17 form the first protective layer 16A1.

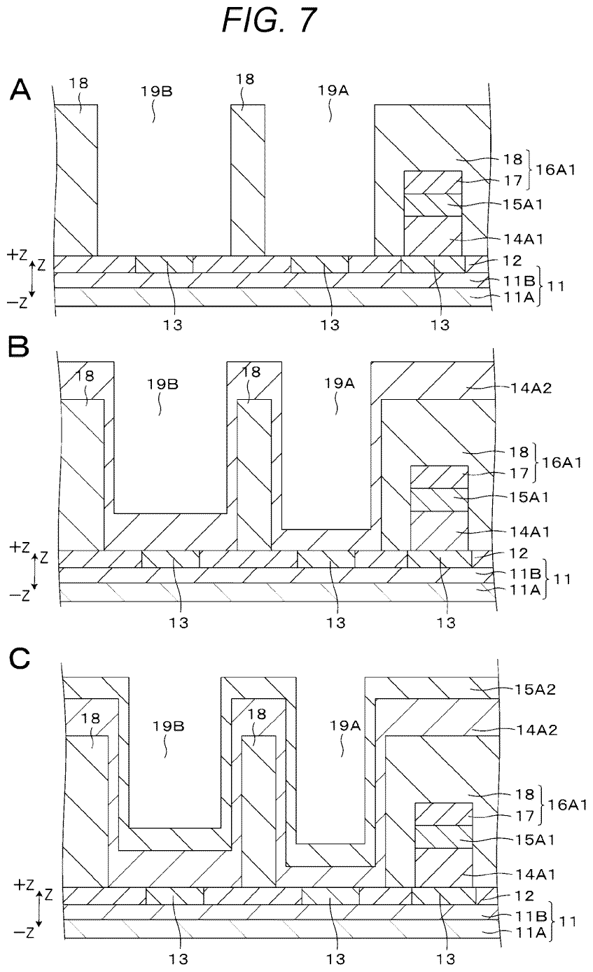

In the end surface protective layer 18, as illustrated in FIG. 7A, the first opening 19A and the second opening 19B are formed as openings in portions corresponding to the second sub-pixel and the third sub-pixel (the sub-pixel 101R and the sub-pixel 101B). The first opening 19A and the second opening 19B can be formed, for example, by applying the dry etching method to the end surface protective layer 18 so as to have the opening widths of the first opening 19A and the second opening 19B.

Furthermore, the second organic layer 14A2 forming the light emitting elements 104 corresponding to the second sub-pixel and the third sub-pixel respectively is formed in portions corresponding to the first opening 19A and the second opening 19B as follows.

The first electrode 13 is exposed at the positions of the first opening 19A and the second opening 19B. As illustrated in FIG. 7B, the second organic layer 14A2 is formed, so as to cover the first electrode 13 and the first protective layer 16A1, on one surface thereof. The second organic layer 14A2 is formed by the hole injection layer 140, the hole transport layer 141, the first light emitting layer (red light emitting layer 142R), the light emission separation layer 145, the second light emitting layer (blue light emitting layer 142B), the electron transport layer 143, and the electron injection layer 144 in this order. The second organic layer 14A2 is formed over the entire surface of the first surface side of the first protective layer 16A1 and the entire surface of the first electrode 13 exposed from the first opening 19A and the second opening 19B.

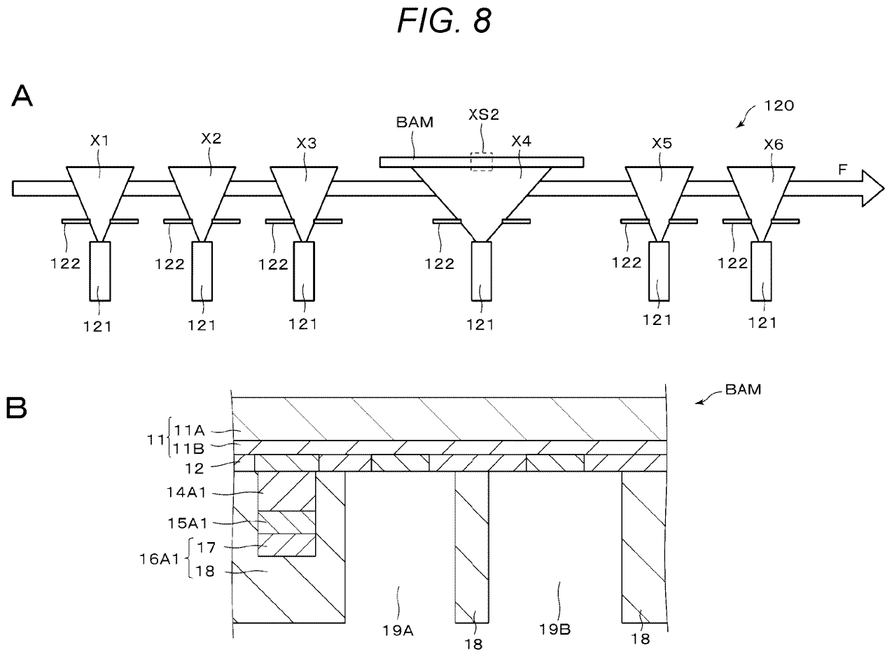

Examples of a method of forming each layer for forming the second organic layer 14A2 include a vapor deposition method. The method for forming the second organic layer 14A2 by the vapor deposition method can be performed, for example, in a manufacturing line 120 as illustrated in FIG. 8A. In the manufacturing line 120, a vapor deposition source 121 and a limiting plate 122 corresponding to respective layers constituting the second organic layer 14A2 are arranged. A thick arrow F in FIG. 8A indicates a transfer method of a substrate BAM to be deposited. As illustrated in FIGS. 8A and 8B, a deposition material X1 to a deposition material X6 are sequentially scattered from the vapor deposition source 121 to the substrate BAM in a state where the substrate BAM is arranged such that the first electrode 13 and the first protective layer are directed toward the vapor deposition source 121 side, whereby each layer for forming the second organic layer 14A2 can be sequentially formed on the first electrode 13 and the first protective layer by the vapor deposition method. FIG. 8B is a cross-sectional view schematically illustrating a state where a region XS2 portion surrounded by a broken line in FIG. 8A is enlarged. Note that in the example of FIG. 8A, the vapor deposition material X1 is a material forming the hole injection layer 140, the vapor deposition material X2 is a material forming the hole transport layer 141, the vapor deposition material X3 is a material forming the red light emitting layer 142R, the vapor deposition material X4 is a material forming the light emission separation layer 145, the vapor deposition material X5 is a material forming the blue light emitting layer 142B, and the vapor deposition material X6 is a material forming the electron transport layer 143. Note that in FIG. 8A, the vapor deposition source 121 and the limiting plate 122 for forming the electron injection layer 144 are not illustrated for convenience of description.

When the light emission separation layer 145 is formed by the vapor deposition method, vapor deposition is performed while changing a film formation width. The film formation width when the light emission separation layer 145 is formed by the vapor deposition method is larger than the film formation width when each layer (the hole injection layer 140 and the like) other than the light emission separation layer 145 constituting the second organic layer 14A2 is formed by the vapor deposition method. In the manufacturing line 120 illustrated in FIG. 8A, regarding the opening width of the limiting plate 122 provided in the vapor deposition source 121 for forming each layer, the opening width of the limiting plate 122 corresponding to the vapor deposition source 121 when the light emission separation layer 145 is formed by the vapor deposition method is larger than the opening width of the limiting plate 122 corresponding to the vapor deposition source 121 when each layer (the hole injection layer 140 and the like) other than the light emission separation layer 145 constituting the second organic layer 14A2 is formed by the vapor deposition method. Therefore, when each layer (the hole injection layer 140 and the like) other than the light emission separation layer 145 constituting the second organic layer 14A2 is formed by the vapor deposition method, vapor deposition with high directivity is performed, and thus, even if the first opening 19A and the second opening 19B are different from each other, the hole injection layer 140 of the light emitting element 104R and the hole injection layer 140 of the light emitting element 104B are less likely to have different thicknesses.

When the light emission separation layer 145 constituting the second organic layer 14A2 is formed by a vapor deposition method, vapor deposition with reduced directivity is performed, and thus the difference between the first opening 19A and the second opening 19B allows the thickness of the light emission separation layer 145 to effectively vary depending on the sub-pixel 101. Specifically, as illustrated in FIG. 7B, in a case where the opening width of the second opening 19B is larger than the opening width of the first opening 19A, the thickness of the light emission separation layer 145 of the light emitting element 104B corresponding to the sub-pixel 101B can be made larger than the thickness of the light emission separation layer 145 of the light emitting element 104R corresponding to the sub-pixel 101R.

As illustrated in FIG. 7C, the second electrode 15A2 is formed on the first surface side of the second organic layer 14A2. As the second electrode 15A2, an IZO film or the like is used. The second electrode 15A2 can be formed by the sputtering method or the like. The second electrode 15A2 can function as a cathode electrode common to the sub-pixel 101R and the sub-pixel 101B.

The second protective layer 16A2 is formed on the first surface side of the second electrode 15A2. Examples of the second protective layer 16A2 include a SiN film and the like. The second protective layer 16A2 can be formed using a CVD method or the like.

The counter substrate 24 is arranged on the first surface side of the second protective layer 16A2 with the sealing resin layer 23 interposed therebetween. The sealing resin layer 23 can bond the second protective layer 16A2 to the counter substrate 24. Therefore, the display device 10 can be obtained.

Note that the manufacturing method described here is an example, and the manufacturing method of the display device 10 is not limited thereto.

### 1-3 Function and Effect

In a conventional display device, a technique is known in which a structure in which a plurality of light emitting layers corresponding to respective color types of sub-pixels are laminated is formed over a plurality of sub-pixels, so that a combination of light emitting layers forming an organic layer is common to the plurality of sub-pixels. In this case, each sub-pixel is required to extract light corresponding to the color type of the sub-pixel from light generated from the light emitting element having the organic layer, and light other than the light corresponding to the color type of the sub-pixel is removed. For this reason, in the conventional display device, there is room for improvement in terms of improving light emission efficiency.

In the display device 10 according to the first embodiment, the opening width of the first opening 19A and the opening width of the second opening 19B are different from each other, and thus the state of the light emission separation layer 145 of the plurality of sub-pixels (the second sub-pixel and the third sub-pixel) having a common combination of the light emitting layers 142 can be made different. For example, in the example of the first embodiment illustrated in FIG. 2, the thickness of the light emission separation layer 145 is different, and the thickness of the light emission separation layer 145 in the sub-pixel 101R (second sub-pixel) is smaller than the thickness of the light emission separation layer 145 in the sub-pixel 101B (third sub-pixel). For this reason, regarding the light emission balance between red light emission (light emission in the red light emitting layer 142R) and blue light emission (light emission in the blue light emitting layer 142B) in the second organic layer 14A2, the light emission balance in the second sub-pixel is different from the light emission balance in the third sub-pixel. As illustrated in FIG. 5A, in the sub-pixel 101B, collision between holes (H) and electrons (E) is likely to occur in the second light emitting layer (blue light emitting layer) located on the second electrode 15A2 side, and the light generated in the light emitting element 104B has a strong blue color. As illustrated in FIG. 5B, in the sub-pixel 101R, the collision between holes (H) and electrons (E) is likely to occur in the first light emitting layer (red light emitting layer) located on the first electrode 13 side, and the light generated in the light emitting element 104R has a strong red color.

Furthermore, in the display device 10 according to the first embodiment, as also described in the above-described manufacturing method, the combination of the light emitting layers 142 is common in the light emitting elements 104 in the sub-pixel 101 corresponding to at least two types of color types, unlike the method of individually forming the light emitting element 104 for each of the color types of the sub-pixel 101, and thus it is also possible to suppress the number of manufacturing processes.

As described above, according to the display device according to the first embodiment, it is possible to suppress an increase in the number of manufacturing 10 processes and to improve the light emission efficiency of the sub-pixel.

### 1-4 Modification

### (First Modification)

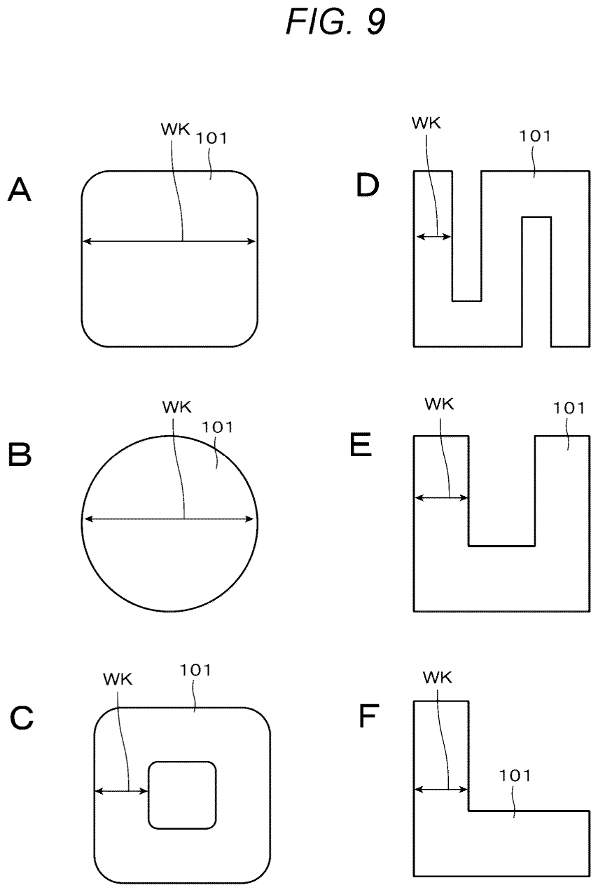

In the display device 10 according to the first embodiment, the layout and shape of the sub-pixels 101B, 101R, and 101G are not limited to the examples illustrated in FIGS. 1A, 1B, and 2. As illustrated in FIGS. 23A to 23D, the layout of the sub-pixels 101B, 101R, and 101G may be different from the delta-shaped layout, and as illustrated in FIGS. 9A to 9F, the sub-pixels 101B, 101R, and 101G may have shapes different from a hexagonal shape. This form is referred to as a first modification of the first embodiment. FIGS. 23A to 23F are diagrams illustrating examples of the layout of the sub-pixel 101. FIGS. 9A to 9F are diagrams illustrating examples of the shape of the sub-pixel 101.

In the display device 10 according to the first modification of the first embodiment, the layout of the sub-pixels 101B, 101R, and 101G may be a square array as illustrated in FIGS. 23A, 23B, and 23C, or may be a stripe-shaped array as illustrated in FIG. 23D. As illustrated in FIGS. 23E and 23 F, the layout of the sub-pixels 101B, 101R, and 101G may be a delta-shaped array.

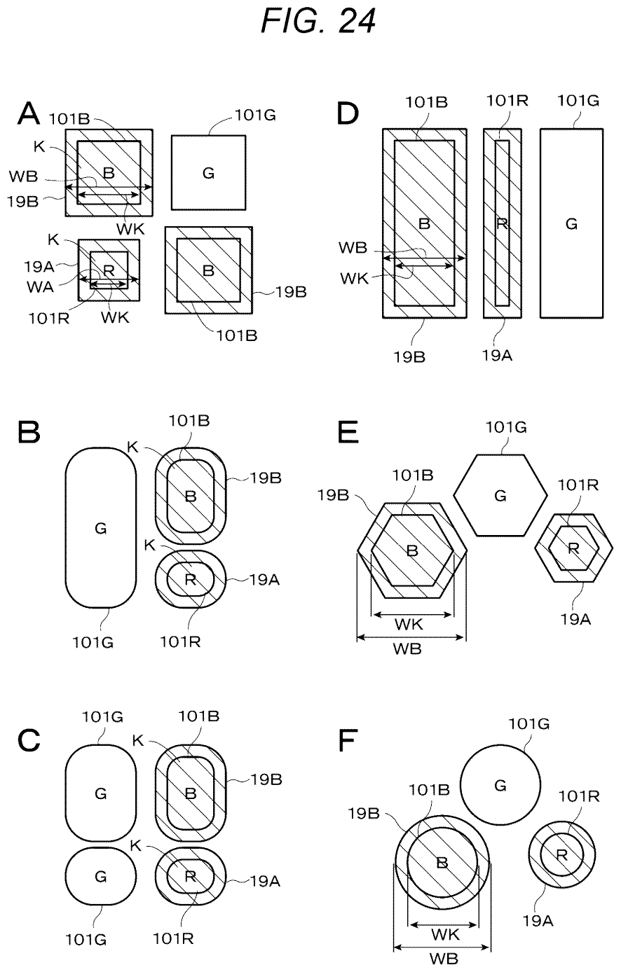

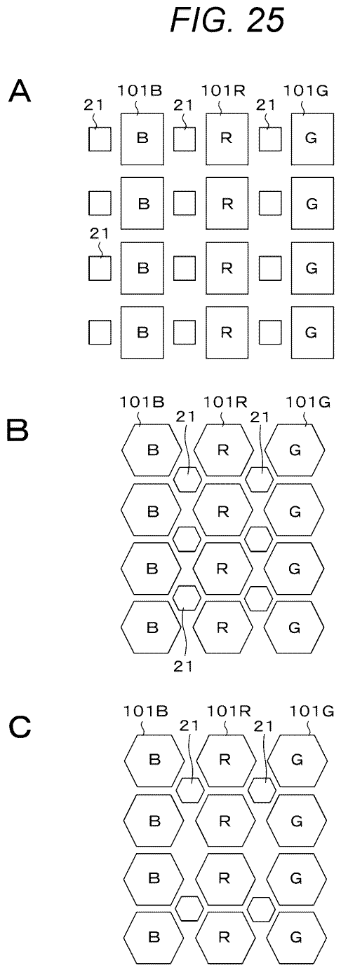

Furthermore, in the display device 10 according to the first embodiment, in the example of FIG. 2, regarding the size of the sub-pixel 101, the size of a region (a region of the light emitting unit K) in which the first electrode 13 and the organic layer 14 directly face each other is smaller than that of the opening of the first protective layer. This is an example, and a dimensional relationship between the size of the sub-pixel 101 and the sizes of the first opening and the second opening is not limited. The size (the size of the sub-pixel 101) of the region (the region of the light emitting unit K) where the first electrode 13 and the organic layer 14 directly face each other may match the sizes of the first opening 19A and the second opening 19B. Furthermore, as illustrated in FIGS. 24A to 24F, the size of the sub-pixel 101 may be different from the sizes of the first opening 19A and the second opening 19B. In the examples illustrated in FIGS. 24A to 24F, regarding the size of the sub-pixel 101, a case is exemplified in which the size of the region (the region of the light emitting unit K) where the first electrode 13 and the organic layer 14 directly face each other is smaller than that of the opening (the first opening 19A and the second opening 19B) of the first protective layer. In this case, in the sub-pixel 101R, the opening width WK of the light emitting unit K is smaller than the opening width WA of the first opening 19A, and in the sub-pixel 101B, the opening width WK of the light emitting unit K is smaller than the opening width WB of the second opening 19B. Note that the size of the opening width can be specified based on the sizes of the opening and the width of the light emitting unit, as recognized in a case where a cut surface obtained by vertically cutting the light emitting unit K and the opening along the same plane is assumed. FIGS. 24A to 24F are diagrams illustrating examples of the layout of the sub-pixel 101. FIGS. 24A to 24C are examples of a case where the layout of the sub-pixels 101B, 101R, and 101G is a square array, FIG. 24D is an example of a case where the layout of the sub-pixels 101B, 101R, and 101G is a stripe-shaped array, and FIGS. 24E and 24F are examples of a case where the layout of the sub-pixels 101B, 101R, and 101G is a delta-shaped array.

In the display device 10 according to the first modification of the first embodiment, the shape of the sub-pixels 101B, 101R, and 101G is not limited to a hexagon. In addition to a rectangular chamfered shape, a circular shape, and an annular shape as illustrated in FIGS. 9A to 9C, a shape having a bent portion such as an S shape, a U shape, and an L shape as illustrated in FIGS. 9D to 9F may be used. Note that the shapes of the sub-pixels 101B, 101R, and 101G correspond to the region (the region of the light emitting unit K) where the first electrode 13 and the organic layer 14 directly face each other. Note that in a case where the sub-pixel 101B has a shape having a bent portion such as an S shape, a U shape, or an L shape, the opening width WK of the region of the light emitting unit K indicates a width in a direction orthogonal to a direction extending in the S shape, the U shape, or the L shape.

### (Second Modification)

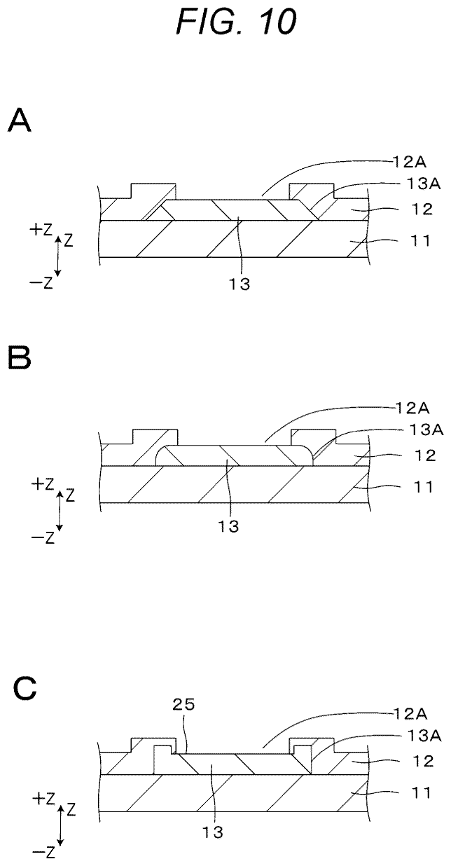

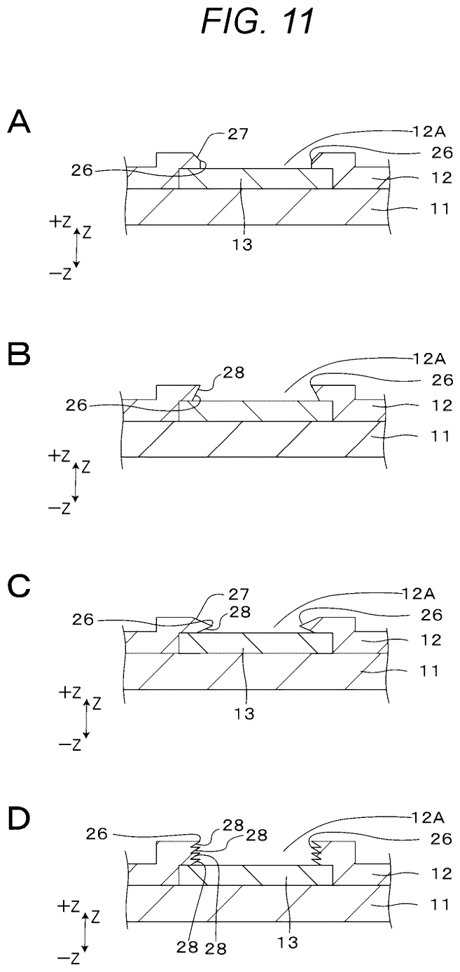

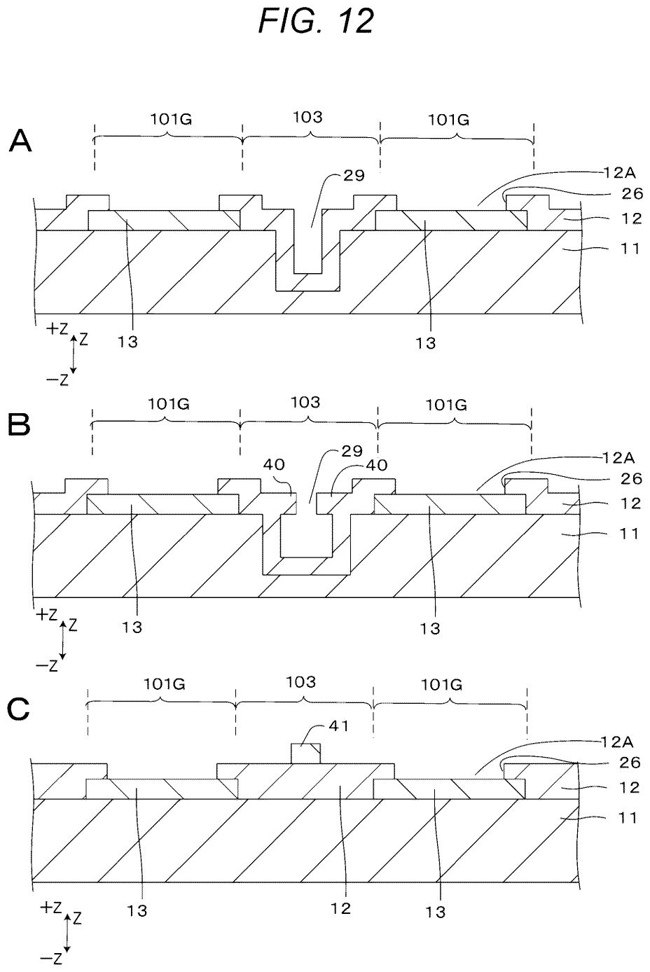

In the display device 10 according to the first embodiment, in the example of FIG. 2, the shape of the first electrode 13 is a shape in which the cross section of the first electrode 13 is a non-tapered rectangular shape, but the shape is not limited thereto, and the shape of the first electrode 13 may be a shape as illustrated in FIGS. 10A, 10B, 10C, and the like. This form is referred to as a second modification of the first embodiment. FIGS. 10A, 10B, and 10C are cross-sectional views for explaining examples of the first electrode 13. Note that in FIGS. 10A, 10B, and 10C, other configurations except for a structure in which the inter-pixel insulating layer 12 and the first electrode 13 are arranged on the drive substrate 11 are not illustrated for convenience of description. The similarity applies to FIGS. 11A to 11D and FIGS. 12A to 12C referred to in third and fourth modifications and the like of the first embodiment described later.

In the display device 10 according to the second modification of the first embodiment, the first electrode 13 may be formed in a shape in which the end portion 13A thereof has an inclined surface (FIG. 10A), and the first electrode 13 may be formed in a shape in which the end portion 13A has a rounded shape (FIG. 10B). In a case where the first electrode 13 has a shape as illustrated in FIGS. 10A and 10B, even when unintended light emission occurs at the end portion of the first electrode 13, it is possible to suppress diffuse reflection of light due to the unintended light emission.

As illustrated in FIG. 10C, a recessed dug portion 25 may be formed in the first electrode 13. According to the display device 10 according to the second modification of the first embodiment, the dug portion 25 is formed in the first electrode 13, so that it is possible to suppress a decrease in light emission efficiency and abnormal light emission due to current leakage in a portion of the organic layer 14 located in the vicinity of the end edge of the opening 12A of the inter-pixel insulating layer 12.

### (Third Modification)

In the display device 10 according to the first embodiment, in the example of FIG. 1, a contour portion (end edge 26) forming the opening 12A in the inter-pixel insulating layer 12 is formed in a non-tapered shape, but the present invention is not limited thereto, and the contour portion (end edge 26) forming the opening 12A in the inter-pixel insulating layer 12 may be configured as illustrated in FIGS. 11A to 11D. This form is referred to as a third modification of the first embodiment. FIGS. 11A to 11D are diagrams for explaining examples of the portion forming the opening 12A in the inter-pixel insulating layer 12.

In the display device 10 according to the third modification of the first embodiment, as illustrated in FIG. 11A, an inclined surface 27 may be formed in the contour portion (end edge 26) forming the opening 12A in the inter-pixel insulating layer 12. In the example of FIG. 11A, the inclined surface 27 is inclined downward toward the inside of the opening 12A. According to the display device 10 according to the third modification of the first embodiment, the inclined surface 27 is formed at the end edge 26, so that local thinning of the organic layer 14 at the opening end of the opening 12A can be suppressed to suppress a decrease in light emission efficiency and abnormal light emission due to current leakage between the anode and the cathode (current leakage between the first electrode 13 and the second electrode 15) due to the thinning.

In the display device 10 according to the third modification of the first embodiment, as illustrated in FIG. 11B, the end edge 26 of the opening 12A in the inter-pixel insulating layer 12 may form an eave-shaped portion 28 having a reverse tapered shape. Furthermore, as illustrated in FIG. 11D, the eave-shaped portion 28 may be formed in multiple steps at the end edge 26 of the opening 12A in the inter-pixel insulating layer 12. Such a structure can be formed by multilayering a film in which the eave-shaped portion 28 is formed. Furthermore, as illustrated in FIG. 11C, the inclined surface 27 may be formed on the upper side (first surface side) of the eave-shaped portion 28 in the end edge 26 of the opening 12A in the inter-pixel insulating layer 12. According to the display device 10 according to the third modification of the first embodiment, the eave-shaped portion 28 is formed at the end edge 26 of the opening 12A in the inter-pixel insulating layer 12, so that the organic layer 14 is thinned or stepped at the position of the eave-shaped portion 28, thereby suppressing current leakage between the sub-pixels 101 and suppressing a decrease in light emission efficiency and abnormal light emission. The current leakage between the sub-pixels 101 may be current leakage passing through the hole injection layer 140 and the hole transport layer 141. In this regard, in particular, by reducing, at the eave-shaped portion 28, the thickness of the hole injection layer 140 and the hole transport layer 141 constituting the organic layer 14, the current leakage between the sub-pixels 101 can be more effectively suppressed. From the viewpoint of suppressing the current leakage between the sub-pixels 101 and the current leakage between the first electrode 13 and the second electrode 15, it is preferable to combine the third modification of the first embodiment, the second modification described above, the fourth modification described later, and the like.

### (Fourth Modification)

In the display device 10 according to the first embodiment, as illustrated in FIGS. 12A and 12B, a groove 29 may be formed at a position between the adjacent sub-pixels 101. This form is referred to as the fourth modification of the first embodiment. FIGS. 12A and 12B are diagrams for explaining examples of the fourth modification of the first embodiment. FIGS. 12A and 12B correspond to cross sections at a position similar to that of the cross section of FIG. 3B.

In the example of FIG. 12A, the groove 29 is formed between the adjacent sub-pixels 101G in the inter-pixel insulating layer 12, but may be formed between the adjacent sub-pixels 101R and 101B, or may be formed between the adjacent sub-pixels 101 of different color types.

Note that, in the display device 10 according to the third modification of the first embodiment, as illustrated in FIG. 12B, an eave-shaped extending portion 40 may be formed at the upper end of the groove 29. In the example of FIG. 12B, in plan view of the display device 10, the extending portion 40 extends from the upper end of the groove 29 in the inward direction of the groove 29.

According to the display device 10 according to the fourth modification of the first embodiment, the groove 29 is formed at the position between the adjacent sub-pixels 101, so that the organic layer 14 is locally thinned (or stepped), thereby effectively suppressing the current leakage between the sub-pixels 101.

### (Fifth Modification)

In the display device 10 according to the first embodiment, as illustrated in FIG. 12C, an inter-pixel electrode 41 may be formed on the upper surface (first surface) side of the inter-pixel insulating layer 12 at a position between the adjacent sub-pixels 101. This form is referred to as a fifth modification of the first embodiment. FIG. 12C is a diagram for explaining an example of the fifth modification of the first embodiment. As the material of the inter-pixel electrode 41, a material similar to that of the first electrode may be used.

In the example of FIG. 12C, the inter-pixel electrode 41 is formed between the adjacent sub-pixels 101G on the upper surface of the inter-pixel insulating layer 12, but may be formed between the adjacent sub-pixels 101R and 101B, or may be formed between the adjacent sub-pixels 101 of different color types.

According to the fifth modification of the first embodiment, the inter-pixel electrode 41 is formed at a position between the adjacent sub-pixels 101, so that a leakage current is drawn into the inter-pixel electrodes 41 to effectively suppress a decrease in light emission efficiency and abnormal light emission.

### (Sixth Modification)

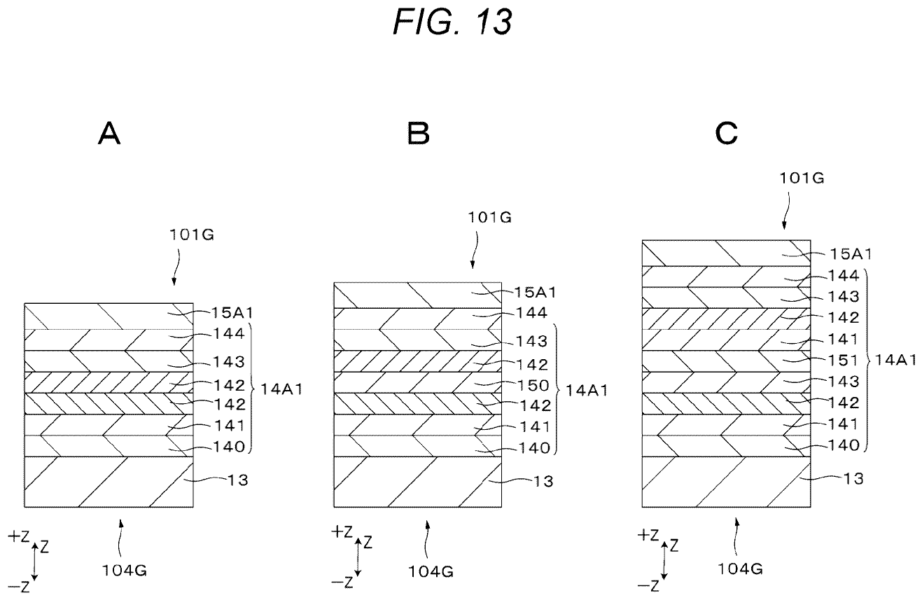

In the display device 10 according to the first embodiment, in the example of FIG. 1, the first organic layer 14A1 may be configured as illustrated in FIGS. 13A to 13C. This form is referred to as a sixth modification of the first embodiment. FIGS. 13A to 13C are cross-sectional views schematically illustrating examples of the first organic layer 14A1 in the display device 10 according to the sixth modification of the first embodiment.

In the display device 10 according to the sixth modification of the first embodiment, the first organic layer 14A1 may be formed with a plurality of light emitting layers as illustrated in FIG. 13A. In the example of FIG. 13A, the first organic layer 14A1 has a structure in which the hole injection layer 140, the hole transport layer 141, the light emitting layer 142, the light emitting layer 142, the electron transport layer 143, and the electron injection layer 144 are laminated in this order from the side closer to the first electrode 13. In this case, the two light emitting layers 142 may be layers including different organic light emitting materials.

As illustrated in FIG. 13B, the first organic layer 14A1 may have a structure in which a hole injection layer 140, a hole transport layer 141, a light emitting layer 142, an intermediate layer 150, a light emitting layer 142, an electron transport layer 143, and an electron injection layer 144 are laminated in this order from the side closer to the first electrode 13. As the material of the intermediate layer 150, a material that can be used for the light emission separation layer 145 described above may be adopted.

Furthermore, as illustrated in FIG. 13C, the first organic layer 14A1 may have a structure (2STACK structure, tandem structure) in which the hole injection layer 140, the hole transport layer 141, the light emitting layer 142, the electron transport layer 143, a charge generation layer 151, the hole injection layer 140, the light emitting layer 142, the electron transport layer 143, and the electron injection layer 144 are laminated in this order from the side closer to the first electrode 13. Examples of the charge generation layer 151 include a layer including an N layer provided on the anode side (the first electrode 13 in the example of FIG. 13C) and a P layer provided on the cathode side (the second electrode 15A1 in the example of FIG. 13 C). Examples of the N layer include a layer formed by including, for example, an alkali metal, an alkaline earth metal, or a rare earth metal which is an electron donating metal, a metal compound or an organometallic complex of these metals, or the like. Examples of the P layer include a layer formed by, for example, an organic compound having an acceptor property such as an azatriphenylene derivative such as hexacyanoazatriphenylene (HAT), an oxide semiconductor such as molybdenum oxide (MoO3), or the like.

### (Seventh Modification)

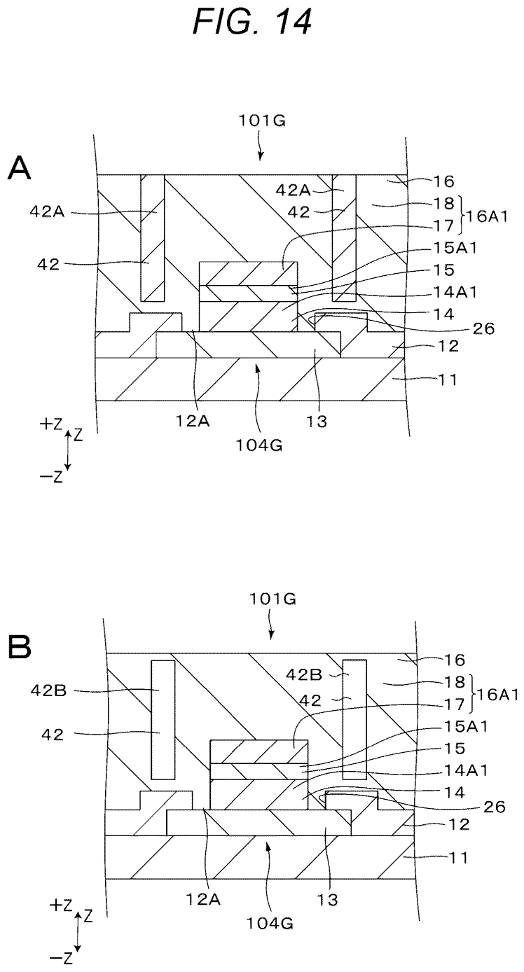

In the display device 10 according to the first embodiment, as illustrated in FIGS. 14A and 14B, a low refractive index portion 42 may be provided in the first protective layer 16A1. This form is referred to as a seventh modification of the first embodiment. FIGS. 14A and 14B are cross sections for explaining an example of the seventh modification of the first embodiment. In FIGS. 14A and 14B, other configurations except for the drive substrate 11, the inter-pixel insulating layer 12, the light emitting element 104G, the first protective layer 16A1, and the low refractive index portion 42 are not illustrated for convenience of description.

In the display device 10 according to the seventh modification of the first embodiment illustrated in the examples of FIGS. 14A and 14B, the low refractive index portion 42 is provided in the end surface protective layer 18 of the first protective layer 16A1. The low refractive index portion 42 is provided at a position between the sub-pixels 101 adjacent to each other. The low refractive index portion 42 is defined as a portion having a refractive index lower than the refractive index of the end surface protective layer 18. The low refractive index portion 42 illustrated in the example of FIG. 14A extends to the upper surface side (first surface side) of the end surface protective layer 18 in the thickness direction of the end surface protective layer 18, but this is an example. The low refractive index portion 42 may be buried in the end surface protective layer 18 as illustrated in FIG. 14B.

The low refractive index portion 42 may include a low refractive index film 42A as illustrated in FIG. 14A, or may include a void portion 42B as illustrated in FIG. 14B.

The low refractive index film 42A may be a film including various organic materials forming the organic layer 14 or a film including various organic materials forming the organic layer 14 and other organic compounds different from those organic materials, or may be a film including a resin having a low refractive index. Examples of the material of the low refractive index film 42A include transparent materials such as SiNx, SiO2, LiF, MgF, and SiON. A porous film (a film having a low film density) may be adopted as the low refractive index film 42A. For example, in a case where SiOx is used as a porous film for the low refractive index film 42A, the low refractive index film 42A can be a film having a lower refractive index of 1.4 or less.

Examples of the void portion 42B include an air gap structure (air layer) and the like, and can be formed in a state of being buried inside the first protective layer 16A1.

### (Eighth Modification)

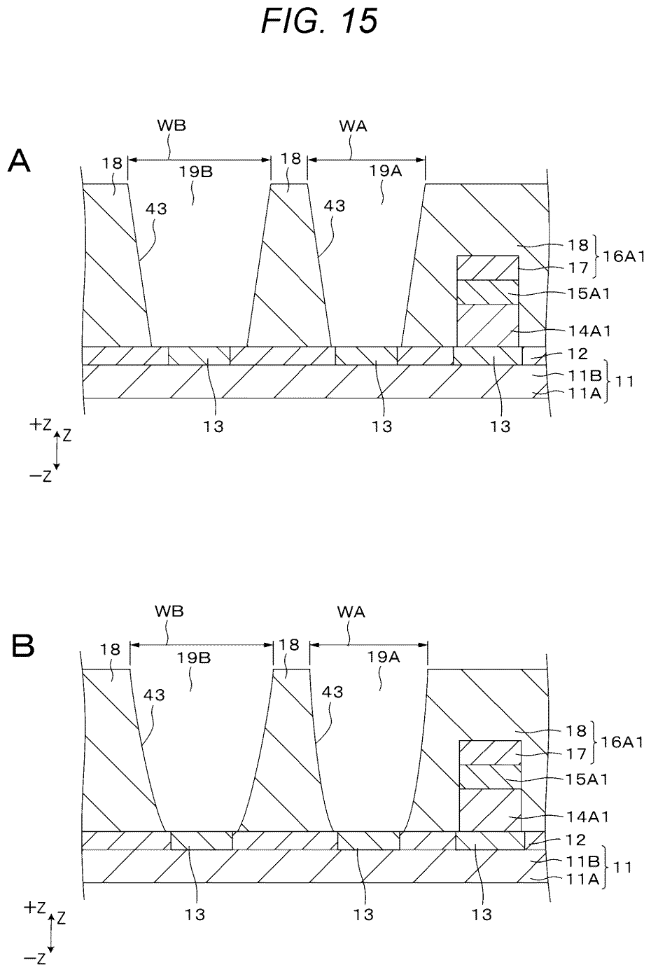

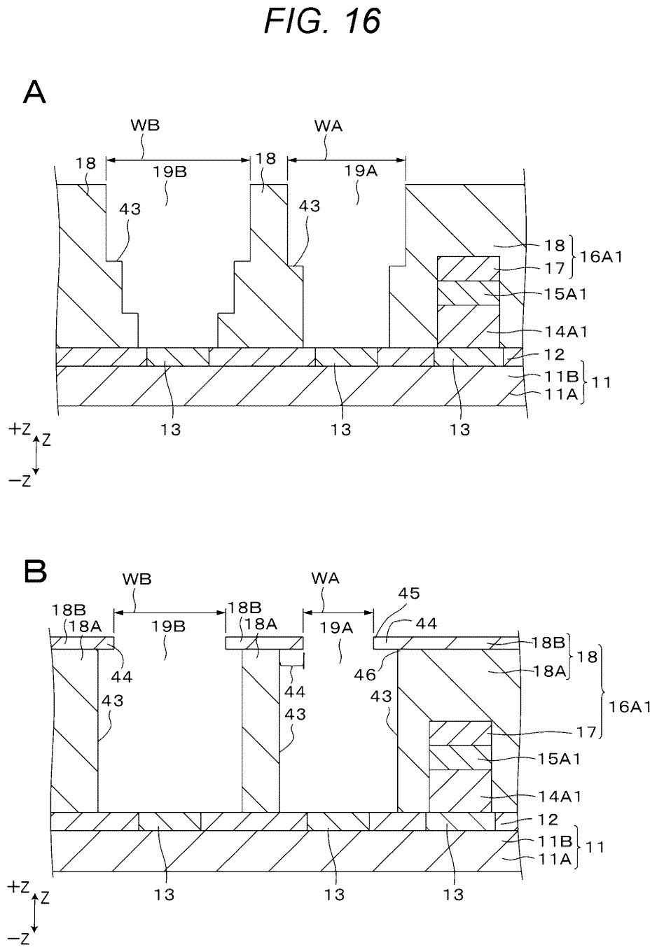

In the display device 10 according to the first embodiment, in the example of FIG. 2, the shape of the opening (the first opening 19A, the second opening 19B) is made such that a peripheral wall surface 43, which is a wall surface portion forming the opening, is a non-tapered standing wall, but the shape of the opening is not limited thereto, and may be a shape as illustrated in FIGS. 15A, 15B, and 16A. This form is referred to as an eighth modification of the first embodiment. FIGS. 15A, 15B, and 16A are cross-sectional views for explaining examples of the protective layer (first protective layer 16A1) in the display device 10 according to the eighth modification of the first embodiment. Note that, in FIGS. 15A, 15B, and 16A, other configurations (for example, the light emitting elements 104R and 104B, and the like) except for a structure in which the inter-pixel insulating layer 12, the first light emitting element (light emitting element 104G), and the first protective layer 16A1 are arranged on the drive substrate 11 are not illustrated for convenience of description.

In the display device 10 according to the eighth modification of the first embodiment, the first protective layer 16A1 may be formed in a shape such that the first opening 19A has a tapered shape (a shape tapered from the first surface toward the second surface) by the peripheral wall surface 43 forming the first opening 19A being an inclined surface (FIG. 15A), and the first protective layer 16A1 may be formed such that the first opening 19A has a curved shape by the peripheral wall surface 43 forming the first opening 19A being a curved shape (FIG. 15B). The first protective layer 16A1 may be formed such that the peripheral wall surface 43 forming the first opening 19A has a multi-step shape (FIG. 16A). In the example of FIG. 16A, the first opening 19A has a shape tapered stepwise from the first surface toward the second surface.

As for the shape of the second opening 19B of the first protective layer 16A1, similarly to the first opening 19A described above, the second opening 19B may have a shape selected from a tapered shape (FIG. 15A), a curved shape (FIG. 15B), and a multi-step shape (FIG. 16A). Note that in the examples illustrated in FIGS. 15A, 15B, and 16A, the shape of the first opening 19A and the shape of the second opening 19B are substantially similar shape, but may be different from each other.

### (Ninth Modification)

In the display device 10 according to the first embodiment, as illustrated in FIG. 16B, an eave portion 44 may be formed at the end edge of the peripheral wall surface 43 which is a wall surface portion forming the opening (the first opening 19A and the second opening 19B) of the first protective layer 16A1. This form is referred to as a ninth modification of the first embodiment. FIG. 16B is a cross-sectional view for explaining an example of the protective layer (first protective layer) in the display device 10 according to the ninth modification of the first embodiment. Note that, in FIG. 16B, other configurations (for example, the light emitting elements 104R and 104B, and the like) except for a structure in which the inter-pixel insulating layer 12, the first light emitting element (light emitting element 104G), and the first protective layer 16A1 are arranged on the drive substrate 11 are not illustrated for convenience of description.

In the display device 10 according to the ninth modification of the first embodiment, the end surface protective layer 18 of the first protective layer 16A1 includes a first layer 18A and a second layer 18B. In the example of FIG. 16B, the second layer 18B is formed on the upper side (first surface side) of the first layer 18A, and forms the upper end edge of the peripheral wall surface 43 of the opening.

In the peripheral wall surface 43 of the opening, an end edge 45 of the second layer 18B extends inward of the opening with respect to an upper end edge 46 of the first layer 18A in plan view of the display device 10. This extending portion serves as the eave portion 44. Note that the opening width of the opening (the opening width WA of the first opening 19A and the opening width WB of the second opening 19B) is determined at the position of the end edge of the eave portion 44.

The eave portion 44 can be formed as follows, for example. In a process of forming the end surface protective layer 18, the first layer 18A is formed on one surface with a material that can be used to form the end surface protective layer 18. The second layer 18B is formed on one surface with a material that is less likely to be etched than the first layer 18A. Then, etching is performed at positions corresponding to the sub-pixels 101R and 101B, so that the first opening 19A and the second opening 19B are formed. At this time, the second layer 18B is less likely to be etched than the first layer 18A, so that the eave portion 44 is formed as a portion of the second layer 18B extending inward of the opening with respect to the upper end edge 46 of the first layer 18A.

### (Tenth Modification)

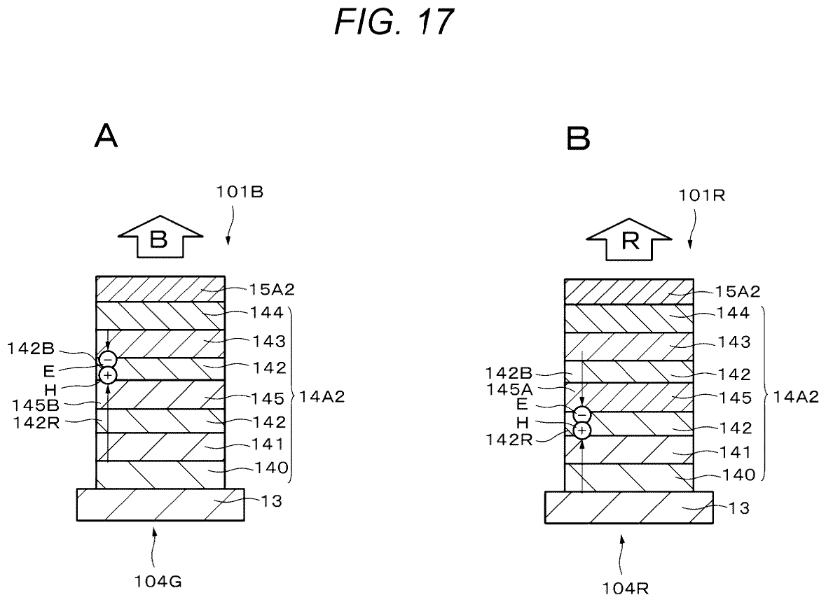

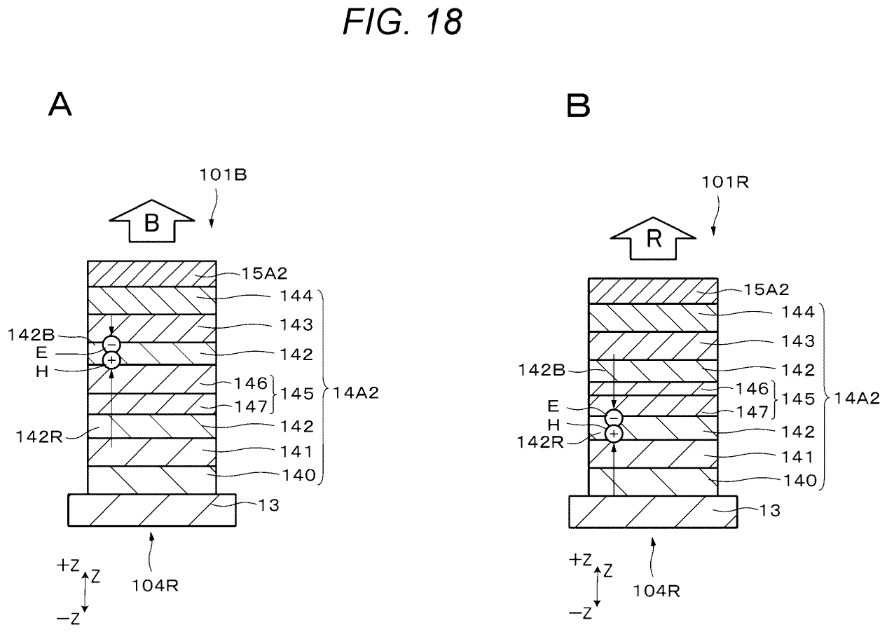

In the display device 10 according to the first embodiment, as illustrated in FIGS. 17A and 17B, a concentration ratio (first concentration ratio) that is a concentration composition of a component (constituent component) constituting the light emission separation layer 145 formed in the second light emitting element corresponding to the second sub-pixel (the sub-pixel 101R in FIG. 17B) may be different from a concentration ratio (second concentration ratio) that is a concentration composition of a component (constituent component) constituting the light emission separation layer 145 formed in the third light emitting element corresponding to the third sub-pixel (the sub-pixel 101B in FIG. 17A). This form is referred to as a tenth modification of the first embodiment. FIG. 17A is a cross-sectional view for explaining an example of the third light emitting element in the display device 10 according to the tenth modification of the first embodiment. FIG. 17B is a cross-sectional view for explaining an example of the second light emitting element in the display device 10 according to the tenth modification of the first embodiment.

In the display device 10 according to the tenth modification of the first embodiment, it is preferable that both the light emission separation layer 145 (light emission separation layer 145A) formed in the light emitting element 104R corresponding to the sub-pixel 101R and the light emission separation layer 145 (light emission separation layer 145B) formed in the light emitting element 104B corresponding to the sub-pixel 101B are formed with a co-deposited film. Examples of the co-deposited film include a co-deposited film in which a hole transport material is doped with an electron transport material. In the display device 10 according to the tenth modification of the first embodiment, regarding the concentration ratio between the hole transport material and the electron transport material, which are components constituting the light emission separation layer 145, the first concentration ratio determined for the light emission separation layer 145A formed in the light emitting element 104R is different from the second concentration ratio determined for the light emission separation layer 145B formed in the light emitting element 104B.

In the light emission separation layer 145A formed in the light emitting element 104R, the concentration ratio (first concentration ratio) between the hole transport material and the electron transport material is determined to be such a ratio that the collision frequency of holes (H) and electrons (E) increases in the red light emitting layer 142R.

In the light emission separation layer 145B formed in the light emitting element 104B, the concentration ratio (second concentration ratio) between the hole transport material and the electron transport material is determined to be such a ratio that the collision frequency of holes (H) and electrons (E) increases in the blue light emitting layer 142B.

Note that the concentration ratio indicates the ratio of the amount of the material component contained in the light emission separation layer 145. For example, the concentration ratio between the hole transport material and the electron transport material is a molar ratio between the hole transport material and the electron transport material.

### (Eleventh Modification)

In the display device 10 according to the first embodiment, as illustrated in FIGS. 18A and 18B, the light emission separation layer 145 formed in the second sub-pixel (the sub-pixel 101R in FIG. 18B) and the third sub-pixel (the sub-pixel 101B in FIG. 18A) may have a laminated structure of a plurality of layers (constituent layers). This form is referred to as an eleventh modification of the first embodiment. FIG. 18A is a cross-sectional view for explaining an example of the third light emitting element in the display device 10 according to the eleventh modification of the first embodiment. FIG. 18B is a cross-sectional view for explaining an example of the second light emitting element in the display device 10 according to the eleventh modification of the first embodiment.

In the display device 10 according to the eleventh modification of the first embodiment, in the example of FIG. 18B, the light emission separation layer 145 provided in the second organic layer 14A2 formed in the light emitting element 104R of the sub-pixel 101R has a structure in which a constituent layer (first constituent layer 146) and a constituent layer (second constituent layer 147) are laminated. In the example of FIG. 18A, the light emission separation layer 145 provided in the second organic layer 14A2 formed in the light emitting element 104B of the sub-pixel 101B also has a structure in which the first constituent layer 146 and the second constituent layer 147 are laminated. As the first constituent layer 146 and the second constituent layer 147, a layer formed using the electron transport material and a layer formed using the hole transport material may be adopted, respectively. Note that in FIGS. 18A and 18B, in a case where the thickness direction of the light emitting element 104 is defined as the vertical direction and the side closer to the second electrode 15A2 is defined as the upper side, the first constituent layer 146 is assumed to be higher than the second constituent layer 147.

In the display device 10 according to the eleventh modification of the first embodiment, a thickness ratio (first thickness ratio (R1)) between the first constituent layer 146 and the second constituent layer 147 in the light emission separation layer 145 provided in the second organic layer 14A2 formed in the light emitting element 104R is different from a thickness ratio (second thickness ratio (R2)) between the first constituent layer 146 and the second constituent layer 147 in the light emission separation layer 145 provided in the second organic layer 14A2 formed in the light emitting element 104B. R1 and R2 represent (thickness of first constituent layer 146)/(thickness of second constituent layer 147).

In the examples of FIGS. 18A and 18B, the first thickness ratio R1 determined for the light emitting element 104R is smaller than the second thickness ratio R2 for the light emitting element 104B.

Furthermore, in the examples of FIGS. 18A and 18B, the thickness of the first constituent layer 146 in the light emission separation layer 145 provided in the second organic layer 14A2 formed in the light emitting element 104R is smaller than the thickness of the first constituent layer 146 in the light emission separation layer 145 provided in the second organic layer 14A2 formed in the light emitting element 104B. Since the opening width WB of the second opening 19B is larger than the opening width WA of the first opening 19A, this can be realized by adjusting the film formation width when the first constituent layer 146 is formed by the vapor deposition method.

Furthermore, in the examples of FIGS. 18A and 18B, the thickness of the second constituent layer 147 in the light emission separation layer 145 provided in the second organic layer 14A2 formed in the light emitting element 104R may be substantially equal to the thickness of the second constituent layer 147 in the light emission separation layer 145 provided in the second organic layer 14A2 formed in the light emitting element 104B. This can also be realized by adjusting the film formation width when the second constituent layer 147 is formed by the vapor deposition method, similarly to the first constituent layer 146.

### (Twelfth Modification)

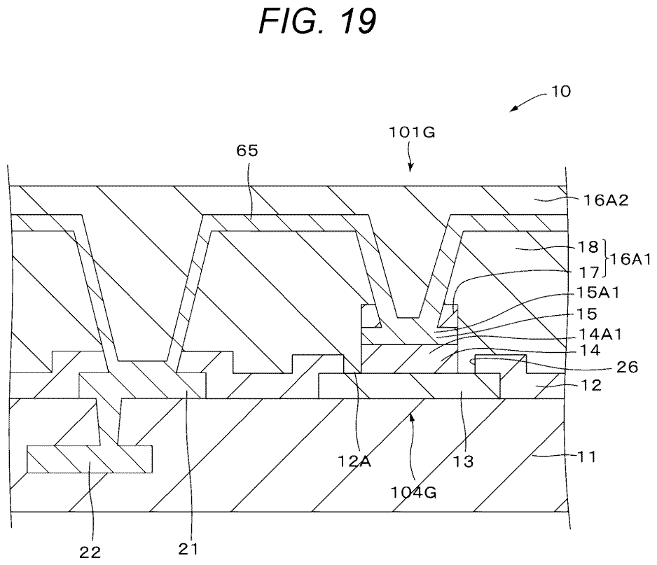

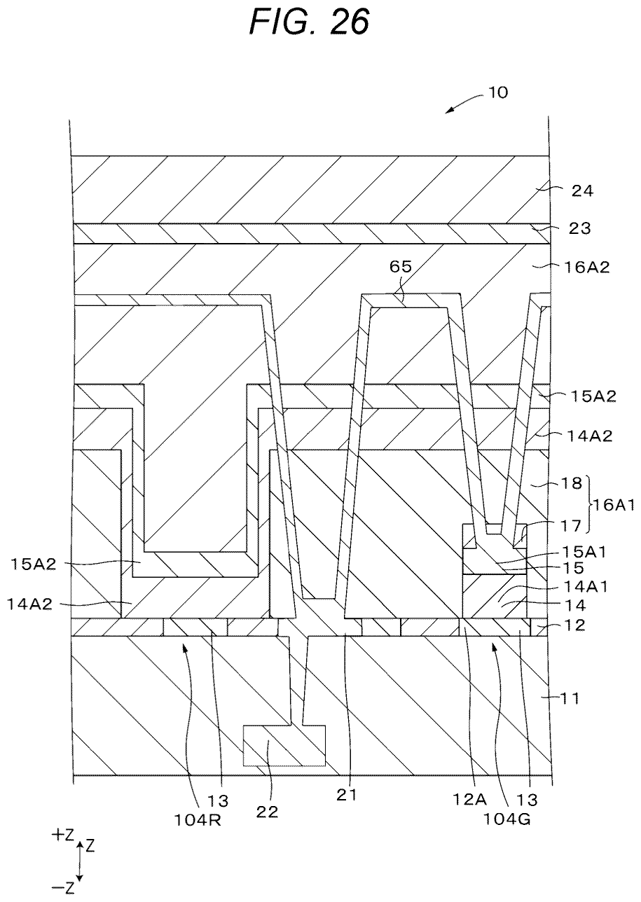

In the display device 10 according to the first embodiment, as illustrated in FIGS. 19 and 26, the auxiliary electrode 21 may be provided in the display region 10A. This form is referred to as a twelfth modification of the first embodiment. FIGS. 19 and 26 are cross-sectional views for explaining examples of the auxiliary electrode 21 in the display device 10 according to the twelfth modification of the first embodiment. FIG. 19 is a cross-sectional view illustrating an example of a case where the auxiliary electrode 21 is connected to the second electrode 15A1 of the light emitting element 104G. FIG. 26 is a cross-sectional view illustrating an example of a case where the auxiliary electrode 21 is connected to the second electrode 15A1 and the second electrode 15A2. Note that, for convenience of description, a layer structure constituting the sub-pixels 101R and 101B is not illustrated in FIG. 19, and the sub-pixel 101B is not illustrated in FIG. 26.

In the display device 10 according to the twelfth modification of the first embodiment illustrated in the example of FIG. 19, as illustrated in FIG. 25A, the auxiliary electrode 21 is formed inside the display region 10A and outside the sub-pixel 101. In the example of FIG. 19, the second electrode 15A1 and auxiliary electrode 21 are connected by the wiring 65, and the auxiliary electrode 21 is connected to the potential supply wiring 22. The layout of the auxiliary electrode 21 may be formed such that one auxiliary electrode 21 can correspond to one sub-pixel 101 as illustrated in FIG. 25A, or may be formed such that one auxiliary electrode 21 can correspond to a plurality of sub-pixels 101 as illustrated in FIGS. 25B and 25C. Note that the auxiliary electrode 21 illustrated in FIG. 25B and the auxiliary electrode 21 illustrated in FIG. 25C are different from each other in the number of sub-pixels 101 corresponding to one auxiliary electrode 21. Furthermore, for convenience of description, the shape of the sub-pixel 101 is a rectangular shape in FIG. 25A, and is a hexagonal shape in FIGS. 25B and 25C.

Furthermore, in the display device 10 according to the twelfth modification of the first embodiment, as illustrated in FIG. 25A, the auxiliary electrode 21 is formed inside the display region 10A and outside the sub-pixel 101. In the example of FIG. 25A, the second electrode 15A1 and the auxiliary electrode 21 are connected by the wiring 65, and the auxiliary electrode 21 is connected to the potential supply wiring 22.

In the display device 10 according to the twelfth modification of the first embodiment, the auxiliary electrode 21 is provided in the display region 10A, so that a distance from the sub-pixel 101 to the second electrode 15 and the auxiliary electrode 21 is shortened, and thus, it is possible to suppress the voltage drop caused by the resistance (the cathode resistance in the example of FIG. 1 and the like) of the second electrode 15.

### (Thirteenth Modification)

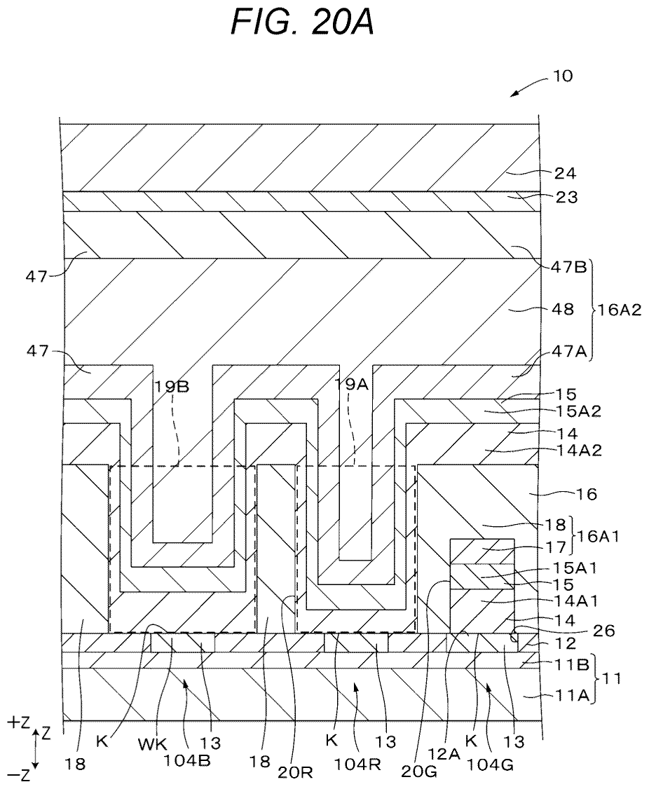

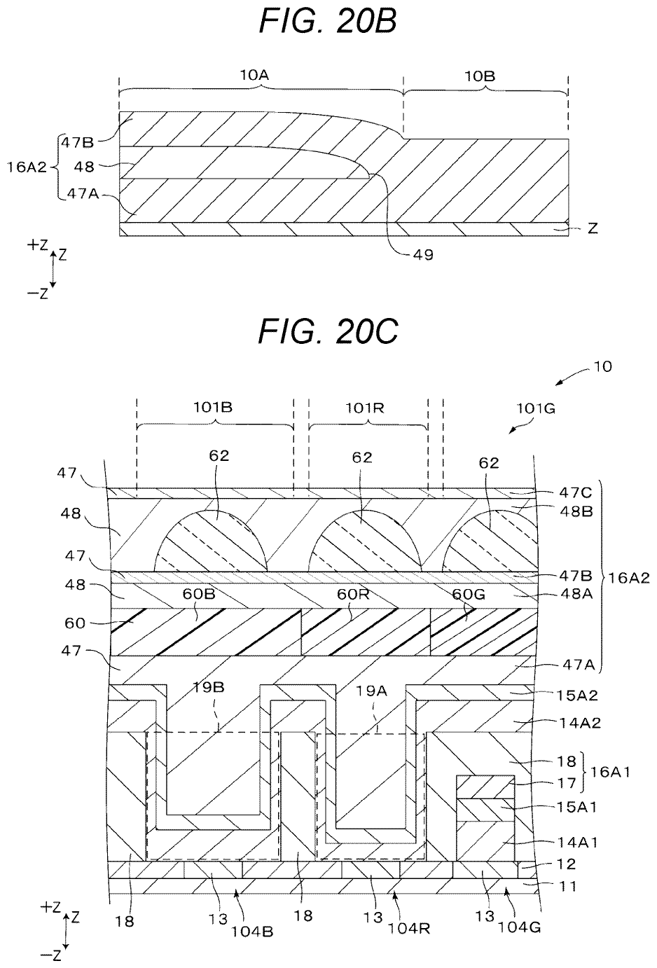

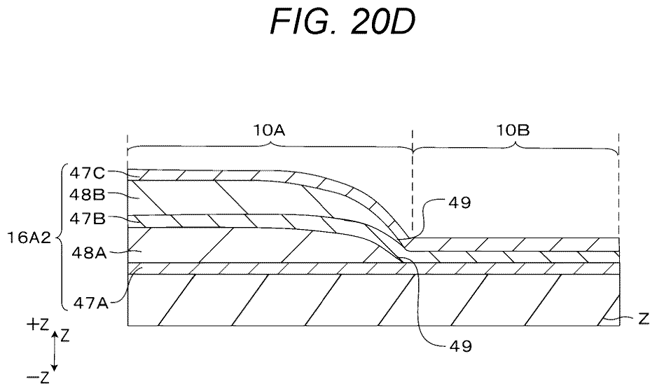

In the display device 10 according to the first embodiment, as illustrated in FIGS. 20A and 20B, the second protective layer 16A2 may have a laminated structure in which a plurality of layers are laminated. This form is referred to as the thirteenth modification of the first embodiment. FIGS. 20A and 20B are cross-sectional views for explaining an example of the display device 10 according to the thirteenth modification of the first embodiment.

In the display device 10 according to the twelfth modification of the first embodiment illustrated in the example of FIG. 20A, the second protective layer 16A2 has a laminated structure in which three layers are laminated. Furthermore, as shown in the example of FIG. 20A, the second protective layer 16A2 may have a laminated structure in which three layers of an inorganic protective layer 47 (first inorganic protective layer 47A), an organic protective layer 48, and an inorganic protective layer 47 (second inorganic protective layer 47B) are laminated in this order from the side closer to the drive substrate 11 side.

The first inorganic protective layer 47A and the second inorganic protective layer 47B may be formed using the same material, or may be formed using different materials. Examples of the materials of the first inorganic protective layer 47A and the second inorganic protective layer 47B include SiON or the like.

Examples of the material of the organic protective layer 48 include an acrylic resin or the like.

In a case where the second protective layer 16A2 has a laminated structure in which three layers of the first inorganic protective layer 47A, the organic protective layer 48, and the second inorganic protective layer 47B are laminated, the first inorganic protective layer 47A and the second inorganic protective layer 47B are preferably connected in the outer region 10B of the display region 10A. In this case, as illustrated in FIG. 20B, an outer peripheral end 49 of the organic protective layer 48 is preferably covered with the first inorganic protective layer 47A and the second inorganic protective layer 47B. Since the first inorganic protective layer 47A and the second inorganic protective layer 47B are connected in the outer region of the display region 10A, even if an uneven structure associated with the opening (the first opening 19A and the second opening 19B) is formed in the first protective layer 16A1, the second organic layer 14A2, and the second electrode 15A2, it is possible to suppress the possibility that moisture enters the organic protective layer 48 from the outer peripheral end of the second protective layer 16A2, and it is possible to improve the reliability of the display device 10. Note that in FIG. 20B, for convenience of description, a layer structure (a structure in which the light emitting element 104 and the first protective layer 16A1 are formed on the drive substrate 11) on the second surface side (−Z direction side) of the second protective layer 16A2 is referred to as a structure entity Z.

In a case where the second protective layer 16A2 has a laminated structure in which three layers of the first inorganic protective layer 47A, the organic protective layer 48, and the second inorganic protective layer 47B are laminated, the outer peripheral edge of the second protective layer 16A2 may have a multi-step structure.

In a case where the second protective layer 16A2 has a laminated structure in which a plurality of layers are laminated, as illustrated in FIG. 20C, a color filter 60 and a lens 62 described later in a fourteenth modification of the first embodiment and a fifteenth modification of the first embodiment may be embedded in the second protective layer 16A2. FIG. 20C is a cross-sectional view schematically illustrating an example of a case where the color filter 60 and the lens 62 are embedded in the second protective layer 16A2 in the display device 10 according to the thirteenth modification of the first embodiment.

In the display device 10 illustrated in FIG. 20C, the second protective layer 16A2 includes five layers of the first inorganic protective layer 47A, the first organic protective layer 48A, the second inorganic protective layer 47B, a second organic protective layer 48B, and a third inorganic protective layer 47C. In this case, the first inorganic protective layer 47A, the second inorganic protective layer 47B, and the third inorganic protective layer 47C may be configured similarly to the inorganic protective layer 47 described above. Both the first organic protective layer 48A and the second organic protective layer 48B may be configured similarly to the organic protective layer 48 described above.

Furthermore, in the display device 10 illustrated in this example, the color filter 60 is formed between the first inorganic protective layer 47A and the first organic protective layer 48A. Note that, as the color filter 60, a red filter 60R, a green filter 60G, and a blue filter 60B, which will be described later, are provided. Furthermore, the second inorganic protective layer 47B is formed on the first organic protective layer 48A (on the first surface side), and the lens 62 is formed between the second inorganic protective layer 47B and the second organic protective layer 48B. Then, the third inorganic protective layer 47C is formed on the first surface side of the second organic protective layer 48B.

Note that in a case where the second protective layer 16A2 has the organic protective layer 48 and the inorganic protective layer 47 as illustrated in FIG. 20C, it is preferable that the inorganic protective layer 47 is formed to the outside of the outer peripheral end 49 of the organic protective layer 48 (to the outer region 10B side) as described above. In a case where the second protective layer 16A2 is formed in a structure having five layers of the first inorganic protective layer 47A, the first organic protective layer 48A, the second inorganic protective layer 47B, the second organic protective layer 48B, and the third inorganic protective layer 47C, as illustrated in FIG. 20D, the first inorganic protective layer 47A, the second inorganic protective layer 47B, and the third inorganic protective layer 47C are preferably connected in the outer region 10B of the display region 10A. In the example illustrated in FIG. 20D, the outer peripheral end 49 of the first organic protective layer 48A is covered with the first inorganic protective layer 47A and the second inorganic protective layer 47B, and the outer peripheral end 49 of the second organic protective layer 48B is covered with the second inorganic protective layer 47B and the third inorganic protective layer 47C. With such a configuration, in the display device 10, it is possible to suppress the possibility that moisture enters the organic protective layer 48 from the outer peripheral end of the second protective layer 16A2.

### (Fourteenth Modification)

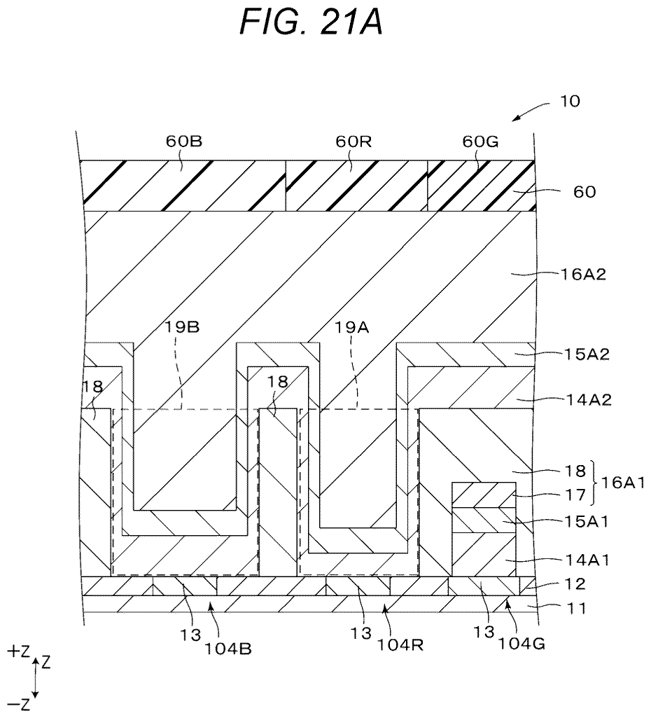

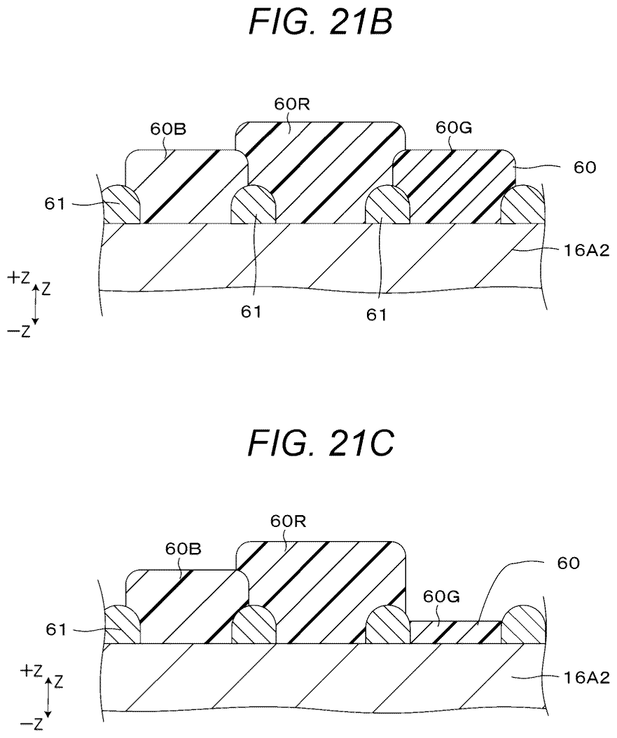

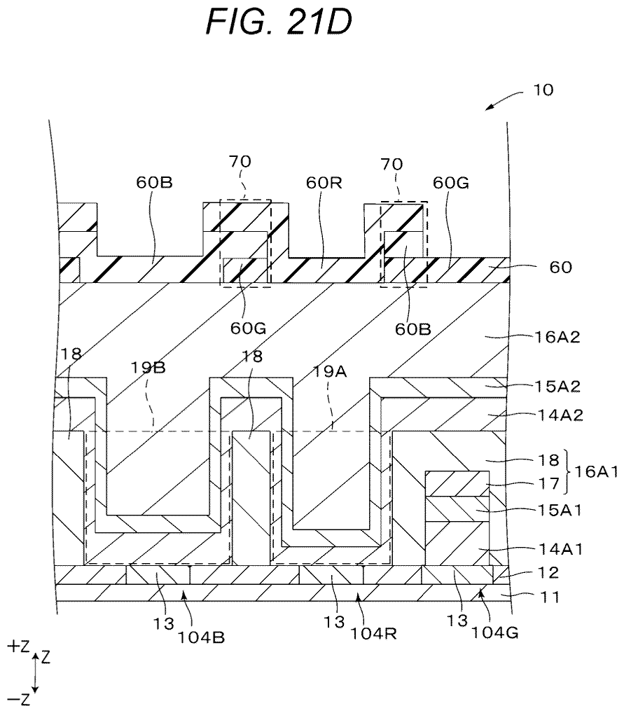

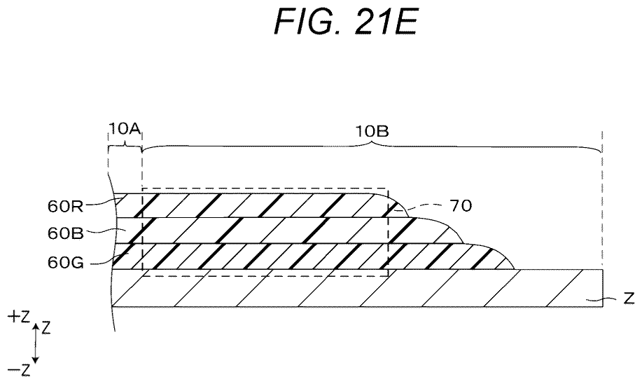

In the display device 10 according to the first embodiment, as illustrated in FIG. 21A, the color filter 60 may be provided. This form is referred to as the fourteenth modification of the first embodiment. FIG. 21A is a cross-sectional view for explaining an example of the display device 10 according to the fourteenth modification of the first embodiment. Note that in FIG. 21A, the sealing resin layer 23 and the counter substrate 24 are not illustrated for convenience of description.

### (Color Filter)

In the display device 10 illustrated in FIG. 21A, the color filter 60 is provided on the first surface side (upper side, +Z direction side) of the second protective layer 16A2. Examples of the color filter 60 include an on chip color filter (OCCF). The color filter 60 is provided according to the color type of the sub-pixel 101. Examples of the color filter 60 include a red color filter (red filter 60R), a green color filter (green filter 60G), and a blue color filter (blue filter 60B) in the example of FIG. 21A. The red filter 60R, the green filter 60G, and the blue filter 60B are provided in the sub-pixels 101R, 101G, and 101B, respectively. Since the color filter 60 is provided in the display device 10, light corresponding to the color type of the sub-pixels 101R, 101G, and 101B can be effectively extracted to the outside. Note that the color filter 60 may be provided for all the color types of the sub-pixels 101, or may be provided for the sub-pixels 101 corresponding to some color types.

The size (width) of the color filter 60 may be determined according to the sizes of the first opening 19A and the second opening 19B. For example, in a case where the opening width WB of the second opening 19B is larger than the opening width WA of the first opening 19A, the blue filter 60B is larger than the red filter 60R.

### (Partition Wall)

In the display device 10 according to the fourteenth modification of the first embodiment, as illustrated in FIG. 21B, a partition wall 61 may be provided between the color filters 60 adjacent to each other. The partition wall 61 is not particularly limited, but may include a light-transmissive material. Note that the partition wall 61 may be a black matrix. In FIG. 21B, other configurations except for a part of the second protective layer 16A2, the color filter 60, and the partition wall 61 are not illustrated for convenience of description. The similarity applies to FIG. 21C.

### (Thickness of Color Filter)

Regarding the thickness of the color filter, in the example illustrated in FIG. 21B, the thickness of the red filter 60R is smaller than the thicknesses of the green filter 60G and the blue filter 60B, but this is an example. The thickness of the color filter 60 may be larger than the thickness of the partition wall 61 or may be smaller than the thickness of the partition wall 61. Furthermore, as illustrated in FIG. 21C, only a part of the color filter 60 may be thinner than the partition wall 61. In the example of FIG. 21C, the thickness of the green filter 60G is smaller than the thickness of the partition wall 61.

### (Light Shielding Layer)

In the display device 10 according to the fourteenth modification of the first embodiment, the color filters 60 corresponding to a plurality of different types of color types may be stacked outside the display region 10A. For example, a structure in which the red filter 60R and the blue filter 60B are stacked in the vertical direction may be formed outside the display region 10A (not illustrated). Since a structure that functions as a light shielding layer is formed by stacking the color filters 60, a light shielding portion can be formed simultaneously with a color filter forming process, and the light shielding portion can be formed without separately adding a process for forming the light shielding portion. Furthermore, as illustrated in FIG. 21E, a structure in which the red filter 60R, the blue filter 60B, and the green filter 60G are stacked in the vertical direction may be formed outside the display region 10A. In FIG. 21E, a structural portion in which the color filters 60 provided outside the display region 10A are stacked can function as the light shielding portion 70. FIG. 21E is a cross-sectional view schematically illustrating an example of a portion that is a structural portion in which the color filters 60 are stacked outside the display region 10A and that can function as the light shielding portion 70 in the display device 10 according to the fourteenth modification of the first embodiment.

### Another Example of Light Shielding Portion

In the above description, in the display device 10 according to the fourteenth modification of the first embodiment, a case has been described in which the portion that is the structural portion in which the color filters 60 are stacked outside the display region 10A and that can function as the light shielding portion 70 is formed, but the light shielding portion 70 may be formed inside the display region 10A. Specifically, as illustrated in FIG. 21D, the light shielding portion 70 may be formed between the adjacent sub-pixels 101 inside the display region 10A. In the example of FIG. 21D, the light shielding portion 70 is formed as a structural portion in which the color filters 60 are stacked between the adjacent sub-pixels 101. FIG. 21D is a cross-sectional view schematically illustrating an example of a portion that is a structural portion in which the color filters 60 are stacked inside the display region 10A and that can function as the light shielding portion 70 in the display device 10 according to the fourteenth modification of the first embodiment. In this case, even if light travels in an unintended direction deviated from the sub-pixel 101, since the structural portion in which the color filters 60 are stacked is formed as the light shielding portion 70 between the adjacent sub-pixels 101, light leaking to the outside from between the adjacent sub-pixels 101 can be suppressed.

Note that in the above description of the display device 10 according to the fourteenth modification of the first embodiment, a case where the color filter 60 is the OCCF has been exemplified. However, a first laminated substrate in which the sealing resin layer 23 and the color filter 60 are formed on the counter substrate 24 and a second laminated substrate in which the light emitting element 104 and the protective layer 16 are formed on the drive substrate 11 are prepared, and the first laminated substrate and the second laminated substrate may be bonded to each other with a flattening layer interposed therebetween.

### (Fifteenth Modification)

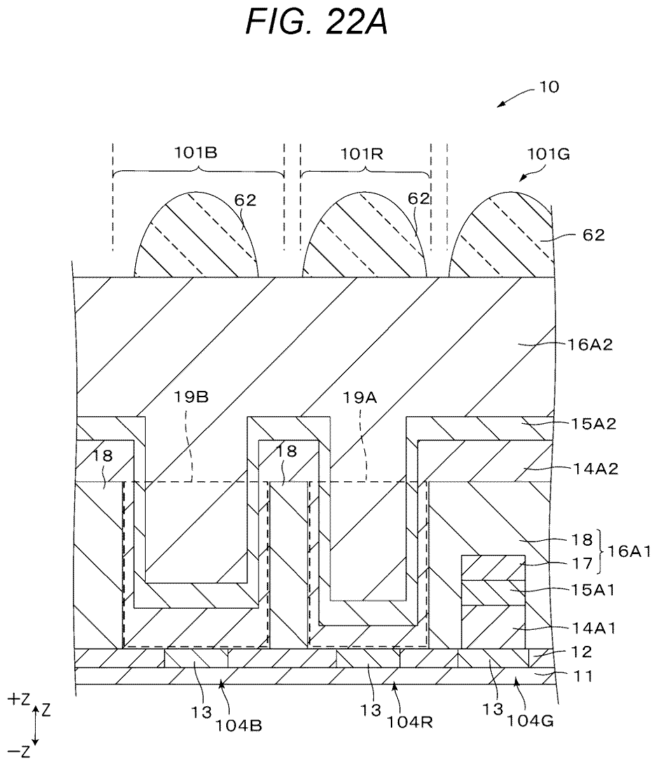

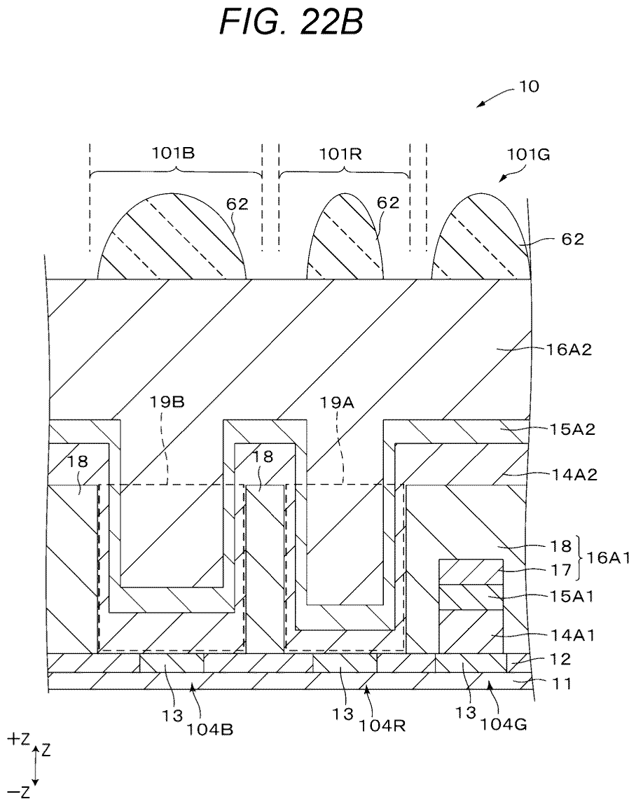

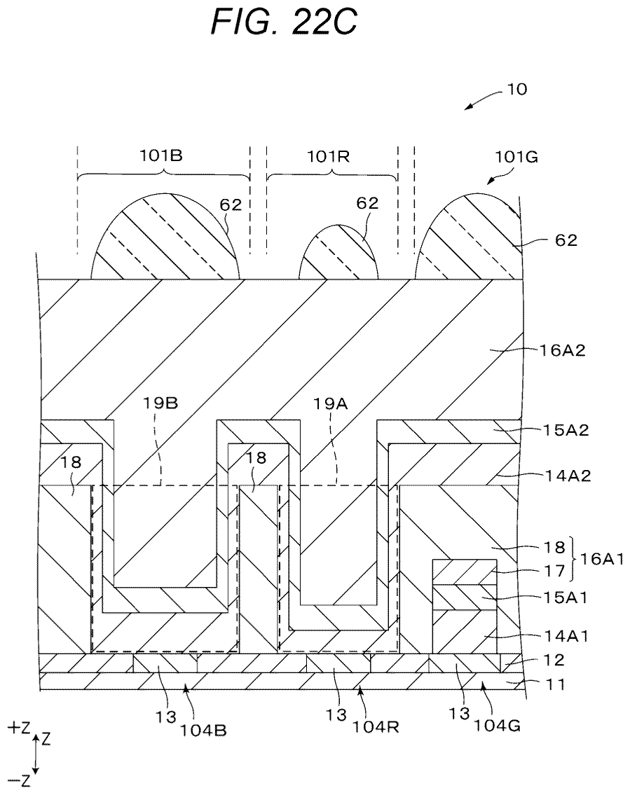

In the display device 10 according to the first embodiment, the lens 62 may be provided as illustrated in FIG. 22A. This form is referred to as the fifteenth modification of the first embodiment. FIG. 22A is a cross-sectional view for explaining an example of the display device 10 according to the fifteenth modification of the first embodiment.

### (Lens)

In the display device 10 illustrated in FIG. 22A, the lens 62 is provided on the first surface side (upper side, +Z direction side) of the second protective layer 16A2. The lens 62 is preferably an on chip lends (OCL). The material of the lens 62 is not particularly limited, and examples of the material include various materials such as a resin material that can be used in forming the sealing resin layer 23 and the like described in the first embodiment. The lens 62 is provided according to the position corresponding to each sub-pixel 101.

### (Shape of Lens)

In the example of FIG. 22A, the lens 62 is preferably formed in a convex shape having a curved surface convexly curved in a direction (+Z direction) away from the drive substrate 11, and is preferably a so-called convex lens.

In the display device 10 according to the fifteenth modification of the first embodiment, the shape and size of the lens 62 may be the same for all the sub-pixels 101, or as illustrated in FIGS. 22B and 22C, the shape and size of the lens 62 may be different according to the type of the sub-pixel. In the example of FIG. 22B, the shape of the lens 62 provided at the position corresponding to the sub-pixel 101R is narrower than that of the lens 62 provided at the position corresponding to the sub-pixel 101B. In the example of FIG. 22C, the size of the lens 62 provided at the position corresponding to the sub-pixel 101R is smaller than that of the lens 62 provided at the position corresponding to the sub-pixel 101B.

### 2 Second Embodiment

### 2-1 Configuration of Device

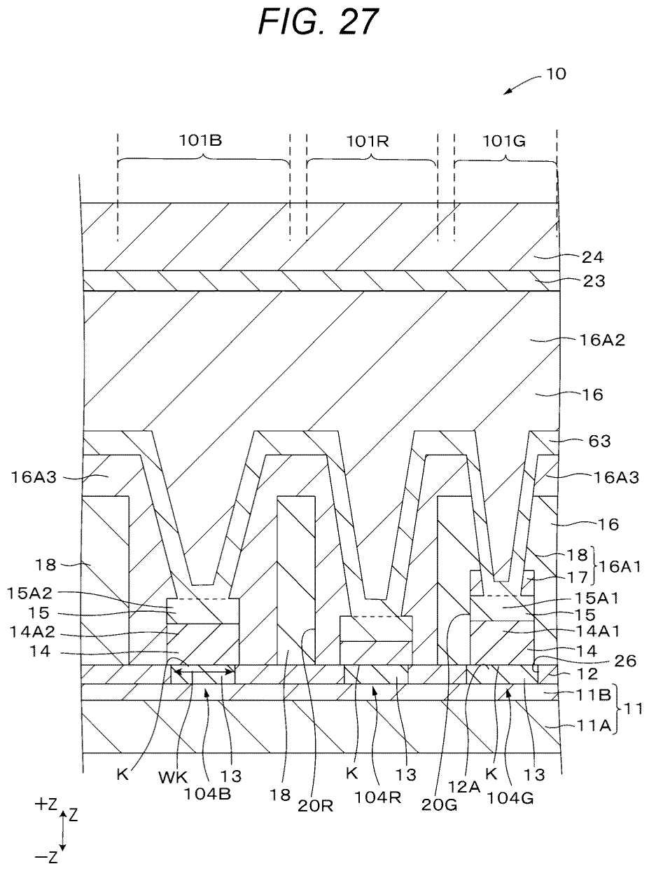

As illustrated in FIG. 27, the display device 10 according to the second embodiment separates the light emitting element 104 for each sub-pixel 101 and includes a third electrode 63, and the second electrode 15A1 and the second electrode 15A2 are connected by the third electrode 63. The display device 10 has a similar structure to that of the display device 10 according to the first embodiment except for the configuration in which the light emitting element 104 is separated, the structure of the second electrode 15, and the third electrode 63. Therefore, in the second embodiment, the configurations of the sub-pixel 101, the drive substrate 11, the layers constituting the light emitting element 104, and the counter substrate 24 are similar to those of the first embodiment, and thus the description thereof will be omitted. FIG. 27 is a cross-sectional view illustrating an example of the display device 10 according to the second embodiment.

### (Second Protective Layer)

The second protective layer 16A2 is formed so as to cover the third electrode 63. The material of the second protective layer 16A2 may be a similar material to that of the second protective layer described in the first embodiment.

### (Third Protective Layer)

In the display device 10 according to the second embodiment, the third protective layer 16A3 is formed between the third electrode 63 and the first protective layer 16A1. The material of the third protective layer 16A3 may be a similar material to that of the second protective layer 16A2 described above.

### (Second Electrode and Organic Layer)

The second electrode 15A1 and the first organic layer 14A1 are formed similarly to the first embodiment except that they are preferably divided in units of individual sub-pixels 101.

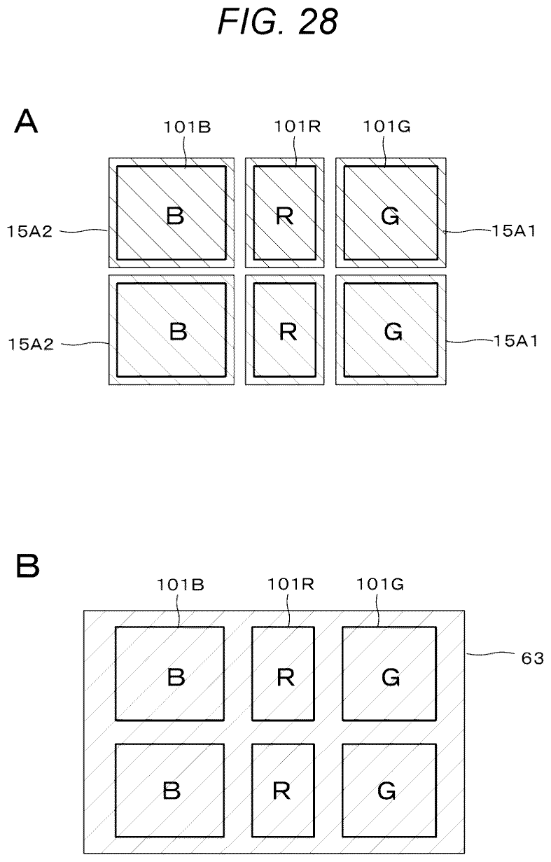

As illustrated in FIGS. 27 and 28A, the second electrode 15A2 is formed similarly to the first embodiment except that the second electrode 15A2 is divided for each sub-pixel 101 as described above. FIG. 28A is a diagram schematically illustrating an example of a positional relationship between the layout of the second electrode 15A1 and the second electrode 15A2 and the layout of the light emitting unit K in the display device 10 according to the second embodiment. Note that in FIG. 28A, the formation regions of the second electrode 15A1 and the second electrode 15A2 are hatched. Furthermore, in FIG. 28A, for convenience of description, a case where the shape of the sub-pixel 101 is a rectangular shape and the layout of the sub-pixel 101 is a lattice shape is taken as an example. The similarity applies to FIG. 28B.

The second organic layer 14A2 is also formed similarly to the first embodiment except that the second organic layer 14A2 is divided for each sub-pixel 101.

### (Third Electrode)

In the display device 10 according to the second embodiment, the third electrode 63 is provided so as to connect the second electrodes 15 formed in the different sub-pixels 101. The material of the third electrode 63 may be similar to the material of the second electrode 15. As illustrated in FIG. 28B, the third electrode 63 is formed on one surface. FIG. 28B is a diagram schematically illustrating an example of the layout of the third electrode 63 in the display device 10 according to the second embodiment. In FIG. 28B, the formation region of the third electrode 63 is hatched.

### (Auxiliary Electrode)

In the display device 10 according to the second embodiment, similarly to the first embodiment, the auxiliary electrode 21 is preferably provided on the drive substrate 11 outside the display region 10A. However, in the display device 10 according to the second embodiment, the third electrode 63 is preferably connected to the auxiliary electrode 21.

However, in the display device 10 according to the second embodiment, similarly to the first embodiment, as illustrated in FIG. 31, the auxiliary electrode 21 may be provided inside the display region 10A. Also in this case, as illustrated in FIG. 31, the third electrode 63 is connected to the auxiliary electrode 21.

### 2-2 Manufacturing Method

The method of manufacturing the display device 10 according to the second embodiment can be implemented as follows, for example. The drive substrate 11 is formed, the first organic layer 14A1, the second electrode 15A1, and the first protective layer 16A1 are formed on the drive substrate 11 (that is, the light emitting element 104G is formed), and the second organic layer 14A2 and the second electrode 15A2 are formed (that is, the light emitting elements 104R and 104B are formed). As a method of forming each layer structure so far, a method similar to the method described in the method of manufacturing the display device according to the first embodiment may be used. However, when the light emitting element 104G is formed, the light emitting element 104 is divided for each sub-pixel 101 (the continuous portion 103 is not included).

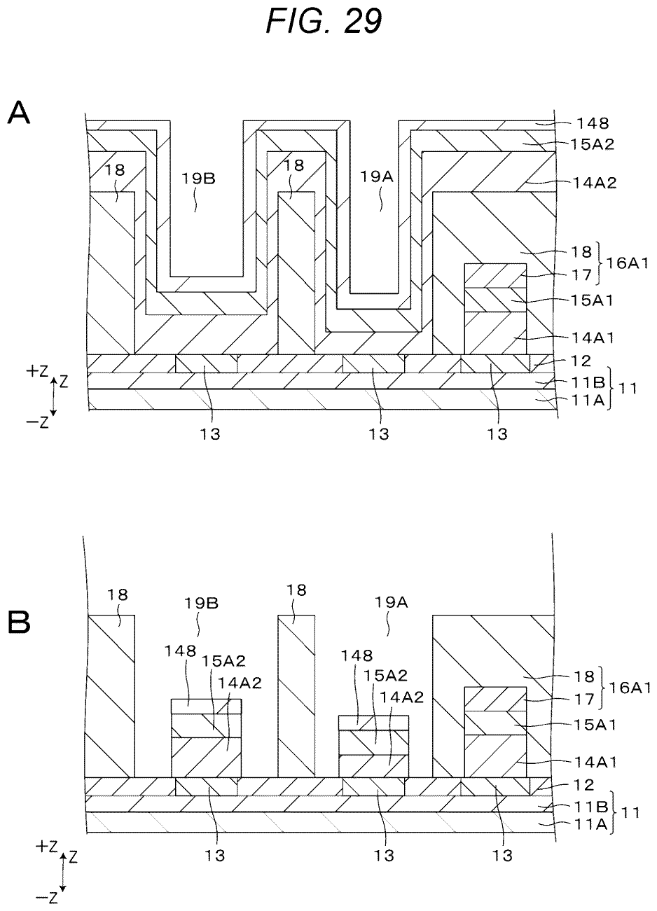

As illustrated in FIG. 29A, a layer 148 including the similar material to that of the third protective layer 16A3 is formed on one surface on the first surface of the second electrode 15A2. As a method of forming the layer 148, a method similar to that in the case of forming the second protective layer 16A2 in the method of manufacturing the display device according to the first embodiment may be used.

Next, the layer 148, the second electrode 15A2, and the second organic layer 14A2 are processed using an etching method or the like so as to have a layout corresponding to the sub-pixels 101R and 101B (FIG. 29B). At this time, the light emitting elements 104R and 104B are formed in the state of being separated from each other according to the sub-pixels 101R and 101B.

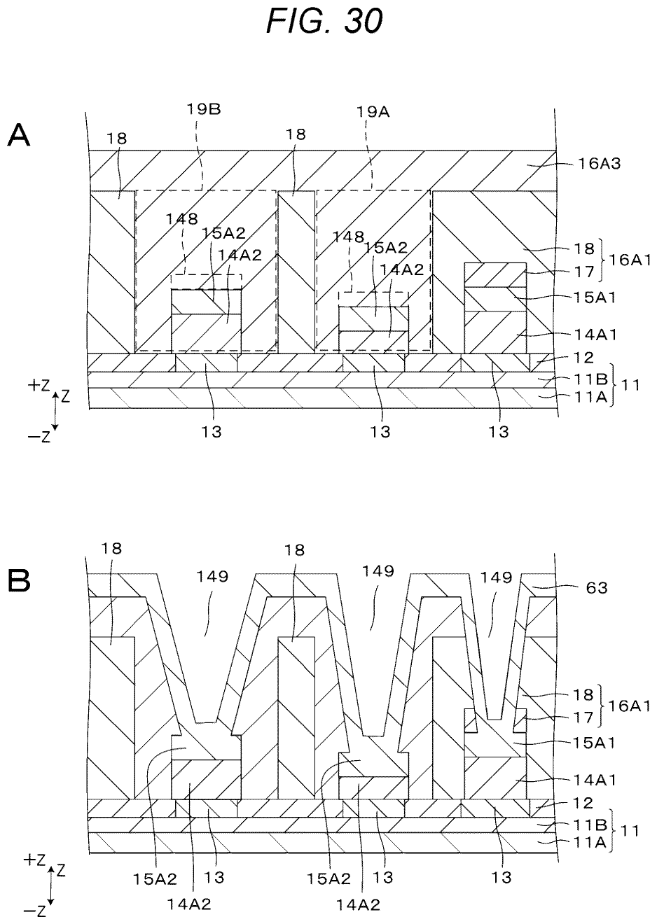

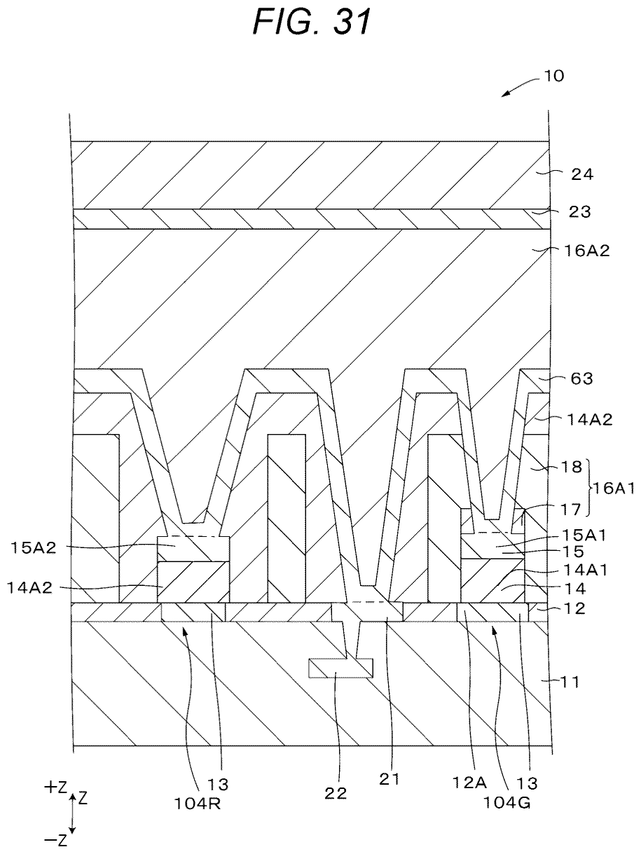

Then, as illustrated in FIG. 30A, the third protective layer 16A3 is formed so as to cover the end surfaces 20R and 20B of the light emitting elements 104R and 104B. Note that in the example of FIG. 30A, the layer 148 is integrated with the third protective layer 16A3. Furthermore, in the example of FIG. 30A, the third protective layer 16A3 is formed such that the surface on the first surface side is a flat surface, but this is an example.

A contact hole 149 is formed from the first surface side of the third protective layer 16A3 toward the first surface of the second electrode 15 (the second electrode 15A1 and the second electrode 15A2). At this time, the first surface of the second electrode 15 is exposed at the position of the bottom surface of the contact hole 149. The third electrode 63 is formed on the first surface of the third protective layer 16A3, the inner peripheral surface of the contact hole 149, and the second electrode 15 exposed on the bottom surface of the contact hole 149 (FIG. 30B). At this time, the plurality of second electrodes 15 formed in the plurality of sub-pixels 101 are electrically connected to each other via the third electrode 63.

The second protective layer 16A2 is formed on the first surface side of the third electrode 63. As a method of forming the second protective layer 16A2, a method may be used which is similar to that in the case of forming the second protective layer 16A2 in the method of manufacturing the display device according to the first embodiment.

For a process after forming the second protective layer 16A2, a method may be used which is similar to the method described in the method of manufacturing the display device according to the first embodiment.

### 2-3 Functions and Effects

According to the display device 10 according to the second embodiment, it is possible to obtain functions and effects similar to those of the first embodiment.

According to the display device 10 according to the second embodiment, the second electrode 15A2 has a structure in which the second electrode 15A2 is divided for each sub-pixel, and thus current leakage between the sub-pixels 101 is less likely to occur. Furthermore, in the sub-pixels 101R and 101B, the end surfaces 20R and 20B are more clearly formed in the light emitting elements 104R and 104B, and thus the light generated from the second organic layer 14A2 is reflected at the positions of the end surfaces 20R and 20B and easily travels from the first surface side toward the outer side, so that the light extraction efficiency can be improved.

Note that any one of the first modification to the fifteenth modification of the display device 10 according to the first embodiment or a combination thereof may be applied to the display device 10 according to the second embodiment. The similarity applies to a third embodiment described later.

### 3 Third Embodiment

### 3-1 Configuration of Device

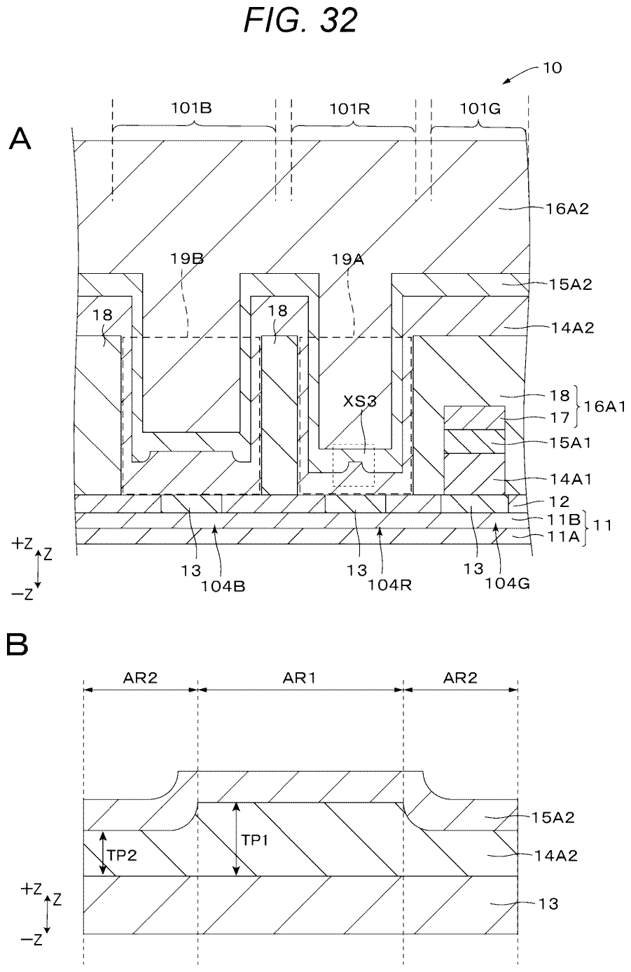

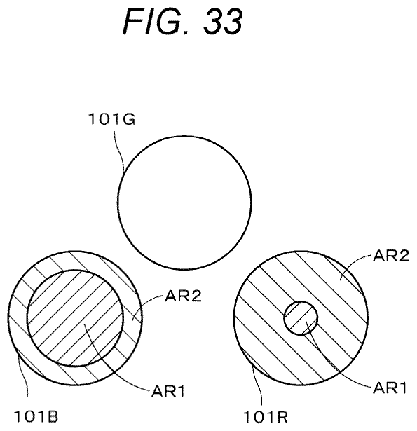

In the display device 10 according to the third embodiment, a first region (AR1) and a second region (AR2) having a smaller thickness of the light emission separation layer than that of the first region (AR1) as regions having different thicknesses of the light emission separation layer 145 as illustrated in FIG. 32B are formed in at least one of the second sub-pixel (the sub-pixel 101R in the example of FIG. 32A) or the third sub-pixel (the sub-pixel 101B in the example of FIG. 32A) in plan view of the light emitting element 104 (in a case where the Z-axis direction is the line-of-sight direction) as illustrated in FIG. 32A. Other configurations except that the light emitting element 104 has a plurality of regions (the first region AR1 and the second region AR2) having different thicknesses of the light emission separation layer may have structures similar to those of the display device 10 according to the first embodiment. Therefore, in the third embodiment, the configurations of the sub-pixel 101, the drive substrate 11, the first electrode 13, the second electrode 15, the protective layer 16, the counter substrate 24, and the like are similar to those of the first embodiment, and thus the description thereof will be omitted. FIG. 32A is a cross-sectional view illustrating an example of the display device 10 according to the third embodiment. In FIG. 32A, the sealing resin layer 23 and the counter substrate 24 are not illustrated for convenience of description. FIG. 32B is a partially enlarged cross-sectional view schematically showing a state where a region XS3 portion in FIG. 32 is enlarged. Note that FIG. 32B illustrates a partially enlarged cross-sectional view of the light emitting element 104R as the second light emitting element, but in the example of FIG. 32A, the light emitting element 104B is also divided into portions corresponding to the first region AR1 and the second region AR2 similarly to the light emitting element 104R.

### (Sub-Pixel)

In the example of FIG. 33, the shape of the sub-pixel is formed to be a circular shape. Furthermore, the layout of the sub-pixels is a delta-shaped layout. However, these are examples, and the shape and layout of the sub-pixel may be the shape and layout as illustrated in the first modification of the first embodiment. FIG. 33 is a plan diagram illustrating an example of division of the first region AR1 and the second region AR2 in the sub-pixel 101. In FIG. 33, for convenience of description, the sizes of the sub-pixel 101R and the sub-pixel 101B are made uniform.

The sub-pixel 101 corresponding to at least one color type is divided into a first region and a second region as two regions which are different in the thickness of the light emission separation layer 145 of the light emitting element 104 in a case where the thickness direction of the light emitting element 104 corresponding to the sub-pixel 101 is the line-of-sight direction. In the example of FIG. 33, the first region AR1 is a predetermined region extending outward from the center of the sub-pixel 101, and the second region AR2 is a predetermined region extending toward the center from the outer peripheral edge of the sub-pixel 101. Note that, as illustrated in the example of FIG. 33, the first sub-pixel (the sub-pixel 101G in FIG. 30) is not necessarily divided into the first region and the second region.

### (Light Emitting Element)

In the sub-pixel 101 divided into the first region AR1 and the second region AR2, the light emitting element 104 is configured such that the thickness of the portion of the light emission separation layer 145 corresponding to the first region AR1 is different from the thickness of the portion of the light emission separation layer 145 corresponding to the second region AR2. Accordingly, in the examples illustrated in FIGS. 32A and 32B, the light emitting element 104 is formed such that the thickness (reference numeral TP1 in FIG. 32B) of the portion of the second organic layer 14A2 corresponding to the first region AR1 is different from the thickness (reference numeral TP2 in FIG. 32B) of the portion of the second organic layer 14A2 corresponding to the second region AR2. In the example illustrated in FIG. 32B, TP1 is larger than TP2. The light emitting element 104 may have a configuration similar to that of the first embodiment in other points of the configuration regarding the thickness of the light emission separation layer 145. Note that in the example of FIG. 32A, for convenience of description, the first surface (the surface on the +Z direction side) of the second electrode 15 is flat. However, as illustrated in FIG. 32B, the first surface of the second electrode 15 may be an uneven surface reflecting the uneven structure of the light emission separation layer 145.

In the example of FIG. 32A, as described above, both the sub-pixels 101R and 101B are divided into the first region AR1 and the second region AR2, and as illustrated in FIG. 33, the second region AR2 is formed in a ring shape, and the first region AR1 is formed inside the second region AR2. Furthermore, in the sub-pixel 101R, the light emitting element 104R is configured such that the thickness of the portion of the light emission separation layer 145 corresponding to the first region AR1 is larger than the thickness of the portion of the light emission separation layer 145 corresponding to the second region AR2. For this reason, in the portion of the light emitting element 104R corresponding to the first region AR1, collision between holes and electrons is likely to occur in the blue light emitting layer 142B on the second electrode 15A2 side. Furthermore, in the portion of the light emitting element 104R corresponding to the second region AR2, collision between holes and electrons is likely to occur in the red light emitting layer 142R on the first electrode 13 side.

Also in the sub-pixel 101B, similarly to the sub-pixel 101R, the light emitting element 104B is configured such that the thickness of the portion of the light emission separation layer corresponding to the first region is larger than the thickness of the portion of the light emission separation layer corresponding to the second region. For this reason, in the portion of the light emitting element 104B corresponding to the first region, similarly to the light emitting element 104R, collision between holes and electrons is likely to occur in the blue light emitting layer 142B on the second electrode 15A2 side. Furthermore, in the portion of the light emitting element 104R corresponding to the second region, collision between holes and electrons is likely to occur in the red light emitting layer 142R on the first electrode 13 side.

### (Area Ratio of First Region and Second Region)

In the display device 10 according to the third embodiment, the area ratio of the first region AR1 and the second region AR2 for the second sub-pixel is different from the area ratio of the first region AR1 and the second region AR2 for the third sub-pixel. In the examples of FIGS. 32A and 33, the area ratio of the first region AR1 and the second region AR2 for the sub-pixel 101R is different from the area ratio of the first region AR1 and the second region AR2 for the sub-pixel 101B, and compared to the sub-pixel 101R, the sub-pixel 101B has the area of the first region AR1 larger than the area of the second region AR2.

In the light emitting element 104R for the sub-pixel 101R, the area of the first region AR1 is smaller than the area of the second region AR2, so that the light generated in the red light emitting layer 142R becomes strong, and strong red light can be extracted from the light emitting element 104R.

In the light emitting element 104B of the sub-pixel 101B, the area of the first region AR1 is larger than the area of the second region AR2, so that the light generated in the blue light emitting layer 142B becomes strong, and blue strong light can be extracted from the light emitting element 104B.

### 3-2 Manufacturing Method

In the method of manufacturing the display device 10 according to the third embodiment, a method similar to the method described in the method of manufacturing the display device according to the first embodiment may be used except for adjusting conditions (a film formation width, an opening width of a limited version, and the like) for forming the light emission separation layer 145 by the vapor deposition method, so as to generate a difference between the thickness of the portion of the light emission separation layer 145 corresponding to the first region AR1 and the thickness of the portion of the light emission separation layer 145 corresponding to the second region AR2.

### 3-3 Functions and Effects

In the display device 10 according to the third embodiment, the first region AR1 and the second region AR2 are formed in at least one of the second sub-pixel or the third sub-pixel, so that two types of regions (that is, the first region AR1 and the second region AR2) having different light emission intensity balances of two types of light emitting layers 142 are formed in one region of the sub-pixel 101 in plan view of the light emitting element 104. For this reason, the balance of the light emission intensity can be adjusted by using two types of the thickness of the light emission separation layer 145 and the area ratio of the first region AR1 and the second region AR2. Therefore, according to the display device 10 according to the third embodiment, it is possible to achieve a more precise balance of the light emission intensity corresponding to the color type of the sub-pixel 101.

### 3-4 Modification

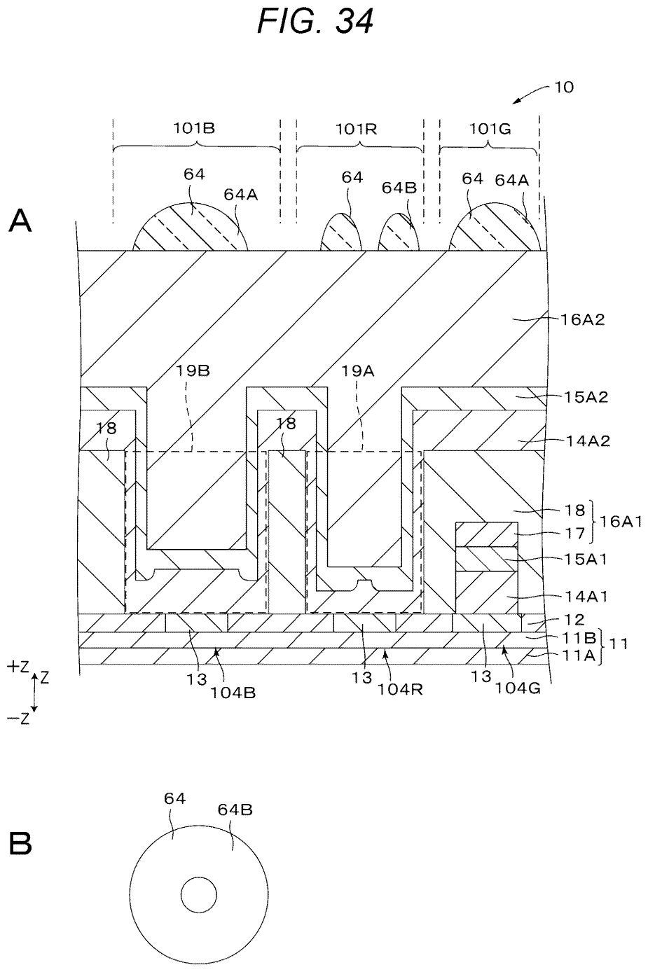

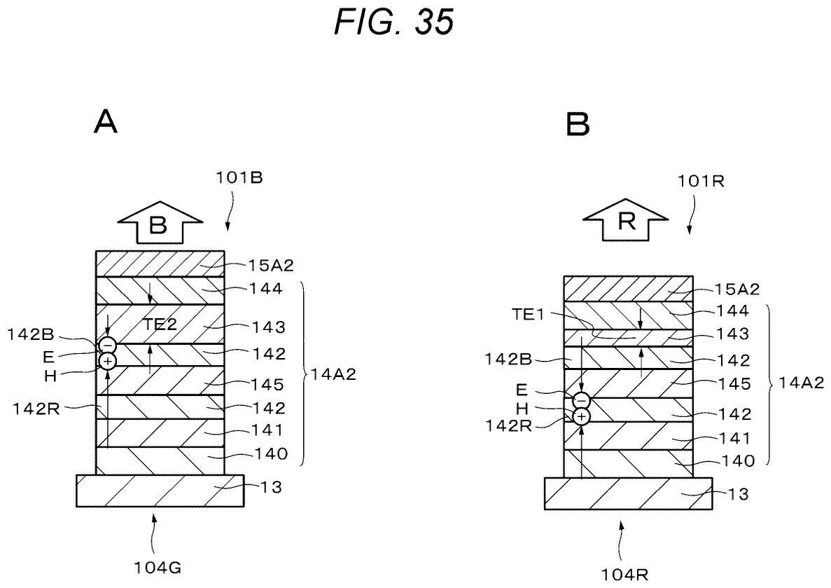

In the display device 10 according to the third embodiment, the lens 64 may be provided as illustrated in FIG. 34A. This form is referred to as a modification of the first embodiment. FIG. 34A is a cross-sectional view for explaining an example of the display device 10 according to the modification of the third embodiment.

### (Lens)

In the display device 10 illustrated in FIG. 34A, the lenses 64 are provided on the first surface side (the upper side, or the +Z direction side) of the second protective layer 16A2. The lens 64 is preferably an on chip lends (OCL). The material of the lens 64 is not particularly limited, and examples of the material include various materials that can be used as the material of the lens 62 described in the fifteenth modification of the first embodiment. The lenses 64 are provided in accordance with the positions corresponding to the respective sub-pixels 101.

### (Shape of Lens)

In the example of FIG. 10, the lens 64 is preferably formed in a convex shape having a curved surface convexly curved in a direction (+Z direction) away from the drive substrate 11, and is preferably a so-called convex lens 64A.

### (Annular Lens)

The lens 64 is not limited to a convex lens, and it is preferable to adopt a lens that can mainly collect light corresponding to the color type of the sub-pixel according to the color type of light obtained in the first region and the color type of light obtained in the second region. For example, in the sub-pixel 101R, strong red light is generated in the second region and strong blue light is generated in the first region, and thus it is preferable to provide a lens that can mainly collect the light generated in the second region. Specifically, in the sub-pixel 101R, an annular lens 64B as illustrated in FIGS. 34A and 34B is preferably provided as the lens 64. Note that, in the example of FIG. 34A, the convex lenses 64A are formed as the lenses 64 at positions corresponding to the sub-pixels 101G and 101B, and the annular lens 64B is formed as the lens 64 at a position corresponding to the sub-pixel 101R.

Note that, although the display device 10 according to the third embodiment may be provided with a color filter, a color filter that can mainly select light corresponding to the color type of the sub-pixel 101 may be adopted for the color filter, similarly to the case of the lens 64.

### 4 Fourth Embodiment

As illustrated in FIGS. 35A and 35B, the display device 10 according to the fourth embodiment may be configured similarly to the display device 10 according to the first embodiment except for a configuration that defines a thickness relationship of layers constituting the second organic layer 14A2 in the second sub-pixel (the sub-pixel 101R in the example of FIG. 35B) and the third sub-pixel (the sub-pixel 101B in the example of FIG. 35A) and a configuration that defines a relationship in size between the sizes of the first opening and the second opening. In the description of the fourth embodiment, points different from the first embodiment will be described. FIGS. 35A and 35B are cross-sectional views schematically illustrating an example of the second organic layer 14A2 used in the display device 10 according to the fourth embodiment.

### (Second Organic Layer)

In the examples illustrated in FIGS. 35A and 35B, in the second organic layer 14A2, a thickness (TE2) of the electron transport layer 143 of the light emitting element 104B corresponding to the sub-pixel 101B is formed to be thicker than a thickness (TE1) of the electron transport layer 143 of the light emitting element 104R corresponding to the sub-pixel 101R. The method of realizing the difference in thickness of the electron transport layer 143 can be realized by applying a method similar to the method of performing the process of forming the light emission separation layer 145 by the vapor deposition method described in the method of manufacturing the display device 10 according to the first embodiment.

### (First Opening and Second Opening)

As for the sizes of the opening width WA of the first opening 19A and the opening width WB of the second opening 19B corresponding to the second sub-pixel (the sub-pixel 101R in the example of FIG. 35B) and the third sub-pixel (the sub-pixel 101B in the example of FIG. 35A) forming the second organic layer 14A2 in FIGS. 35A and 35B, similarly to the first embodiment, the opening width WB of the second opening 19B is preferably larger than the opening width WA of the first opening 19A.

### Functions and Effects

As for the display device 10 according to the fourth embodiment, in the sub-pixel 101B illustrated in the examples of FIGS. 35A and 35B, collision between holes (H) and electrons (E) is likely to occur in the second light emitting layer (blue light emitting layer) located on the second electrode 15A2 side, and the light generated in the light emitting element 104B becomes strong in blue. In the sub-pixel 101R, collision between holes (H) and electrons (E) is likely to occur in the first light emitting layer (red light emitting layer) located on the first electrode 13 side, and the light generated in the light emitting element 104R becomes strong in red.

### Another Example of Fourth Embodiment

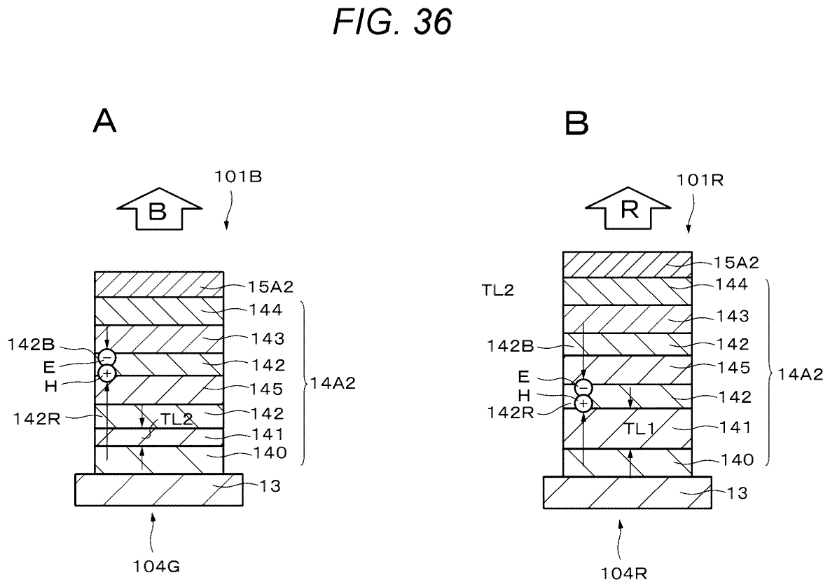

In the display device 10 according to the fourth embodiment, the second organic layer 14A2 is not limited to the examples illustrated in FIGS. 35A and 35B described above. In the second organic layer 14A2, as illustrated in FIGS. 36A and 36B, a thickness (TL2) of the hole transport layer 141 of the light emitting element 104B corresponding to the sub-pixel 101B may be formed smaller than a thickness (TL1) of the hole transport layer 141 of the light emitting element 104R corresponding to the sub-pixel 101R. FIGS. 36A and 36B are cross-sectional views schematically illustrating another example of the second organic layer 14A2 used in the display device 10 according to the fourth embodiment.

### (First Opening and Second Opening)

The sizes of the opening width WA of the first opening 19A and the opening width WB of the second opening 19B corresponding to the second sub-pixel (the sub-pixel 101R in the example of FIG. 36B) and the third sub-pixel (the sub-pixel 101B in the example of FIG. 36A) forming the second organic layer 14A2 in FIGS. 36A and 36B are preferably have a dimensional relationship different from that of the sizes of the opening width WA of the first opening 19A and the opening width WB of the second opening 19B corresponding to the second sub-pixel (the sub-pixel 101R in the example of FIG. 36B) and the third sub-pixel (the sub-pixel 101B in the example of FIG. 36A) forming the second organic layer 14A2 in FIGS. 35A and 35B, and the opening width WA of the first opening 19A is preferably larger than the opening width WB of the second opening 19B. In this case, as a method of realizing the difference in thickness of the hole transport layer 141, a method similar to the method of realizing the difference in thickness of the electron transport layer 143 described above can be applied. That is, a method of realizing the difference in thickness of the hole transport layer 141 can be realized by applying a method similar to the method of performing the process of forming the light emission separation layer 145 by the vapor deposition method described in the method of manufacturing the display device 10 according to the first embodiment.

### Functions and Effects of Another Example of Fourth Embodiment

In the sub-pixel 101B illustrated in the example of FIG. 36A, similarly to the case of the sub-pixel 101B illustrated in the example of FIG. 35A, collision between holes (H) and electrons (E) is likely to occur in the second light emitting layer (blue light emitting layer) located on the second electrode 15A2 side, and the light generated in the light emitting element 104B becomes strong in blue. In the sub-pixel 101R illustrated in the example of FIG. 36B, similarly to the case of the sub-pixel 101R illustrated in the example of FIG. 35A, collision between holes (H) and electrons (E) is likely to occur in the first light emitting layer (red light emitting layer) located on the first electrode 13 side, and the light generated in the light emitting element 104R becomes strong in red.

In the description of the first embodiment described above, a case has been described in which the second organic layer 14A2 includes a plurality of layers (the hole transport layer 141, the light emitting layer 142, the electron transport layer 143, and the like), and the thickness of the light emission separation layer 145 among the plurality of layers is different between the second light emitting element corresponding to the second sub-pixel and the third light emitting element corresponding to the third sub-pixel. Furthermore, in the fourth embodiment, unlike the first embodiment, a case has been described in which the second light emitting element corresponding to the second sub-pixel and the third light emitting element corresponding to the third sub-pixel are different in the thickness of another layer different from the light emission separation layer 145 among the plurality of layers forming the second organic layer 14A2. As for a layer of which the thickness is to be changed among the plurality of layers forming the second organic layer 14A2, it is preferable to change the thickness of the light emission separation layer 145 according to the sub-pixel as described in the first embodiment, from the viewpoint of easily controlling the light emission colors of the second sub-pixel and the third sub-pixel more precisely. Furthermore, the first embodiment and the fourth embodiment may be combined. For example, the thickness of the electron transport layer 143 and the thickness of the light emission separation layer 145 may be different between the second light emitting element corresponding to the second sub-pixel and the third light emitting element corresponding to the third sub-pixel.

On the basis of the descriptions of the first embodiment and the fourth embodiment, the present specification discloses that the thickness of at least one layer among the plurality of layers forming the second organic layer is different between the thickness of the at least one layer in the second light emitting element and the thickness of the at least one layer in the third light emitting element.

Note that, in the description of the fourth embodiment, a case has been described which is similar to the first embodiment except for the configuration (first configuration) that defines the thickness relationship of the layers constituting the second organic layer 14A2 in the second sub-pixel (the sub-pixel 101R in the example of FIG. 35B) and the third sub-pixel (the sub-pixel 101B in the example of FIG. 35A) and the configuration (second configuration) that defines the relationship in size between the first opening and the second opening. However, the fourth embodiment may be configured to be similar to the second embodiment or the third embodiment except for the first configuration and the second configuration. For example, in a case where the fourth embodiment is configured similarly to the third embodiment except for the first configuration and the second configuration, the second organic layer 14A2 may be configured such that a difference between the thickness of the portion of the first region AR1 and the thickness of the portion of the second region AR2 is caused by a thickness difference of another layer (for example, the electron transport layer 143 or the like) different from the light emission separation layer 145.

### 5 Example of Case Where Display Device Has Resonator Structure

The description regarding a case where a resonator structure is formed in the display device 10 continues with the display device 10 according to the first embodiment used as an example. In the display device 10 according to the first embodiment, the resonator structure may be further formed in at least some of the plurality of sub-pixels 101. Note that the resonator structure described using the first embodiment may be applied to the second to fourth embodiments.

### (Resonator Structure)

The resonator structure is formed in the display device 10. The resonator structure is a cavity structure, and is a structure that causes resonation of light generated in the organic layer 14. In the display device 10, the resonator structure is formed in the light emitting element 104 (light emitting elements 104R, 104B, and 104G), and the resonator structure includes the first electrode 13, the organic layer 14, and the second electrode 15. Causing resonation of light emitted from the organic layer 14 means causing resonation of light of a specific wavelength included in emitted light.

In a resonator structure, of the emitted light from the organic layer 14, the component that is reflected and resonates between predetermined layers such as between the first electrode 13 and the second electrode 15 is emphasized, and the light emphasized is emitted toward the outside from the side of the display surface DP (first surface side).

The organic layer 14 generally uses light corresponding to the color type of the sub-pixel 101 as emitted light, and the resonator structure causes resonation of light of a specific wavelength included in the emitted light from the organic layer 14. In this case, light of a predetermined wavelength in the emitted light from the organic layer 14 is emphasized. Then, light is emitted from the second electrode 15 side (that is, the light emitting surface side) of the light emitting element 104 toward the outside in a state where the light of the predetermined wavelength is emphasized. Note that the light of the predetermined wavelength is light corresponding to a predetermined color type, and indicates light corresponding to a color type determined in accordance with the sub-pixel 101. The display device 10 includes light emitting elements 104R, 104G, and 104B corresponding to sub-pixels 101R, 101G, and 101B. Furthermore, resonator structures are formed corresponding to the light emitting elements 104R, 104G, and 104B, respectively. In the resonator structure in the sub-pixel 101R, red light of the emitted light from the organic layer 14 resonates. Light is emitted from the second electrode 15 of the light emitting element 104R toward the outside in a state where the red light is further emphasized. Accordingly, the red light having excellent color purity can be emitted from the sub-pixel 101R. In the resonator structures in the sub-pixels 101G and 101B, green light and blue light of the emitted light from the organic layer 14 resonate, respectively. In the sub-pixels 101G and 101B, light is emitted from the second electrodes 15 of the light emitting elements 104G and 104B toward the outside in a state where the green light and the blue light are further emphasized. Accordingly, the green light and the blue light having excellent color purity can be emitted from the sub-pixels 101G and 101B, respectively.

As the resonator structures are formed in the display device 10 in this manner, the color purity of the sub-pixels 101 can be improved.

First to seventh examples will be sequentially described below as example cases where the display device includes resonator structures, and the explanation 10 will be continued.

### Resonator Structure: First Example

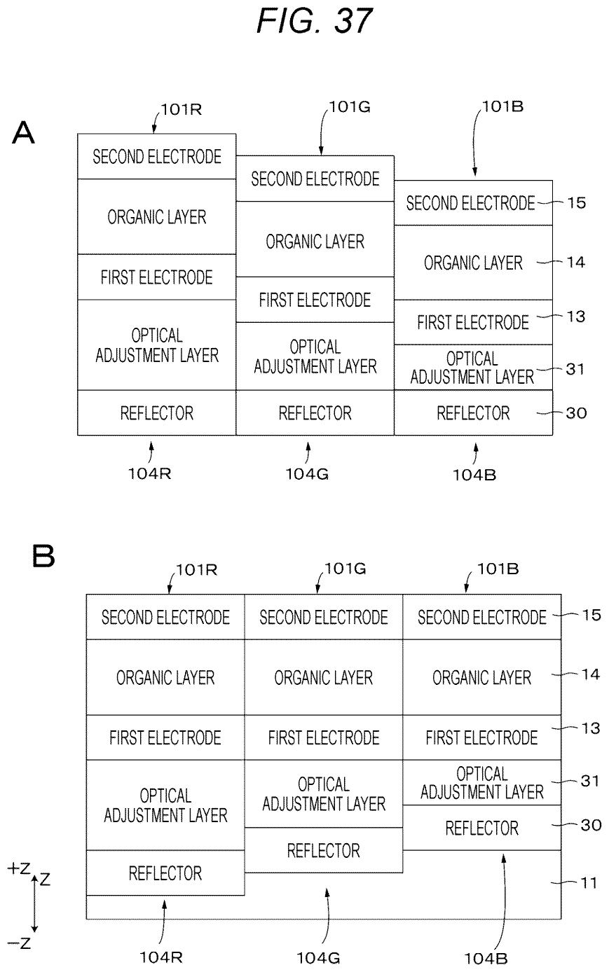

FIG. 37A is a schematic cross-sectional view for explaining the first example in a case where the display device 10 has a resonator structure.

In the first example, a thickness of the first electrode 13 and a thickness of the second electrode 15 are uniform among the sub-pixels 101R, 101G, and 101B.

In each of the sub-pixels 101R, 101G, and 101B (light emitting elements 104R, 104G, and 104B), an optical adjustment layer 31 is provided on a lower side (second surface side) of the first electrode 13, a reflector 30 is disposed on the second surface side of the optical adjustment layer 31, and the optical adjustment layer 31 is formed between the reflector 30 and the first electrode 13. The resonator structure that causes resonation of light generated by the organic layer 14 is formed between the reflector 30 and the second electrode 15.

A thickness of the reflector 30 is uniform in the sub-pixels 101R, 101G, and 101B. A thickness of the optical adjustment layer 31 varies depending on the sub-pixels 101R, 101G, and 101B. As the optical adjustment layer 31 has a thickness that varies depending on the sub-pixels 101R, 101G, and 101B, it is possible to set optical distances for causing resonance suitable for the sub-pixels 101R, 101G, and 101B.

In the example in FIG. 37A, the positions of the first surfaces of the reflectors 30 provided in the sub-pixels 101R, 101G, and 101B are arranged so as to be aligned in the vertical direction. In the sub-pixels 101R, 101G, and 101B, the positions of the first surfaces of the second electrodes 15 vary with the differences in the thickness among the optical adjustment layers 31.

The reflectors 30 can be formed with a metal such as aluminum (Al), silver (Ag), or copper (Cu), or an alloy containing these metals as principal components, for example.

The optical adjustment layers 31 can be formed with an inorganic insulating material such as silicon nitride (SiNx), silicon oxide (SiOx), or silicon oxynitride (SiOxNy), or an organic resin material such as an acrylic resin or a polyimide resin. Each of the optical adjustment layers 31 may be a single layer, or may be a multilayer film formed with a plurality of materials.

Each of the second electrodes 15 is preferably a layer that functions as a semi-transmissive reflective film. The second electrodes 15 can be formed with magnesium (Mg), silver (Ag), a magnesium-silver alloy (MgAg) containing these materials as the principal components, an alloy containing an alkali metal or an alkaline earth metal, or the like. The configurations of the first electrodes 13 and the organic layers 14 are similar to those described above, and thus the description thereof will be omitted.

### Resonator Structure: Second Example

FIG. 37B is a schematic cross-sectional view for explaining the second example in a case where the display device 10 has a resonator structure. The second example has a layer structure similar to that of the first example, except that the positions of the second electrodes 15 and the reflectors 30 are different from those in the first example.

In the sub-pixels 101R, 101G, and 101B (light emitting elements 104R, 104G, and 104B), the upper surfaces of the second electrodes 15 are arranged so that their positions in the vertical direction are aligned. The reflectors 30 provided in the sub-pixels 101R, 101G, and 101B are at different positions in the vertical direction, depending on the differences in thickness among the optical adjustment layers 31.

### Resonator Structure: Third Example

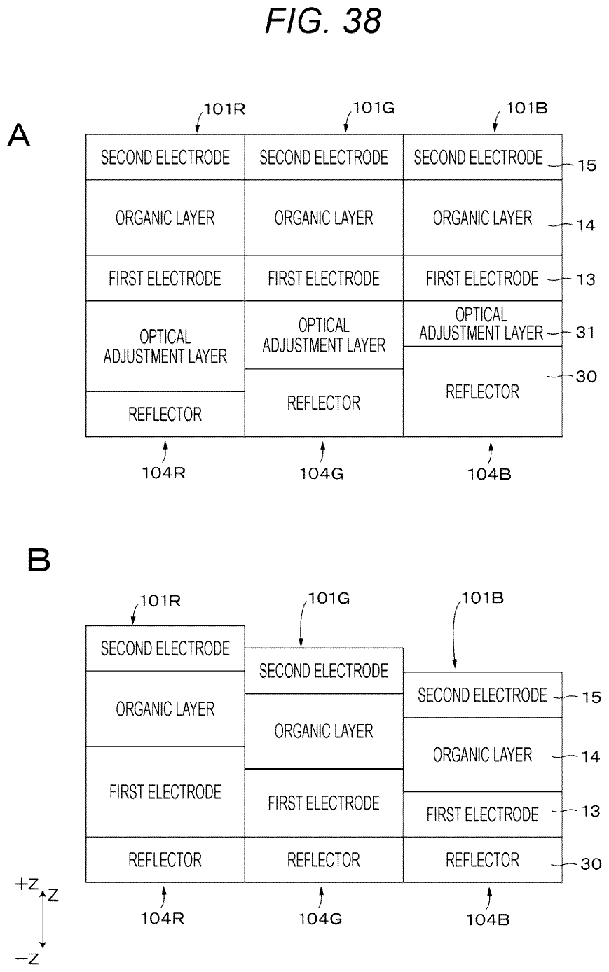

FIG. 38A is a schematic cross-sectional view for explaining the third example in a case where the display device 10 has a resonator structure. The third example has a layer structure similar to that of the first example, except that the thicknesses of the reflectors 30 vary among the sub-pixels 101R, 101G, and 101B (light emitting elements 104R, 104G, and 104B).

In the sub-pixels 101R, 101G, and 101B, the upper surfaces of the second electrodes 15 are arranged so that their positions in the vertical direction are aligned. The positions of the first surfaces of the reflectors 30 provided in the sub-pixels 101R, 101G, and 101B vary in the vertical direction, depending on the differences in thickness among the optical adjustment layers 31. However, the positions of the second surfaces of the reflectors 30 are aligned among the sub-pixels 101R, 101G, and 101B.

### Resonator Structure: Fourth Example

FIG. 38B is a schematic cross-sectional view for explaining the fourth example in a case where the display device 10 has a resonator structure. The fourth example is similar to the first example, except that the optical adjustment layers 31 are not included, and the thicknesses of the first electrodes 13 vary among the sub-pixels 101R, 101G, and 101B (light emitting elements 104R, 104G, and 104B).

Regarding the thicknesses of the first electrodes 13, the respective thicknesses of the first electrodes 13 are designed so as to set optical distances for causing optical resonance suitable for the sub-pixels 101R, 101G, and 101B.

### Resonator Structure: Fifth Example

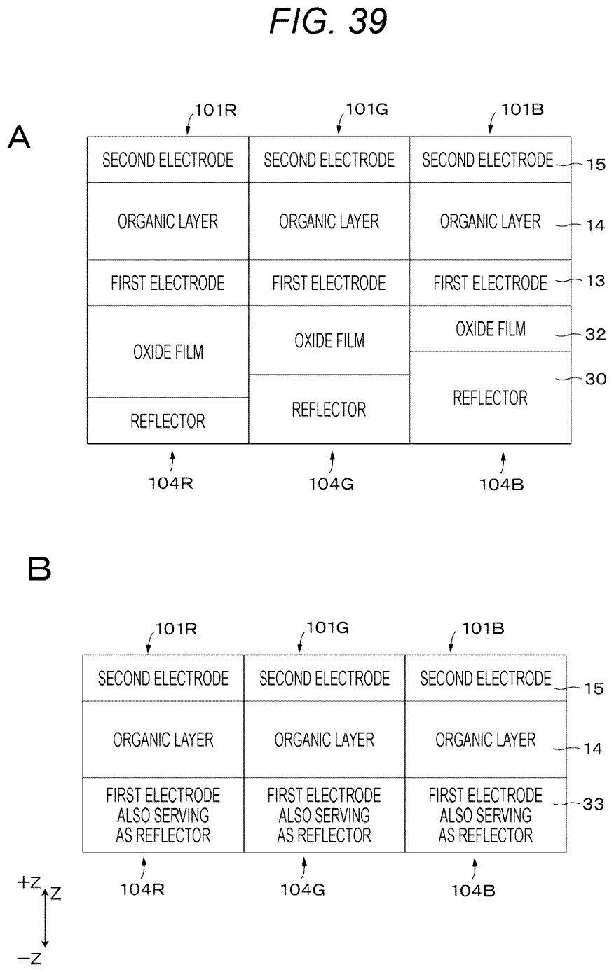

FIG. 39A is a schematic cross-sectional view for explaining the fifth example in a case where the display device 10 has a resonator structure. The fifth example is similar to the first example, except that the optical adjustment layers 31 are not included, and oxide films 32 are formed on the first surface side (the side of the surfaces facing the first electrodes 13) of the reflectors 30.

The thicknesses of the oxide films 32 vary among the sub-pixels 101R, 101G, and 101B (light emitting elements 104R, 104G, and 104B).

Regarding the thicknesses of the oxide films 32, the respective thicknesses of the oxide films 32 are designed so as to set optical distances for causing optical resonance suitable for the sub-pixels 101R, 101G, and 101B.

The oxide films 32 are films obtained by oxidizing the surfaces of the reflectors 30, and are formed with aluminum oxide, tantalum oxide, titanium oxide, magnesium oxide, zirconium oxide, or the like, for example. The oxide films 32 function as insulating films for adjusting the optical path lengths (optical distances) between the reflectors 30 and the second electrodes 15.

The oxide films 32 having thicknesses suitable for the sub-pixels 101R, 101G, and 101B can be formed in the following manner, for example.

First, a substrate on which the reflectors 30 are formed is immersed in a container filled with an electrolytic solution, and electrodes are disposed so as to face the reflectors 30.

Then, with the electrodes being used as references, positive voltages are applied to the reflectors 30, to anodize the reflectors 30. Voltages corresponding to the thicknesses of the oxide films 32 to be obtained are applied to the reflectors 30 of the sub-pixels 101R, 101G, and 101B. As a result, the oxide films 32 having different thicknesses (the oxide films 32 having thicknesses suitable for the sub-pixels 101R, 101G, and 101B) can be collectively formed on the reflectors 30 of the sub-pixels 101R, 101G, and 101B.

### Resonator Structure: Sixth Example

FIG. 39B is a schematic cross-sectional view for explaining the sixth example in a case where the display device 10 has a resonator structure.

In the sixth example, each resonator structure of the display device 10 is formed with a structure in which the first electrode 13, the organic layer 14, and the second electrode 15 are layered. In the sixth example, each first electrode 13 is a first electrode (also serving as a reflector) 33 that is designed to function as both an electrode and a reflector. The first electrodes (also serving as reflectors) 33 are formed with a material having an optical constant selected in accordance with the types of the light emitting elements 104R, 104G, and 104B. Since the phase shift by the first electrodes (also serving as reflectors) 33 vary, it is possible to set an optical distance for generating optimum resonance for the wavelength of light corresponding to the color to be displayed.

The first electrodes (also serving as reflectors) 33 can be formed with a single-component metal such as aluminum (Al), silver (Ag), gold (Au), or copper (Cu), or an alloy containing these metals as the principal components. For example, a first electrode (also serving as a reflector) 33R of the sub-pixel 101R may be formed with copper (Cu), and a first electrode (also serving as a reflector) 33G of the sub-pixel 101G and a first electrode (also serving as a reflector) 33B of the sub-pixel 101B may be formed with aluminum.

The second electrodes 15 and the organic layers 14 are similar to those of the first example, and thus the description thereof will be omitted.

### Resonator Structure: Seventh Example

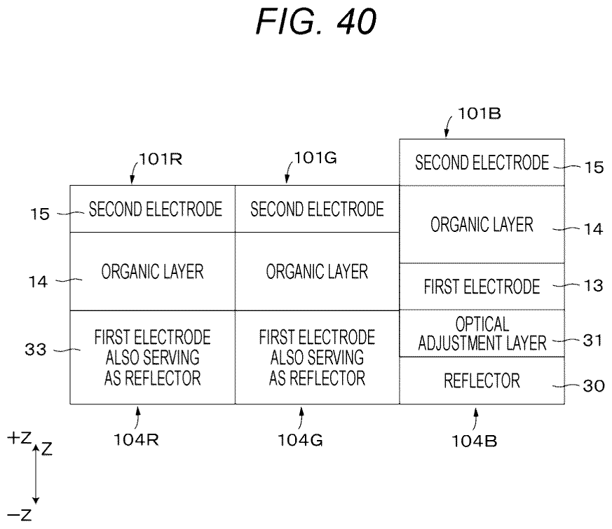

FIG. 40 is a schematic cross-sectional view for explaining the seventh example in a case where the display device 10 has a resonator structure.

In the seventh example, the resonator structures illustrated in the sixth example are provided for the sub-pixels 101R and 101G (light emitting elements 104R and 104G), and the resonator structure illustrated in the first example is provided for the sub-pixel 101B (light emitting element 104B).

### 6 Example of Positional Relationship in Case Where Display Device Includes Wavelength Selection Unit

Regarding the positional relationship in a case where wavelength selection units are formed in a display device 10, the mutual positional relationship among the light emitting units, the lens members, and the wavelength selection units is now described, with the display device 10 obtained by combining the fifteenth modification and the fourteenth modification of the first embodiment being taken as an example. The display device 10 obtained by combining the fifteenth modification and the fourteenth modification of the first embodiment includes a color filter as the wavelength selection unit. Note that [6 Example of Case Where Display Device Includes Wavelength Selection Unit] may be applied to each embodiment (second to fourth embodiments) including a color filter and a lens.

### (Color Filter and Lens)

In the display device 10 obtained by combining the fifteenth modification and the fourteenth modification of the first embodiment, as illustrated in FIG. 10, a wavelength selection unit and a lens member are provided in each sub-pixel 101. In the example shown in the combination of the fifteenth modification and the fourteenth modification of the first embodiment, the wavelength selection unit is the color filter 60. For example, as the color filters 60, the red filter 60R, the green filter 60G, and the blue filter 60B are provided for the sub-pixels 101R, 101G, and 101B, respectively. At this point of time, a light absorbing layer is preferably provided between the color filters 60 adjacent to each other. Examples of the light absorbing layer include a black matrix portion. Furthermore, in the example shown in the combination of the fifteenth modification and the fourteenth modification of the first embodiment, the lens 62 is provided as the lens member.

### (Relationship Among Normal Lines Passing Through Centers of Light Emitting Unit, Lens Member, and Wavelength Selection Unit)

Hereinafter, the relationship among a normal line IN passing through the center of a light emitting unit, a normal line LN′ passing through the center of a lens member, and a normal line LN″ passing through the center of a wavelength selection unit is described. Here, the light emitting unit is, for example, the light emitting unit K. The lens member is, for example, the lens 62. The wavelength selection unit is, for example, the red filter 60R, the green filter 60G, and the blue filter 60B.

Note that the size of the wavelength selection unit may be changed as appropriate in accordance with light emitted from the light emitting unit, or, in a case where a light absorbing unit (for example, a black matrix portion) is provided between the wavelength selection units of the adjacent light emitting units, the size of the light absorbing unit may be changed as appropriate in accordance with light emitted from the light emitting unit. Furthermore, the size of the wavelength selection unit may be changed as appropriate in accordance with a distance (offset amount) do between the normal line passing through the center of the light emitting unit and the normal line passing through the center of the wavelength selection unit. The planar shape of the wavelength selection unit may be the same as, similar to, or different from the planar shape of the lens member.

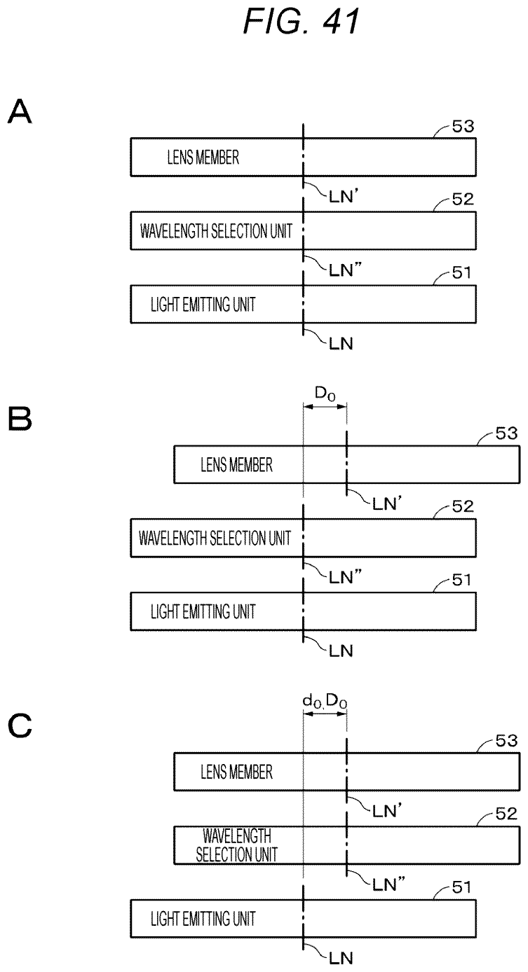

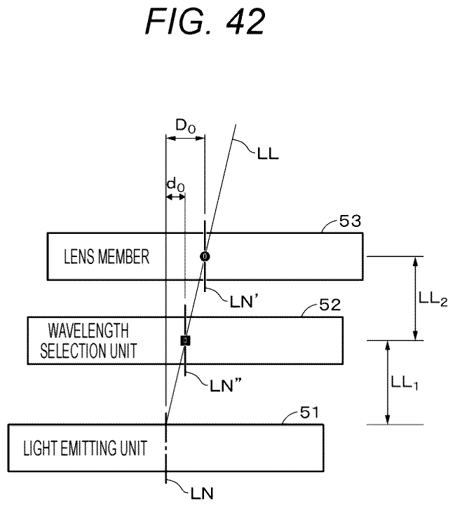

Hereinafter, with reference to FIGS. 41A, 41B, 41C, and 42, a relationship among the normal lines each passing through the center of each unit in a case where the light emitting unit 51 (corresponding to the light emitting unit K in the example of FIG. 2), the wavelength selection unit 52, and the lens member 53 are arranged in this order will be described.

As illustrated in FIG. 41A, the normal line LN passing through the center of the light emitting unit 51, the normal line LN″ passing through the center of the wavelength selection unit 52, and the normal line LN′ passing through the center of the lens member 53 may coincide with each other. That is, D0=0 and d0=0 may be satisfied. Here, D0 represents a distance (offset amount) between the normal line LN passing through the center of the light emitting unit 51 and the normal line LN′ passing through the center of the lens member 53, and do represents a distance (offset amount) between the normal line LN passing through the center of the light emitting unit 51 and the normal line LN″ passing through the center of the wavelength selection unit 52.

As illustrated in FIG. 41B, it may be configured that the normal line LN passing through the center of the light emitting unit 51 and the normal line LN″ passing through the center of the wavelength selection unit 52 coincide with each other, but the normal line LN extending through the center of the light emitting unit 51 and the normal line LN″ passing through the center of the wavelength selection unit 52 do not coincide with the normal line LN′ passing through the center of the lens member 53. That is, D0>0 and d0=0 may be satisfied.

As illustrated in FIG. 41C, it may be configured that the normal line LN passing through the center of the light emitting unit 51 does not coincide with the normal line LN″ passing through the center of the wavelength selection unit 52 and the normal line LN′ passing through the center of the lens member 53, but the normal line LN″ passing through the center of the wavelength selection unit 52 and the normal line LN′ passing through the center of the lens member 53 coincide with each other. That is, D0>0, d0>0, and D0=d0 may be satisfied.

As illustrated in FIG. 42, it may be configured that the normal line LN passing through the center of the light emitting unit 51, the normal line LN″ passing through the center of the wavelength selection unit 52, and the normal line LN′ passing through the center of the lens member 53 do not coincide with each other. That is, D0>0, d0>0, and D0≠d0 may be satisfied. Here, the center of the wavelength selection unit 52 (a position indicated by a black square in FIG. 42) is preferably located on a straight line LL connecting the center of the light emitting unit 51 and the center of the lens member 53 (a position indicated by a black circle in FIG. 42). Specifically, assuming that a distance in the thickness direction (vertical direction in FIG. 42) between the center of the light emitting unit 51 and the center of the wavelength selection unit 52 is LL1, and that a distance in the thickness direction between the center of the wavelength selection unit 52 and the center of the lens member 53 is LL2, it is preferable that

$$D 0 > d 0 > 0$$

is satisfied, and with manufacturing variations being taken into consideration,

$$d 0 : D 0 = L L 1 : ( L L 1 + L L 2 )$$

is satisfied.

Here, the thickness direction indicates the thickness direction of the light emitting unit 51, the wavelength selection unit 52, and the lens member 53.

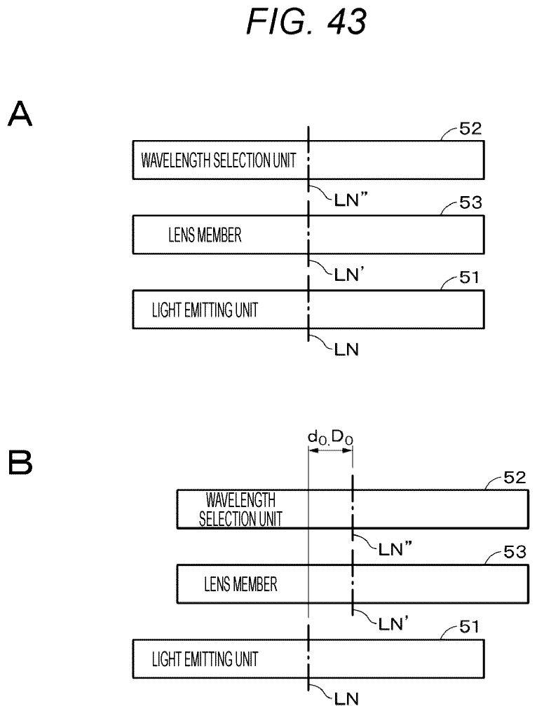

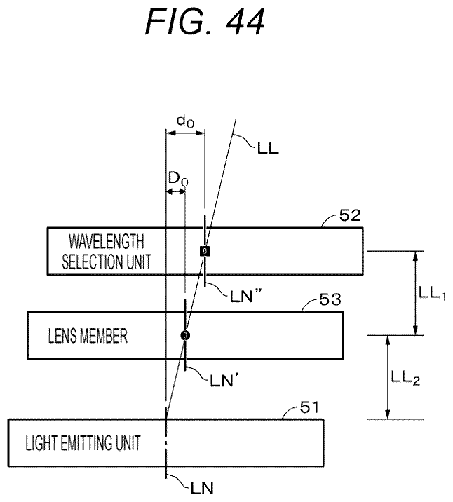

Hereinafter, with reference to FIGS. 43A, 43B, and 44, a relationship among the normal lines each passing through the center of each unit in a case where the light emitting unit 51, the lens member 53, and the wavelength selection unit 52 are arranged in this order will be described.

As illustrated in FIG. 43A, it may be configured that the normal line LN passing through the center of the light emitting unit 51, the normal line LN″ passing through the center of the wavelength selection unit 52, and the normal line LN′ passing through the center of the lens member 53 coincide with each other. That is, D0>0 and d0=0 may be satisfied.

As illustrated in FIG. 43B, it may be configured that the normal line LN passing through the center of the light emitting unit 51 does not coincide with the normal line LN″ passing through the center of the wavelength selection unit 52 and the normal line LN′ passing through the center of the lens member 53, but the normal line LN″ passing through the center of the wavelength selection unit 52 and the normal line LN′ passing through the center of the lens member 53 coincide with each other. That is, D0>0, d0>0, and D0=d0 may be satisfied.

As illustrated in FIG. 44, it may be configured that the normal line LN passing through the center of the light emitting unit 51, the normal line LN″ passing through the center of the wavelength selection unit 52, and the normal line LN′ passing through the center of the lens member 53 do not coincide with each other. Here, the center of the lens member 53 (a position indicated by a black circle in FIG. 44) is preferably located on the straight line LL connecting the center of the light emitting unit 51 and the center of the wavelength selection unit 52 (a position indicated by a black square in FIG. 44). Specifically, assuming that a distance in the thickness direction (vertical direction in FIG. 44) between the center of the light emitting unit 51 and the center of the lens member 53 is LL2, and that a distance in the thickness direction between the center of the lens member 53 and the center of the wavelength selection unit 52 is LL1, it is preferable that

$$D 0 > d 0 > 0$$

is satisfied, and, with manufacturing variations being taken into consideration,

$$d 0 : D 0 = L L 2 : ( L L 1 + L L 2 )$$

is satisfied.

Here, the thickness direction indicates the thickness direction of the light emitting unit 51, the wavelength selection unit 52, and the lens member 53.

### 7 Application Example

### (Electronic Apparatus)

The display device 10 according to one of the above-described embodiments may be provided in various electronic apparatuses. Especially, the display device is preferably provided in an apparatus requiring high resolution of an image and used near the eyes for viewing in a magnified state, the apparatus including an electronic viewfinder of a video camera or a single-lens reflex camera, a head mounted display, or the like.

### Specific Example 1

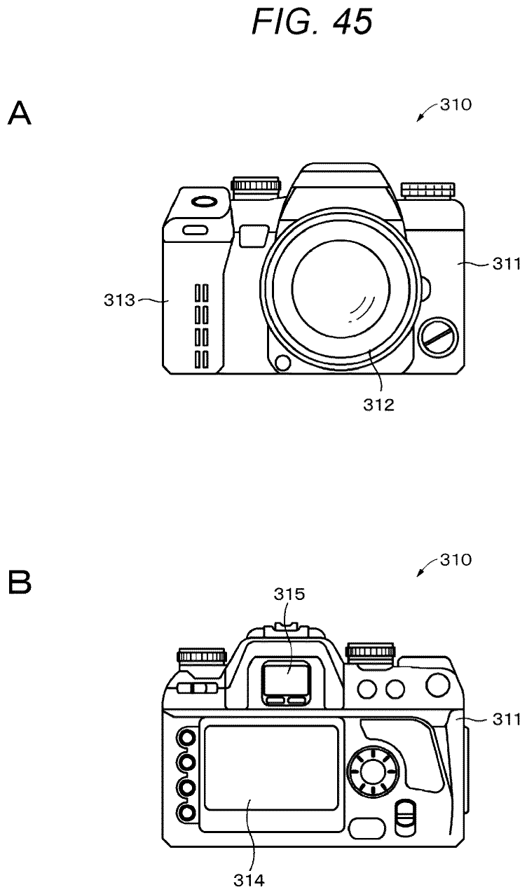

FIG. 45A is a front view illustrating an example of an external appearance of a digital still camera 310. FIG. 45B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by the photographer on the front left side.

A monitor 314 is provided at a position shifted to the left from the center of the rear surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. As the electronic viewfinder 315, any one of the display devices 10 according to the above-described embodiments and modifications can be used.

### Specific Example 2

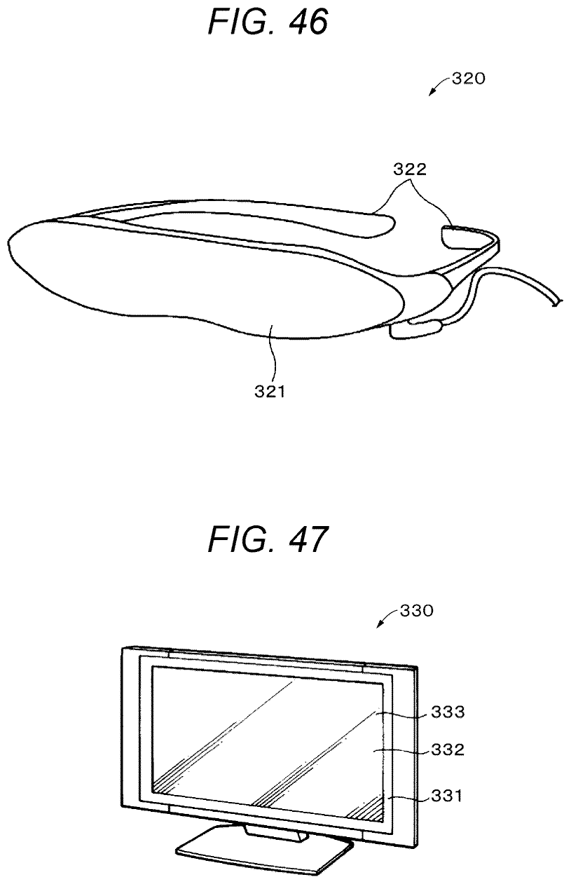

FIG. 46 is a perspective view illustrating an example of an external appearance of a head-mounted display 320. The head-mounted display 320 includes, for example, ear hooking portions 322 for a user to wear the head-mounted display 320 on the head, on both sides of a display unit 321 having a shape of eyeglasses. As the display unit 321, any one of the display devices 10 according to the above-described embodiments and modifications can be used.

### Specific Example 3

FIG. 47 is a perspective view illustrating an example of an external appearance of a television device 330. The television device 330 includes, for example, a video display screen unit 331 including a front panel 332 and a filter glass 333, and the video display screen unit 331 includes any one of the display devices 10 according to the above-described embodiments and modifications.

### Specific Example 4

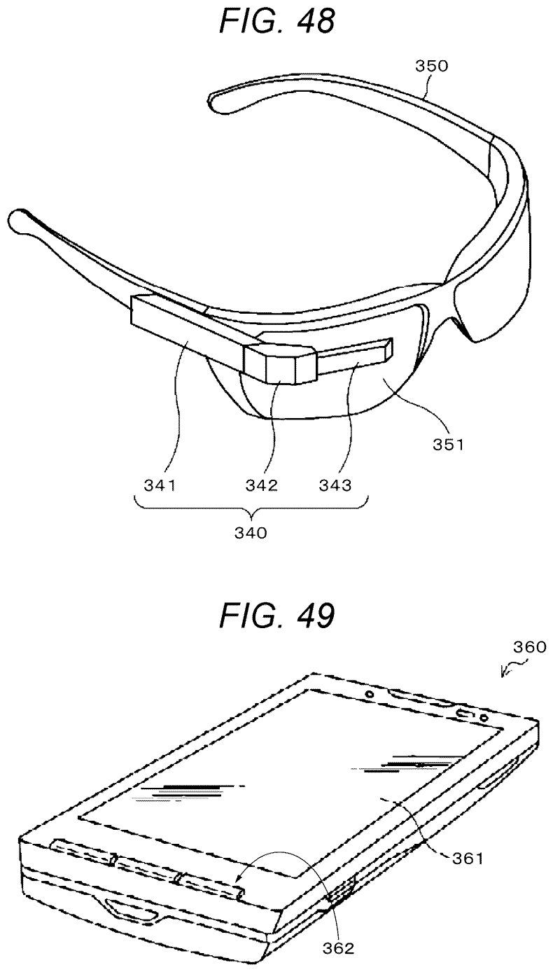

FIG. 48 illustrates an example of an external appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be mounted directly on the head of the human body.

The main body 341 includes a control substrate for controlling operations of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes one of the above display device 10 and the like.

### Specific Example 5

FIG. 49 is a perspective view illustrating an example of an external appearance of a smartphone 360. As illustrated in FIG. 49, the smartphone 360 includes a display unit 361 that displays information such as pixels, and an operation unit 362 including a button or the like that receives an operation input by the user. The display device 10 according to the above-described embodiments and modifications can be applied to the display unit 361.

### Specific Example 6

Any of the display devices 10 and the like described above may be included in a vehicle or in various kinds of displays.

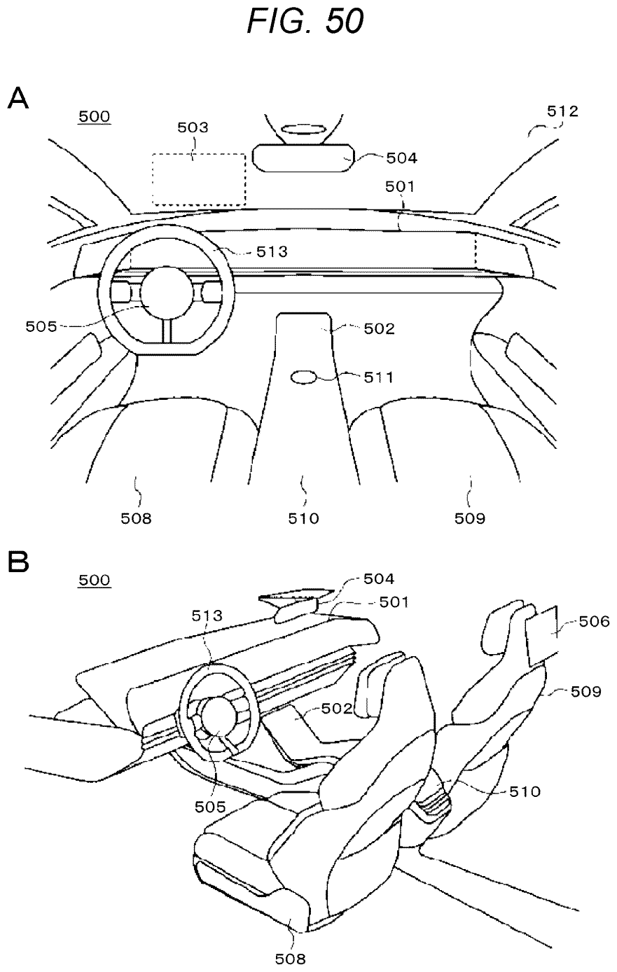

FIGS. 50A and 50B are views illustrating an example of an internal configuration of a vehicle 500 provided with various displays. Specifically, FIG. 50A is a view illustrating an example of an internal state of the vehicle 500 as viewed from the rear to the front of the vehicle 500, and FIG. 50B is a view illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the above display device 10 and the like. For example, all of these displays may include one of the above display device 10 and the like.

The center display 501 is disposed on the dashboard at a location facing a driver seat 508 and a passenger seat 509. FIGS. 50A and 50B illustrate an example of the center display 501 having a horizontally elongated shape extending from the driver seat 508 side to the passenger seat 509 side, but the screen size and the location of the center display 501 are determined as appropriate. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, or the like. The center display 501 can be used to display at least one piece of information including safety-related information, operation-related information, lifelogs, health-related information, authentication/identification-related information, and entertainment-related information, for example.

The safety-related information is information such as doze sensing, looking-away sensing, sensing of mischief of a child riding together, and presence or absence of wearing of a seat belt, sensing of leaving of an occupant, and is information sensed by a sensor disposed, for example, to overlap with the back surface side of the center display 501. The operation-related information is information obtained by using the sensor to detect gestures related to operations by the occupant. Gestures to be sensed may include operations of various types of equipment in the vehicle 500. For example, operations of air conditioning equipment, a navigation device, an audiovisual (AV) device, a lighting device, and the like are detected. The life log includes life logs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information on a keyless entry function of performing face authentication by using a sensor, and a function of automatically adjusting a seat height and position through face identification. The entertainment-related information includes information on a function of detecting, with a sensor, operation information about an audio/visual (AV) device being used by the occupant, and a function of recognizing the face of the occupant with the sensor and providing content suitable for the occupant through the AV device.

The console display 502 can be used, for example, to display lifelog information. The console display 502 is disposed near a shift lever 511 of a center console 510 between the driver seat 508 and the passenger seat 509. The console display 502 can also display information detected by various sensors. Furthermore, the console display 502 may display an image of the surroundings of the vehicle captured with an image sensor, or may display a distance image of an obstacle present in the surroundings of the vehicle.

The head-up display 503 is virtually displayed behind a windshield 512 in front of the driver seat 508. The head-up display 503 can be used to display at least one piece of information including the safety-related information, the operation-related information, the lifelogs, the health-related information, the authentication/identification-related information, and the entertainment-related information, for example. Since the head-up display 503 is virtually disposed in front of the driver seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but can also display the state of the occupant in the rear seat, and thus, can be used to display, for example, the life log information, by disposing a sensor on the back surface side of the digital rearview mirror 504 in an overlapping manner.

The steering wheel display 505 is disposed near the center of a steering wheel 513 of the vehicle 500. The steering wheel display 505 can be used to display at least one piece of information including the safety-related information, the operation-related information, the lifelogs, the health-related information, the authentication/identification-related information, and the entertainment-related information, for example. In particular, since the steering wheel display 505 is located close to the hands of the driver, the steering wheel display 505 is suitable for displaying the life log information such as the body temperature of the driver, or for displaying information regarding operations of the AV device, the air conditioning equipment, or the like.

The rear entertainment display 506 is attached to the rear surface side of the driver seat 508 or the passenger seat 509, and is for the occupant in the rear seat to enjoy viewing/listening. The rear entertainment display 506 can be used to display at least one piece of information including the safety-related information, the operation-related information, the lifelogs, the health-related information, the authentication/identification-related information, and the entertainment-related information, for example. In particular, as the rear entertainment display 506 is located in front of an occupant in the rear seat, information related to the occupant in the rear seat is displayed. For example, information regarding the operation of the AV device or the air conditioning equipment may be displayed, or a result of measurement of the body temperature or the like of the occupant in the rear seat with a temperature sensor may be displayed on the display.

A sensor may be disposed on the back surface side of the display device 10 or the like in an overlapping manner, so that the distance to an object present in the surroundings can be measured. Optical distance measurement methods are roughly classified into a passive type and an active type. By a method of the passive type, distance measurement is performed by receiving light from an object, without projecting light from a sensor onto the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the above display device and the like can be used in distance measurement by any of these methods. With a sensor disposed on the back surface side of the above display device 10 or the like in an overlapping manner, distance measurement of the passive type or the active type described above can be performed.

Although the display device according to the first to fourth embodiments, the display device according to each example, the method of manufacturing the display device, and the application examples have been specifically described as an example of the light emitting device of the present disclosure, the present disclosure is not limited to the display device according to the first to fourth embodiments, the display device according to each example, the method of manufacturing the display device, and the application example described above, and various modifications based on the technical idea of the present disclosure can be made.

For example, the configurations, methods, processes, shapes, materials, numerical values, and the like exemplified in the display device according to the first to fourth embodiments, the display devices according to each example, the method of manufacturing the display device, and the application examples described above are merely examples, and different configurations, methods, processes, shapes, materials, numerical values, and the like may be used as necessary.

The configurations, methods, processes, shapes, materials, numerical values, and the like of the display device according to the first to fourth embodiments, the display device according to each example, the method of manufacturing the display device, and application examples described above can be combined with each other without departing from the gist of the present disclosure.

The materials exemplified in the display device according to the first to fourth embodiments, the display device according to each example, the method of manufacturing the display device, and the application examples described above can be used alone or in combination of two or more unless otherwise specified.

Furthermore, the present disclosure may also employ the following configurations.

(1)

A display device including:
a first sub-pixel, a second sub-pixel, and a third sub-pixel as sub-pixels, in which
a light emitting element including an organic layer is formed in each of the sub-pixels,
the first sub-pixel includes a first light emitting element as the light emitting element, and the first light emitting element includes a first organic layer as the organic layer,
the display device further includes: a protective layer that covers at least the first light emitting element,
in the protective layer, a first opening and a second opening are formed as openings in portions corresponding to the second sub-pixel and the third sub-pixel, respectively, and
opening shapes of the first opening and the second opening are different.
   (2)

The display device according to (1), in which
the second sub-pixel and the third sub-pixel include a second light emitting element and a third light emitting element as the light emitting elements, respectively,
the second light emitting element and the third light emitting element include a second organic layer as the organic layer having a common material, and
the second organic layer includes a plurality of light emitting layers having different light emission peak wavelengths and a light emission separation layer disposed between a plurality of the light emitting layers.
   (3)

The display device according to (2), in which
in the second organic layer, a portion formed in the second light emitting element and a portion formed in the third light emitting element are continuous.
   (4)

The display device according to (2) or (3), in which
the second organic layer has a structure in which a plurality of layers are laminated, and
in a thickness of at least one layer of the plurality of layers forming the second organic layer, the thickness of the at least one layer in the second light emitting element is different from the thickness of the at least one layer in the third light emitting element.
   (5)

The display device according to (4), in which
the thickness of the at least one layer is a thickness of the light emission separation layer.
   (6)

The display device according to any one of (2) to (5), in which
the light emission separation layer includes a plurality of types of constituent components, and
a first concentration ratio that is a concentration ratio of the constituent components of the light emission separation layer formed in the second organic layer in the second light emitting element is different from a second concentration ratio that is a concentration ratio of the constituent components of the light emission separation layer formed in the second organic layer in the third light emitting element.
   (7)

The display device according to any one of (2) to (6), in which
the light emission separation layer has a structure in which a plurality of constituent layers are laminated, and
a first thickness ratio that is a ratio of a thickness of the constituent layers of the light emission separation layer formed in the second organic layer in the second light emitting element is different from a second thickness ratio that is a ratio of a thickness of the constituent layers of the light emission separation layer formed in the second organic layer in the third light emitting element.
   (8)

The display device according to any one of (2) to (7), in which
in plan view of the light emitting element, the second light emitting element and the third light emitting element each have, as regions having different thicknesses of the light emission separation layer, a first region and a second region having a smaller thickness of the light emission separation layer than the first region, and
the second light emitting element and the third light emitting element have different area ratios of the first region and the second region.
   (9)

The display device according to any one of (1) to (8), in which
an opening width of the first opening is smaller than an opening width of the second opening.
   (10)

The display device according to any one of (1) to (9), in which
the opening includes a wall surface portion, and
the wall surface portion has a shape selected from a non-tapered shape, a tapered shape, a curved shape, and a multi-step shape.
   (11)

The display device according to any one of (1) to (10), in which
the opening includes a wall surface portion, and
in the wall surface portion, an eave portion extending toward an inner side of the opening is formed in an end edge of the wall surface portion.
   (12)

The display device according to any one of (1) to (11), including:
a substrate, in which
the light emitting element includes a first electrode and a second electrode sandwiching the organic layer, and the first electrode, the organic layer, and the second electrode are laminated in this order from a side closer to the substrate, and
in at least a part of the second sub-pixel and the third sub-pixel, a size of the opening is different from a size of a region where the first electrode and the organic layer are in contact with each other.
   (13)

The display device according to any one of (1) to (12), including:
a substrate, in which
the light emitting element includes a first electrode and a second electrode sandwiching the organic layer, and the first electrode, the organic layer, and the second electrode are laminated in this order from a side closer to the substrate,
the second electrode is divided in units of the individual sub-pixels, and
a third electrode is provided so as to connect the second electrodes formed in the different sub-pixels.
   (14)

The display device according to any one of (1) to (13), including:
a substrate, in which
the light emitting element includes a first electrode and a second electrode sandwiching the organic layer, the first electrode, the organic layer, and the second electrode are laminated in this order from a side closer to the substrate,
the display device further includes: an auxiliary electrode that is configured to be electrically connectable to an outside, and
the second electrode is connected to the auxiliary electrode.
   (15)

The display device according to any one of (1) to (14), including:
a substrate, in which
the light emitting element includes a first electrode and a second electrode sandwiching the organic layer, and the first electrode, the organic layer, and the second electrode are laminated in this order from a side closer to the substrate, and
laminated structures of the second electrode and the first organic layer formed in a plurality of the first light emitting elements are connected to each other.
   (16)

The display device according to any one of (1) to (15), in which
an opening width of the opening is 1 μm or more and 10 μm or less.
   (17)

The display device according to any one of (1) to (16), in which
a thickness of the protective layer is 1 μm or more.
   (18)

An electronic apparatus including the display device according to any one of (1) to (17).

(19)

A method of manufacturing a display device, the method including:
forming a first light emitting element having a first organic layer at a position corresponding to a first sub-pixel;
forming a protective layer covering the first light emitting element;
forming a first opening and a second opening at positions corresponding to a second sub-pixel and a third sub-pixel in the protective layer so as to have opening shapes different from each other; and
forming a second organic layer in portions corresponding to the first opening and the second opening, the second organic layer forming a second light emitting element and a third light emitting element corresponding to the second sub-pixel and the third sub-pixel, respectively, and having a common material.

### REFERENCE SIGNS LIST

10 Display device
10A Display region
11 Drive substrate
13 First electrode
14 Organic layer
14A1 First organic layer
14A2 Second organic layer
15 Second electrode
15A1 Second electrode
15A2 Second electrode
16A1 First protective layer
16A2 Second protective layer
17 Upper surface protective layer
18 End surface protective layer
19A First opening
19B Second opening
23 Sealing resin layer
24 Counter substrate
51 Light emitting unit
52 Wavelength selection unit
53 Lens member
60 Color filter
62 Lens
63 Third electrode
64 Lens
101 Sub-pixel
101B Sub-pixel
101G Sub-pixel
101R Sub-pixel
103 Continuous portion
104 Light emitting element
104B Light emitting element
104G Light emitting element
104R Light emitting element
120 Manufacturing line
121 Vapor deposition source
122 Limiting plate
140 Hole injection layer
141 Hole transport layer
142 Light emitting layer
143 Electron transport layer
144 Electron injection layer
145 Light emission separation layer
AR1 First region
AR2 Second region
WA Opening width
WB Opening width
WK Opening width

1. A display device comprising:
a first sub-pixel, a second sub-pixel, and a third sub-pixel as sub-pixels, wherein
a light emitting element including an organic layer is formed in each of the sub-pixels,
the first sub-pixel includes a first light emitting element as the light emitting element, and the first light emitting element includes a first organic layer as the organic layer,
the display device further comprises: a protective layer that covers at least the first light emitting element,
in the protective layer, a first opening and a second opening are formed as openings in portions corresponding to the second sub-pixel and the third sub-pixel, respectively, and
opening shapes of the first opening and the second opening are different.

2. The display device according to claim 1, wherein
the second sub-pixel and the third sub-pixel include a second light emitting element and a third light emitting element as the light emitting elements, respectively,
the second light emitting element and the third light emitting element include a second organic layer as the organic layer having a common material, and
the second organic layer includes a plurality of light emitting layers having different light emission peak wavelengths and a light emission separation layer disposed between a plurality of the light emitting layers.

3. The display device according to claim 2, wherein
in the second organic layer, a portion formed in the second light emitting element and a portion formed in the third light emitting element are continuous.

4. The display device according to claim 2, wherein
the second organic layer has a structure in which a plurality of layers are laminated, and
in a thickness of at least one layer of the plurality of layers forming the second organic layer, the thickness of the at least one layer in the second light emitting element is different from the thickness of the at least one layer in the third light emitting element.

5. The display device according to claim 4, wherein
the thickness of the at least one layer is a thickness of the light emission separation layer.

6. The display device according to claim 2, wherein
the light emission separation layer includes a plurality of types of constituent components, and
a first concentration ratio that is a concentration ratio of the constituent components of the light emission separation layer formed in the second organic layer in the second light emitting element is different from a second concentration ratio that is a concentration ratio of the constituent components of the light emission separation layer formed in the second organic layer in the third light emitting element.

7. The display device according to claim 2, wherein
the light emission separation layer has a structure in which a plurality of constituent layers are laminated, and
a first thickness ratio that is a ratio of a thickness of the constituent layers of the light emission separation layer formed in the second organic layer in the second light emitting element is different from a second thickness ratio that is a ratio of a thickness of the constituent layers of the light emission separation layer formed in the second organic layer in the third light emitting element.

8. The display device according to claim 2, wherein
in plan view of the light emitting element, the second light emitting element and the third light emitting element each have, as regions having different thicknesses of the light emission separation layer, a first region and a second region having a smaller thickness of the light emission separation layer than the first region, and
the second light emitting element and the third light emitting element have different area ratios of the first region and the second region.

9. The display device according to claim 1, wherein
an opening width of the first opening is smaller than an opening width of the second opening.

10. The display device according to claim 1, wherein
the opening includes a wall surface portion, and
the wall surface portion has a shape selected from a non-tapered shape, a tapered shape, a curved shape, and a multi-step shape.

11. The display device according to claim 1, wherein
the opening includes a wall surface portion, and
in the wall surface portion, an eave portion extending toward an inner side of the opening is formed in an end edge of the wall surface portion.

12. The display device according to claim 1, comprising:
a substrate, wherein
the light emitting element includes a first electrode and a second electrode sandwiching the organic layer, and the first electrode, the organic layer, and the second electrode are laminated in this order from a side closer to the substrate, and
in at least a part of the second sub-pixel and the third sub-pixel, a size of the opening is different from a size of a region where the first electrode and the organic layer are in contact with each other.

13. The display device according to claim 1, comprising:
a substrate, wherein
the light emitting element includes a first electrode and a second electrode sandwiching the organic layer, and the first electrode, the organic layer, and the second electrode are laminated in this order from a side closer to the substrate,
the second electrode is divided in units of the individual sub-pixels, and
a third electrode is provided so as to connect the second electrodes formed in the different sub-pixels.

14. The display device according to claim 1, comprising:
a substrate, wherein
the light emitting element includes a first electrode and a second electrode sandwiching the organic layer, the first electrode, the organic layer, and the second electrode are laminated in this order from a side closer to the substrate,
the display device further comprises: an auxiliary electrode that is configured to be electrically connectable to an outside, and
the second electrode is connected to the auxiliary electrode.

15. The display device according to claim 1, comprising:
a substrate, wherein
the light emitting element includes a first electrode and a second electrode sandwiching the organic layer, and the first electrode, the organic layer, and the second electrode are laminated in this order from a side closer to the substrate, and
laminated structures of the second electrode and the first organic layer formed in a plurality of the first light emitting elements are connected to each other.

16. The display device according to claim 1, wherein
an opening width of the opening is 1 μm or more and 10 μm or less.

17. The display device according to claim 1, wherein
a thickness of the protective layer is 1 μm or more.

18. An electronic apparatus comprising
the display device according to claim 1.

19. A method of manufacturing a display device, the method comprising:
forming a first light emitting element having a first organic layer at a position corresponding to a first sub-pixel;
forming a protective layer covering the first light emitting element;
forming a first opening and a second opening at positions corresponding to a second sub-pixel and a third sub-pixel in the protective layer so as to have opening shapes different from each other; and
forming a second organic layer in portions corresponding to the first opening and the second opening, the second organic layer forming a second light emitting element and a third light emitting element corresponding to the second sub-pixel and the third sub-pixel, respectively, and having a common material.
